(19) United States
(12) Patent Application Publication
(10) Pub. No.: US 2017/0003591 A1
(43) Pub. Date: Jan. 5, 2017

(54) MANUFACTURING METHOD FOR ACTINIC RAY-SENSITIVE OR RADIATION-SENSITIVE RESIN COMPOSITION, ACTINIC RAY-SENSITIVE OR RADIATION-SENSITIVE RESIN COMPOSITION, ACTINIC RAY-SENSITIVE OR RADIATION-SENSITIVE FILM, MASK BLANK COMPRISING ACTINIC RAY-SENSITIVE OR RADIATION-SENSITIVE FILM, PHOTO MASK, FORMING METHOD FOR PATTERN, MANUFACTURING METHOD FOR ELECTRONIC DEVICE, AND ELECTRONIC DEVICE

(71) Applicant: FUJIFILM Corporation, Tokyo (JP)

(72) Inventors: Hidehiro MOCHIZUKI, Haibara-gun (JP); Koutarou TAKAHASHI, Haibara-gun (JP); Tomotaka TSUCHIMURA, Haibara-gun (JP)

(73) Assignee: FUJIFILM Corporation, Tokyo (JP)

(21) Appl. No.: 15/267,252

(22) Filed: Sep. 16, 2016

Related U.S. Application Data
(63) Continuation of application No. PCT/JP2015/057360, filed on Mar. 12, 2015.

(30) Foreign Application Priority Data
Mar. 31, 2014 (JP) 2014-073965

(51) Int. Cl. G03F 7/039; G03F 7/004; G03F 7/26; G03F 7/20; G03F 1/22

(52) U.S. Cl. CPC G03F 7/0397; G03F 7/70283; G03F 1/22; G03F 7/20; G03F 7/26; G03F 7/0045

(57) ABSTRACT

A manufacturing method for an actinic ray-sensitive or radiation-sensitive resin composition that contains a resin, an acid generator, an organic acid, and a solvent, includes at least one of (i), (ii), or (iii) below, and a content ratio of the organic acid in the actinic ray-sensitive or radiation-sensitive resin composition is greater than 5% by mass based on a total solid content in the composition; (i) dissolving the organic acid in a solution that does not substantially contain the resin and the acid generator, (ii) dissolving the organic acid in a solution that contains the acid generator and does not substantially contain the resin, and (iii) dissolving the organic acid in a solution that contains the resin and does not substantially contain the acid generator, an actinic ray-sensitive or radiation-sensitive resin composition, an actinic ray-sensitive or radiation-sensitive film, a mask blank including the film, a forming method for a photo mask and a pattern, a manufacturing method for an electronic device, and an electronic device.

### CROSS-REFERENCE TO RELATED APPLICATIONS

This application is a Continuation of PCT International Application No. PCT/JP2015/57360, filed on Mar. 12, 2015, which claims priority under 35 U.S.C. §119(a) to Japanese Patent Application No. 2014-73965, filed on Mar. 31, 2014. Each of the above application(s) is hereby expressly incorporated by reference, in its entirety, into the present application.

### BACKGROUND OF THE INVENTION

1. Field of the Invention

The present invention relates to a manufacturing method for an actinic ray-sensitive or radiation-sensitive resin composition that is suitably used in an ultramicrolithography process or other fabrication processes for manufacturing VLSI or high capacity microchips, or the like and that can form definition-enhanced patterns by using electron beams, extreme ultraviolet rays, or the like, an actinic ray-sensitive or radiation-sensitive resin composition, an actinic ray-sensitive or radiation-sensitive film, a mask blank comprising an actinic ray-sensitive or radiation-sensitive film, a photo mask, a forming method for a pattern, a manufacturing method for an electronic device, and an electronic device.

2. Description of the Related Art

In microfabrication using a resist composition, according to the high integration of an integrated circuit, forming of hyperfine patterns is required. Accordingly, the exposure wavelength tends to become short, from a g line, to an i line, and further to excimer laser light, and thus, for example, lithography techniques using electron beams are being currently developed.

A resist film which is provided for exposure with excimer laser light or electron beams is generally formed with a chemical amplification resist composition, and various compounds have been developed with respect to photoacid generators which are a main component of a chemical amplification resist composition. For example, a technique of using a fluorine-substituted triphenyl sulfonium salt as a photoacid generator in order to form a satisfactory pattern is known (for example, see JP2014-2359A). A technique of using an organic acid as an additive and increasing stability from the manufacturing of the resist composition to the use thereof (hereinafter, referred to as “temporal stability”) is known (for example, see JP2003-177516A).

However, in view of overall performance as a resist, it is very difficult to find a suitable combination of a resin, a photoacid generator, a basic compound, an additive, a solvent, and the like, which are used. Particularly, in view of current demands for highly efficiently forming ultrafine patterns (for example, line width of 50 nm or less), further improvement is required.

Microfabrication by a resist composition is used directly for manufacturing an integrated circuit, and recently, microfabrication has also been applied to manufacturing of a so-called imprint mold structure body and the like (for example, see JP2008-162101A). Therefore, in order to sufficiently respond to these uses, forming of ultrafine patterns (for example, having line width of 50 nm or less) in a state in which high sensitivity and high resolution are satisfied at the same time has become an important object.

### SUMMARY OF THE INVENTION

As disclosed in JP2003-177516A, it is well-known that temporal stability of the resist composition is increased by adding an organic acid. However, as a result of diligent research of the present inventors, improvement on temporal stability due to the addition of organic acid relates to various elements, and thus it has been found that increase of temporal stability to a satisfactory level and increase of resolution cannot be achieved by only technical common knowledge of simply adding an organic acid.

An object of the invention is to provide a manufacturing method for an actinic ray-sensitive or radiation-sensitive resin composition having excellent temporal stability and excellent resolution.

An object of the invention is to provide an actinic ray-sensitive or radiation-sensitive resin composition having excellent temporal stability and excellent resolution, an actinic ray-sensitive or radiation-sensitive film using this, a mask blank comprising an actinic ray-sensitive or radiation-sensitive film, a photo mask, and a forming method for a pattern, a manufacturing method for an electronic device, and an electronic device.

According to an embodiment, the invention is as follows.

[1] A manufacturing method for an actinic ray-sensitive or radiation-sensitive resin composition that contains (A) resin, (B) acid generator, (C) organic acid; and (D) solvent, comprising: at least one of (i), (ii), or (iii) below, in which content ratio of (C) organic acid in the actinic ray-sensitive or radiation-sensitive resin composition is greater than 5% by mass based on a solid content in the composition.

(i) dissolving (C) organic acid in a solution that does not substantially contain (A) resin and (B) acid generator

(ii) dissolving (C) organic acid in a solution that contains (B) acid generator and does not substantially contain (A) resin, and

(iii) dissolving (C) organic acid in a solution that contains (A) resin and does not substantially contain (B) acid generator.

[2] The manufacturing method according to [1], in which pKa of (C) organic acid is lower than pKa of (A) resin and is greater than pKa of acid generated from (B) acid generator.

[3] The manufacturing method according to [1] or [2], in which (C) organic acid is organic carboxylic acid.

[4] The manufacturing method according to [3], in which (C) organic acid is aromatic organic carboxylic acid.

[5] The manufacturing method according to any one of [1] to [4], in which (A) resin includes a repeating unit having a group that is decomposed due to an action of acid and of which polarity increases.

[6] The manufacturing method according to any one of [1] to [5], in which (A) resin includes a repeating unit having a phenolic hydroxyl group.

[7] The manufacturing method according to any one of [1] to [6], in which (B) acid generator is an ionic compound consisting of an organic anion and a cation selected from a sulfonium cation and an iodonium cation, and the cation is a cation having at least one electron-withdrawing group.

[8] The manufacturing method according to [7], in which the organic anion is an aromatic sulfonic acid anion.

[9] The manufacturing method according to any one of [1] to [8], in which the actinic ray-sensitive or radiation-sensitive resin composition further contains a basic compound.

[10] The manufacturing method according to [9], in which the basic compound is an ammonium salt.

[11] The manufacturing method according to any one of [1] to [10], in which a concentration of a solid content of the actinic ray-sensitive or radiation-sensitive resin composition is 10% by mass or less.

[12] An actinic ray-sensitive or radiation-sensitive resin composition manufactured by the manufacturing method according to any one of [1] to [11].

[13] An actinic ray-sensitive or radiation-sensitive film manufactured from the actinic ray-sensitive or radiation-sensitive resin composition according to [12].

[14] The actinic ray-sensitive or radiation-sensitive film according to [13], in which a film thickness is 200 nm or less.

[15] A mask blank comprising: the actinic ray-sensitive or radiation-sensitive film according to [13] or [14].

[16] A photo mask manufactured by a method including exposing an actinic ray-sensitive or radiation-sensitive film comprising the mask blank according to [15] and developing the exposed actinic ray-sensitive or radiation-sensitive film.

[17] A method for forming a pattern including exposing the actinic ray-sensitive or radiation-sensitive film according to [13] or [14] and developing the exposed film.

[18] The method for forming a pattern according to [17], in which the exposure is exposure with electronic rays or EUV light.

[19] An actinic ray-sensitive or radiation-sensitive resin composition, comprising: (A) resin; (B) acid generator; and (C) organic acid; in which a content ratio of (C) organic acid is greater than 5% by mass based on a solid content in the actinic ray-sensitive or radiation-sensitive resin composition.

[20] The actinic ray-sensitive or radiation-sensitive resin composition according to [19], in which pKa of (C) organic acid is lower than pKa of (A) resin and higher than pKa of acid that is generated from (B) acid generator.

[21] The actinic ray-sensitive or radiation-sensitive resin composition according to [19] or [20], in which (A) resin is a resin including a repeating unit having a phenolic hydroxyl group, (B) acid generator is an ionic compound consisting of an organic anion and a cation selected from a sulfonium cation and an iodonium cation, and the cation is an ionic compound having at least one electron-withdrawing group.

[22] The actinic ray-sensitive or radiation-sensitive resin composition according to any one of [19] to [21], in which (B) acid generator is a compound that generates acid having a volume of 240 Å³ or greater due to irradiation of actinic rays or radiation.

[23] A manufacturing method for an electronic device, comprising: the method for forming a pattern according to [17] or [18].

[24] An electronic device manufactured by the manufacturing method for an electronic device according to [23].

According to the invention, it is possible to provide a manufacturing method for an actinic ray-sensitive or radiation-sensitive resin composition having excellent temporal stability and excellent resolution.

According to the invention, it is possible to provide an actinic ray-sensitive or radiation-sensitive resin composition having excellent temporal stability and excellent resolution, an actinic ray-sensitive or radiation-sensitive film using this, a mask blank comprising an actinic ray-sensitive or radiation-sensitive film, a forming method for a photo mask and a pattern, a manufacturing method for an electronic device, and an electronic device.

### DESCRIPTION OF THE PREFERRED EMBODIMENTS

Hereinafter, detailed descriptions of the invention are specifically provided.

In the description of a group (atomic group) in this specification, a description of not indicating substitution or unsubstitution includes a group (atomic group) not having a substituent together with a group (atomic group) having a substituent. For example, an “alkyl group” include not only an alkyl group (unsubstituted alkyl group) not having a substituent but also an alkyl group (substituted alkyl group) having a substituent.

According to the invention, “actinic rays” or “radiation” mean, for example, a bright line spectrum of a mercury lamp, far ultraviolet rays represented by an excimer laser, extreme ultraviolet rays (EUV light), X rays, and electron beams. In addition, according to the invention, “light” means actinic rays or radiation. According to the invention, unless described otherwise, “exposure” includes not only exposure by bright line spectrum of a mercury lamp, far ultraviolet rays represented by an excimer laser, X rays, and EUV light but also drawing by particle beams such as electron beams and ion beams.

Hereinafter, the invention is described in detail.

A manufacturing method for an actinic ray-sensitive or radiation-sensitive resin composition according to the invention (hereinafter, also referred to as a “manufacturing method according to the invention”) relates to a manufacturing method for an actinic ray-sensitive or radiation-sensitive resin composition that contains a resin, an acid generator, an organic acid, and a solvent, and a first characteristic thereof is to specify an adding time of the organic acid to the solvent in a relationship between the resin and the acid generator, and to add the organic acid such that a content ratio thereof becomes greater than 5% by mass with respect to a total solid content in the actinic ray-sensitive or radiation-sensitive resin composition.

A manufacturing method according to the invention is a manufacturing method for an actinic ray-sensitive or radiation-sensitive resin composition that contains (A) resin, (B) acid generator, (C) organic acid; and (D) solvent, and includes several steps selected from:

(i) a step of dissolving (C) organic acid in a solution that does not substantially contain (A) resin and (B) acid generator,

(ii) a step of dissolving (C) organic acid in a solution that contains (B) acid generator and does not substantially contain (A) resin, and

(iii) a step of dissolving (C) organic acid in a solution that contains (A) resin and does not substantially contain (B) acid generator, and a content ratio of (C) organic acid in the actinic ray-sensitive or radiation-sensitive resin composition is greater than 5% by mass with respect to a total solid content in the composition.

This is based on an idea that, in a case where the resin and the acid generator coexist in a solution that does not contain organic acid, even if organic acid is added afterwards, a desired improvement effect of temporal stability of an actinic ray-sensitive or radiation-sensitive resin composition due to organic acid may not be obtained. If a case where a resin having a phenolic hydroxyl group is used as the resin and aromatic carboxylic acid is used as the organic acid is provided as an example, this mechanism is assumed as follows.

That is, in a case where the resin having the phenolic hydroxyl group is dissolved in the solvent, phenolate anion (C₆H₆O⁻) is generated. A phenolate anion exhibiting a strong nucleophilic effect generates addition reaction on a carbon atom included in a cation of the acid generator in the solvent, and thus a bond between the resin and the acid generator proceeds. This addition reaction prominently proceeds in a case where the cation of the acid generator has an electron-withdrawing group. Due to the bond between the resin and the acid generator, dissolving speed of the composition continuously decrease (that is, temporal stability is deteriorated), and as a result, performance deterioration such as sensitivity decrease occurs. The addition reaction between the resin and the acid generator is an irreversible reaction. Even if organic acid is added after the resin and the acid generator are bonded, an effect as a stabilizer is not exhibited.

Accordingly, in a case where organic acid is added to a solvent without making a situation in which the resin and the acid generator coexist in a solvent that does not contain organic acid, that is, in a case where the manufacturing method according to the invention includes any step of the steps (i), (ii), and (iii), the generation of the phenolate anion is suppressed, and a generation amount of a benzoate anion increases. It is assumed that, since a nucleophilic effect of a benzoate anion is weak, addition reaction generated between the resin and the acid generator can be suppressed, and thus the temporal stability of the actinic ray-sensitive or radiation-sensitive resin composition. This suppression effect increases in a case where pKa of the organic acid is lower than pKa of the resin, or in a case where pKa of the organic acid is higher than pKa of acid generated from the acid generator.

In the manufacturing method according to the invention, the expression “substantially containing (A) resin and (B) acid generator” in step (i) means that a content ratio of (A) resin and (B) acid generator in the solution (or solvent) is ideally 0% by mass, but does not intend to exclude a case where a minute amount thereof is contained in a range of not deteriorating the effect of the invention. For example, unless the effect according to the invention is not deteriorated, content ratios of (A) resin and (B) acid generator in the solution are respectively 0.05% by mass or less, preferably 0.03% by mass or less, more preferably 0.01% by mass, and most preferably 0% by mass.

In the same manner, the expression “not substantially containing (A) resin” in step (ii) does not intend to exclude a case where a minute amount of (A) resin is contained in a range of not deteriorating the effect of the invention. For example, the content ratio of (A) resin in the solution may be 0.05% by mass or less, preferably 0.03% by mass or less, more preferably 0.01% by mass, and most preferably 0% by mass.

In the same manner, the expression “not substantially containing (B) acid generator” in step (iii) does not intend to exclude a case where a minute amount of (B) acid generator is contained in a range of not deteriorating the effect of the invention. For example, the content ratio of (B) acid generator in the solution may be 0.05% by mass or less, preferably 0.03% by mass or less, more preferably 0.01% by mass, and most preferably 0% by mass.

In the manufacturing method according to the invention, insertion interval of respective components of the resin, the acid generator, and the organic acid to the solvent is not particularly limited, and the organic acid may be added to the solvent without making the situation in which the resin and the acid generator coexist in the solvent that does not contain the organic acid.

For example, in a case where the manufacturing method according to the invention includes step (i) above, the resin and the acid generator may be added at the same time, after adding the organic acid. In step (ii) above, a case where the organic acid and the resin are added to the solution that contains the acid generator and does not substantially contain the resin at the same time is also included. In step (iii), a case where the organic acid and the acid generator are added to the solution that contains the resin and does not substantially contain the acid generator at the same time is included.

However, an embodiment of adding respective components to the solvent one by one and adding a next component after added components are completely dissolved is more preferable.

An addition order of components (for example, a basic compound described below and the like) other than the resin, the acid generator, and the organic acid is not particularly limited.

<(C) Organic Acid>

An amount of the organic acid added in the manufacturing method according to the invention is preferably large in view of temporal stability, and the the organic acid is added such that the content ratio of the organic acid in the actinic ray-sensitive or radiation-sensitive resin composition (hereinafter, also referred to as a “composition according to the invention”) according to the invention becomes greater than 5% by mass with respect to the total solid content. According to an embodiment of the invention, the content ratio of the organic acid in the composition according to the invention is more preferably greater than 5% by mass and less than 15% by mass and even more preferably greater than 5% by mass and less than 10% by mass with respect to the total solid content in the composition.

In view of temporal stability, pKa of the organic acid is preferably in the range of 0 to 10, more preferably in the range of 2 to 8, and even more preferably in the range of 3 to 7. Here, pKa refers to pKa in the aqueous solution and is, for example, as defined in Chemical Handbook (II) (4th Revised Edition, 1993, edited by The Chemical Society of Japan, Maruzen). As a value thereof is lower, acid strength is greater. pKa in the aqueous solution can be actually measured by measuring an acid dissociation constant at 25° C. by using an infinite dilution aqueous solution. Values based on Hammett substituent constant and database in the well-known document values can be obtained by calculated using software package 1 below. Values of pKa in this specification completely indicate values obtained by calculation using this software package. Software package 1: Advanced Chemistry Development (ACD/Labs) Software V8.14 for Solaris (1994-2007 ACD/Labs).

As described above, in view of suppression of addition reaction generated between the resin and the acid generator, pKa of organic acid is preferably lower than pKa of the resin, and preferably higher than pKa of acid generated from the acid generator. According to an embodiment of the invention, pKa of the organic acid is preferably lower than pKa of (A) resin by 3 or greater and more preferably lower than pKa of (A) resin by 5 or greater. According to another embodiment, pKa of the organic acid is preferably higher than pKa of the acid generated from (B) acid generator by 2 or greater, and more preferably higher than pKa of the acid generated from 3 or greater.

Examples of the organic acid that can be used in the invention include organic carboxylic acid and organic sulfonic acid. Among these, organic carboxylic acid is preferable. Examples of the organic carboxylic acid include aromatic organic carboxylic acid, aliphatic carboxylic acid, alicyclic carboxylic acid, unsubstituted aliphatic carboxylic acid, oxycarboxylic acid, and alkoxycarboxylic acid. According to an embodiment of the invention, aromatic organic carboxylic acid is preferable, and benzoic acid, 2-hydroxy-3-naphthoic acid, and 2-naphthoic acid are particularly preferable.

<(A) Resin>

Specifically, (A) resin preferably includes a repeating unit having a group (hereinafter, referred to as an “acid decomposable group”) that is decomposed due to an action of an acid and of which polarity increases. As the repeating unit having a group that is decomposed due to an action of acid and of which polarity increases, a repeating unit having a group that is decomposed due to an action of acid and generates an alkali soluble group is preferable (hereinafter, the resin (A) in this case may be referred to as a “resin that is decomposed due to an action of acid and of which solubility in an alkaline developer increases” or an “acid decomposable resin”).

The acid decomposable group is preferably a group obtained by substituting a hydrogen atom of an alkaline soluble polymer such as a —COOH group and an —OH group with a group that is left due to an action of acid. The group that is left due to an action of acid is particularly preferably an acetal group or a tertiary ester group.

An example of a matrix resin in a case where this acid decomposable group is bonded as a side chain includes an alkaline soluble resin having —OH or a —COOH group at a side chain. Examples of this alkaline soluble resin include resins described below.

The alkali dissolution rate of this alkaline soluble resin is preferably 17 nm/sec or greater measured by 0.261 N tetramethyl ammonium hydroxide (TMAH) (23° C.). This rate is particularly preferably 33 nm/sec or greater.

In this point of view, examples of particularly preferable alkaline soluble resin include a resin including a hydroxystyrene structure unit such as o-, m-, and p-poly(hydroxystyrene), and copolymers of these, hydrogenated poly(hydroxystyrene), a halogen- or alkyl-substituted poly(hydroxystyrene), and partially O-alkylated products or O-acylated products of poly(hydroxystyrene), a styrene-hydroxystyrene copolymer, an α-methylstyrene-hydroxystyrene copolymer, and a hydrogenated novolac resin; and a resin including a repeating unit having a carboyxl group such as a (meth)acrylic acid and a norbornene carboxylic acid.

Examples of the preferable repeating unit having the acid decomposable group include t-butoxycarbonyloxystyrene, 1-alkoxyethoxystyrene, and (meth)acrylic acid tertiary alkyl ester. As the repeating unit, 2-alkyl-2-adamantyl (meth)acrylate or dialkyl(1-adamantyl)methyl (meth)acrylate are more preferable.

As disclosed in EP254853A, JP1990-25850A (JP-H2-25850A), JP1991-223860A (JP-H3-223860A), and JP1992-251259A (JP-H4-251259A), the resin that is decomposed due to an action of acid and of which solubility in an alkaline developer increases can be obtained, for example, by reacting a precursor of a group that is left due to an action of acid with a resin, or copolymerizing an alkaline soluble resin monomer bonded to the group that is left due to the action of the acid with various monomers.

In a case where the composition according to the invention is irradiated with KrF excimer light, electron beams, X rays, or high energy rays having a wavelength of 50 nm or less (for example, EUV), the resin preferably have a hydroxystyrene repeating unit. It is still more preferable that the resin is a copolymer of hydroxystyrene protected by a group that is left due to the action of the acid and hydroxystyrene or a copolymer of hydroxystyrene and (meth)acrylic acid tertiary alkyl ester.

With respect to the resin, specifically, examples of the repeating unit having a group include a resin having a repeating unit represented by Formula (A) below. In a case where the resin having the repeating unit is used, the dry etching resistance of the formed pattern is improved.

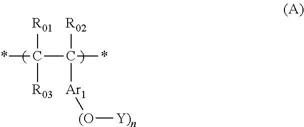

In the formula, R₀₁, R₀₂, and R₀₃ each independently represents, for example, a hydrogen atom, an alkyl group, a cycloalkyl group, a halogen atom, a cyano group, or an alkoxycarbonyl group. Ar₁ represents, for example, an aromatic ring group. R₀₃ and Ar₁ are alkylene groups, and both are bonded to each other to form a 5-membered or 6-membered ring together with a —C—C— chain.

N items of Y's each independently represent a hydrogen atom or a group that is left due to an action of an acid. However, at least one of the Y's represents a group that is left due to an action of an acid.

n represents an integer of 1 to 4, preferably an integer of 1 or 2 is, and more preferably 1.

The alkyl groups as R₀₁ to R₀₃ are, for example, an alkyl group having 20 or less carbon atoms, and preferably a methyl group, an ethyl group, a propyl group, an isopropyl group, a n-butyl group, a sec-butyl group, a hexyl group, a 2-ethylhexyl group, an octyl group, or a dodecyl group. It is more preferable that the alkyl group is an alkyl group having 8 or less carbon atoms. The alkyl group may have a substituent.

As the alkyl group included in the alkoxycarbonyl group, the same alkyl groups as the alkyl groups in R₀₁ to R₀₃ are preferable.

The cycloalkyl group may be a monocyclic cycloalkyl group or may be a polycyclic cycloalkyl group. It is preferable that examples thereof include a monocyclic cycloalkyl group having 3 to 8 carbon atoms such as a cyclopropyl group, a cyclopentyl group, and a cyclohexyl group. In addition, these cycloalkyl groups may have substituents.

Examples of the halogen atom include a fluorine atom, a chlorine atom, a bromine atom, and an iodine atom, and a fluorine atom is more preferable.

In a case where R₀₃ represents an alkylene group, the alkylene group is preferably a group having 1 to 8 carbon atoms, such as a methylene group, an ethylene group, a propylene group, a butylene group, a hexylene group, and an octylene group.

The aromatic ring group as Ar₁ is preferably an aromatic ring group having 6 to 14 carbon atoms, and examples thereof include a benzene ring, a toluene ring, and a naphthalene ring. In addition, these aromatic ring groups may have substituents.

Examples of the group Y that is left due to an action of an acid include groups) represented by —C(R³⁶)(R³⁷)(R³⁸), —C(═O)—O—C(R³⁶)(R³⁷)(R³⁸), —C(R⁰¹)(R⁰²)(OR³⁹), —C(R⁰¹)(R⁰²) C(═O)—O—C(R³⁶)(R³⁷)(R³⁸), and —CH(R³⁶)(Ar).

In the formula, R³⁶ to R³⁹ each independently represent an alkyl group, a cycloalkyl group, an aryl group, an aralkyl group, or an alkenyl group. R³⁶ and R³⁷ are bonded to each other to form a ring structure.

R⁰¹ and R⁰² each independently represent a hydrogen atom, an alkyl group, a cycloalkyl group, an aryl group, an aralkyl group, or an alkenyl group.

Ar represents an aryl group.

An alkyl group as R³⁶ to R³⁹, R⁰¹, or R⁰² is preferably an alkyl group having 1 to 8 carbon atoms, and examples thereof include a methyl group, an ethyl group, a propyl group, a n-butyl group, a sec-butyl group, a hexyl group, and an octyl group.

The cycloalkyl group as R³⁶ to R³⁹, R⁰¹, or R⁰² may be a monocyclic cycloalkyl group or may be a polycyclic cycloalkyl group. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, and cyclooctyl group. As the polycyclic cycloalkyl group, a cycloalkyl group having 6 to 20 carbon atoms is preferable, and examples thereof include an adamantyl group, a norbornyl group, an isobornyl group, a camphanyl group, a dicyclopentyl group, an α-pinel group, a tricyclodecanyl group, a tetracyclododecyl group, and an androstanyl group. In addition, a portion of a carbon atom in a cycloalkyl group may be substituted with a hetero atom such as an oxygen atom.

The aryl group as R³⁶ to R³⁹, R⁰¹, R⁰², or Ar is preferably an aryl group having 6 to 10 carbon atoms, and examples thereof include a phenyl group, a naphthyl group, and an anthryl group.

The aralkyl group as R³⁶ to R³⁹, R¹⁰, or R⁰² preferably an aralkyl group having 7 to 12 carbon atoms, and for example, a benzyl group, a phenethyl group, and a naphthylmethyl group are preferable.

The alkenyl group as R³⁶ to R³⁹, R⁰¹, or R⁰² is preferably an alkenyl group having 2 to 8 carbon atoms, and examples thereof include a vinyl group, an allyl group, a butenyl group, and a cyclohexanyl group.

A ring that can be formed by bonding R³⁶ and R³⁷ to each other may be a monocyclic type or may be a polycyclic type. As the monocyclic type, a cycloalkane structure having 3 to 8 carbon atoms is preferable, and examples thereof include a cyclopropane structure, a cyclobutane structure, a cyclopentane structure, a cyclohexane structure, a cycloheptane structure, and a cyclooctane structure. As the polycyclic type, a cycloalkane structure having 6 to 20 carbon atoms is preferable, and examples thereof include an adamantane structure, a norbornene structure, a dicyclopentane structure, a tricyclodecane structure, and a tetracyclododecane structure. In addition, a portion of the carbon atom in the ring structure is substituted with a hetero atom such as an oxygen atom.

The respective groups may have substituents. Examples of the substituent include an alkyl group, a cycloalkyl group, an aryl group, an amino group, an amido group, an ureido group, an urethane group, a hydroxyl group, a carboyxl group, a halogen atom, an alkoxy group, a thioether group, an acyl group, an acyloxy group, an alkoxycarbonyl group, a cyano group, and a nitro group. The substituent preferably has 8 or less carbon atoms.

As the group Y that is left due to an action of an acid, a structure represented by Formula (B) below is more preferable.

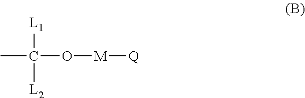

In the formula, L₁ and L₂ each independently represent a hydrogen atom, an alkyl group, a cycloalkyl group, an aryl group, or an aralkyl group.

M represents a single bond or a divalent linking group.

Q represents an alkyl group, a cycloalkyl group, a cyclic aliphatic group, an aromatic ring group, an amino group, an ammonium group, a mercapto group, a cyano group, or an aldehyde group. In addition, the cyclic aliphatic group and the aromatic ring group may have hetero atoms.

At least two of Q, M, or L₁ may be bonded to each other to form a 5-membered or 6-membered ring.

An example of the alkyl group as L₁ and L₂ is an alkyl group having 1 to 8 carbon atoms, and specific examples thereof include a methyl group, an ethyl group, a propyl group, an isopropyl group, a n-butyl group, a sec-butyl group, a t-butyl group, a hexyl group, and an octyl group.

The cycloalkyl group as L₁ and L₂ is, for example, a cycloalkyl group having 3 to 15 carbon atoms, and specific examples thereof include a cyclopentyl group, a cyclohexyl group, a norbornyl group, and an adamantyl group.

The aryl group as L₁ and L₂ is, for example, an aryl group having 6 to 15 carbon atoms, and specific examples thereof include a phenyl group, a tolyl group, a naphthyl group, and an anthryl group.

The aralkyl group as L₁ and L₂ is, for example, an aralkyl group having 6 to 20 carbon atoms, and specific examples thereof include a benzyl group and a phenethyl group.

The divalent linking group as M is, for example, an alkylene group (for example, a methylene group, an ethylene group, a propylene group, a butylene group, a hexylene group, or an octylene group), a cycloalkylene group (for example, a cyclopentyl group or a cyclohexylene group), an alkenylene group (for example, an ethynylene group, a propenyl group, or a butenyl group), an arylene group (for example, a penylene group, a tolylene group, or a naphthylene group), —S—, —O—, —CO—, —SO₂—, and —N(R₀)—, or a bond of 2 or more of these groups. Here, R₀ is a hydrogen atom or an alkyl group. The alkyl group as R₀ is, for example, an alkyl group having 1 to 8 carbon atoms, and specific examples thereof include a methyl group, an ethyl group, a propyl group, a n-butyl group, a sec-butyl group, a hexyl group, and an octyl group.

The alkyl group and the cycloalkyl group as Q are the same as the respective groups as L₁ and L₂ described above.

Examples of the cyclic aliphatic group or the aromatic ring group as Q include the cycloalkyl group and the aryl group as L₁ and L₂ described above. This cycloalkyl group and this aryl group are preferably groups having 3 to 15 carbon atoms.

Examples of the cyclic aliphatic group or the aromatic ring group including the hetero atom as Q include a group having a heterocyclic ring structure such as thiirane, cyclothiolane, thiophene, furan, pyrrole, benzothiophene, benzofuran, benzopyrrole, triazine, imidazole, benzimidazole, triazole, thiadiazole, thiazole, and pyrrolidone. However, the cyclic aliphatic group or the aromatic ring group is not limited thereof as long as a group is a ring formed with carbon and a hetero atom, or a ring formed only with hetero atoms.

An example of the ring structure that can be formed by bonding at least two of Q, M, or L₁ include a 5-membered or 6-membered ring structure obtained by forming a propylene group or a butylene group with these. In addition, the 5-membered or 6-membered ring structure contains an oxygen atom.

The respective groups represented by L₁, L₂, M, and Q in Formula (B) may have substituents. Examples of the substituent include an alkyl group, a cycloalkyl group, an aryl group, an amino group, an amido group, an ureido group, a urethane group, a hydroxyl group, a carboyxl group, a halogen atom, an alkoxy group, a thioether group, an acyl group, an acyloxy group, an alkoxycarbonyl group, a cyano group, and a nitro group. These substituents preferably have 8 or less carbon atoms.

As the group represented by -(M-Q), the group having 1 to 30 carbon atoms is preferable, and a group having 5 to 20 carbon atoms is more preferable. Particularly, in view of outgas suppression, a group having 6 or more carbon atoms is preferable.

The acid decomposable resin may be a resin having a repeating unit represented by Formula (X) below, as a repeating unit having an acid decomposable group.

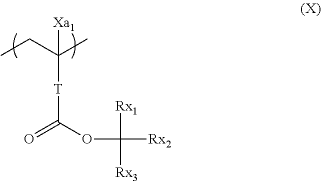

In Formula (X),

Xa₁ represents a hydrogen atom, a methyl group, a trifluoromethyl group, or a hydroxymethyl group.

T represents a single bond or a divalent linking group.

Rx₁ to Rx₃ each independently represent a straight chain or branched alkyl group or a monocyclic or polycyclic cycloalkyl group. In addition, 2 of Rx₁ to Rx₃ may be bonded to each other to form a monocyclic or polycyclic cycloalkyl group.

Examples of the divalent linking group as T include an alkylene group, a —(COO-Rt)- group, and an —(O-Rt)- group. Here, Rt represents an alkylene group or a cycloalkylene group.

T is preferably a single bond or a —(COO-Rt)- group. Here, Rt is preferably an alkylene group having 1 to 5 carbon atoms, and a —CH₂— group or a —(CH₂)₃— group is more preferable.

The alkyl group as Rx₁ to Rx₃ is preferably an alkyl group having 1 to 4 carbon atoms such as a methyl group, an ethyl group, a n-propyl group, an isopropyl group, a n-butyl group, an isobutyl group, and a t-butyl group.

The cycloalkyl group as Rx₁ to Rx₃ is preferably a monocyclic cycloalkyl group such as a cyclopentyl group and a cyclohexyl group or a polycyclic cycloalkyl group such as a norbornyl group, a tetracyclodecanyl group, a tetracyclododecanyl group, and an adamantyl group.

As the cycloalkyl group that can be formed by bonding two of Rx₁ to Rx₃, a monocyclic cycloalkyl group such as a cyclopentyl group and a cyclohexyl group, or a polycyclic cycloalkyl group having a norbornyl group, a tetracyclodecanyl group, a tetracyclododecanyl group, and an adamantyl group is preferable.

Particularly, Rx₁ is a methyl group or an ethyl group, and an aspect in which Rx₂ and Rx₃ are bonded to each other and the cycloalkyl group described above is formed is preferable.

According to an embodiment, the resin (A) preferably has a phenolic hydroxyl group. Here, the phenolic hydroxyl group refers to a group obtained by substituting a hydrogen atom of an aromatic ring group with a hydroxy group. The aromatic ring of this aromatic ring group is a monocyclic or polycyclic aromatic ring, and examples thereof include a benzene ring or a naphthalene ring.

In a case where the resin (A) according to the invention is a resin having a phenolic hydroxyl group, this resin preferably contains a repeating unit having at least one phenolic hydroxyl group. The repeating unit having a phenolic hydroxyl group is not particularly limited, and is preferably a repeating unit represented by Formula (1) below.

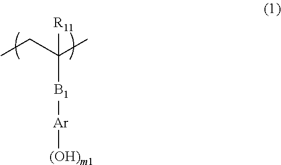

In Formula (1), R₁₁ is a hydrogen atom, a methyl group that may have a substituent, or a halogen atom.

B₁ is a single bond or divalent linking group.

Ar represents an aromatic ring.

m1 represents an integer of 1 or greater.

Examples of the methyl group that may have a substituent in R₁₁ include a trifluoromethyl group and a hydroxymethyl group.

R₁₁ is preferably a hydrogen atom or a methyl group. For the reason of developability, a hydrogen atom is preferable.

As a divalent linking group of B₁, a carbonyl group, an alkylene group (preferably having 1 to 10 carbon atoms and more preferably having 1 to 5 carbon atoms), sulfonyl group (—S(═O)₂—), —O—, —NH— or a divalent linking group obtained by combining these is preferable.

B₁ preferably represents a single bond, a carbonyloxy group (—C(═O)—O—), or —C(═O)—NH—, more preferably represents a single bond or a carbonyloxy group (—C(═O)—O—). In view of dry etching resistance enhancement, a single bond is particularly preferable.

An aromatic ring of Ar is a monocyclic or polycyclic aromatic ring, an aromatic hydrocarbon ring that may have substituent having 6 to 18 carbon atoms such as a benzene ring, a naphthalene ring, an anthracene ring, a fluorene ring, and a phenanthrene ring. Examples thereof include an aromatic heterocyclic ring including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, in view of resolution, a benzene ring and a naphthalene ring are preferable, and in view of sensitivity, a benzene ring is most preferable.

m1 is preferably an integer of 1 to 5 and most preferably 1. When m1 is 1 and Ar is a benzene ring, a substitution position of —OH may be a para position, a meta position, or an ortho position with respect to the bonding position to B₁ of a benzene ring (a polymer main chain, in a case where B₁ is a single bond). And, in view of crosslinking reaction, a para position and a meta position are preferable, and a para position is more preferable.

An aromatic ring of Ar may have a substituent in addition to a group represented by —OH above, and examples of the substituent include an alkyl group, a cycloalkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

The repeating unit having the phenolic hydroxyl group is more preferably a repeating unit represented by Formula (2) below, for the reason of crosslinking reaction, developability, and dry etching resistance.

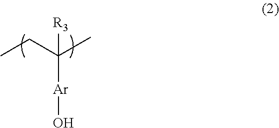

In Formula (2), R₃ represents a hydrogen atom or a methyl group.

Ar represents an aromatic ring.

R₃ represents a hydrogen atom or a methyl group, and is preferably a hydrogen atom for the reason of developability.

Ar in Formula (2) has the same meaning as Ar in Formula (1), and a preferable range thereof is the same. The repeating unit represented by Formula (2) is preferably a repeating unit (that is, a repeating unit in Formula (2), in which R₃ is a hydrogen atom, Ar is a benzene ring) derived from hydroxy styrene, in view of sensitivity.

The resin (A) may be only formed with the repeating unit having the phenolic hydroxyl group as above, or may have a repeating unit described below in addition to the repeating unit having the phenolic hydroxyl group as above. In this case, the content of the repeating unit having the phenolic hydroxyl group is preferably 10% to 98% by mol, more preferably 30% to 97% by mol, and even more preferably 40% to 95% by mol with respect to the total repeating unit in the resin (A). Accordingly, particularly, in a case where the actinic ray-sensitive or radiation-sensitive film is a thin film (for example, in a case where a film thickness is 10 to 200 nm), dissolving speed with respect to the alkaline developer in an exposure portion in the actinic ray-sensitive or radiation-sensitive film according to the invention which is formed by using the resin (A) can be more securely decreased (that is, a dissolving speed of the actinic ray-sensitive or radiation-sensitive film using the resin (A) can be more securely controlled to the optimum). As a result, it is possible to more securely enhance the sensitivity.

Examples of the repeating unit having the phenolic hydroxyl group are provided below, but the invention is not limited thereto.

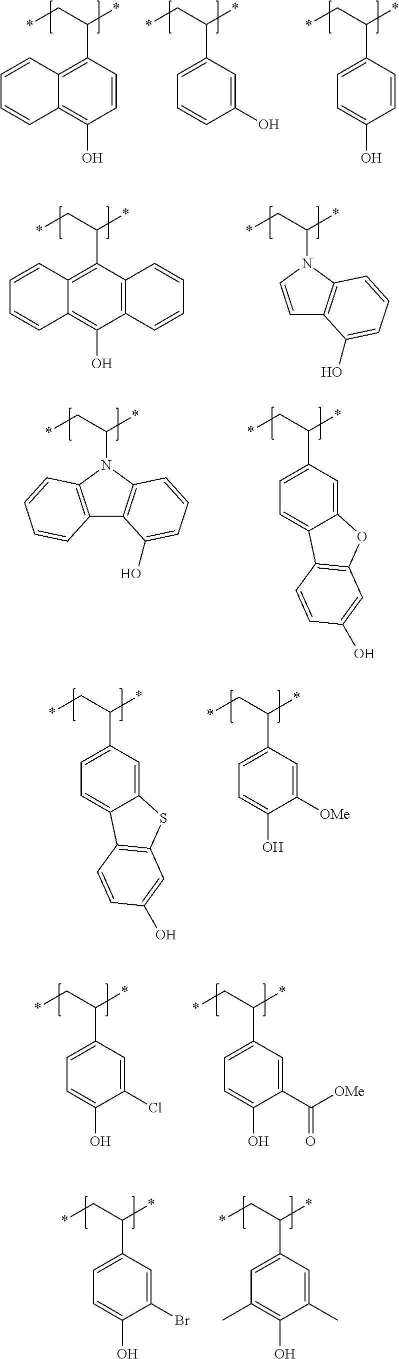

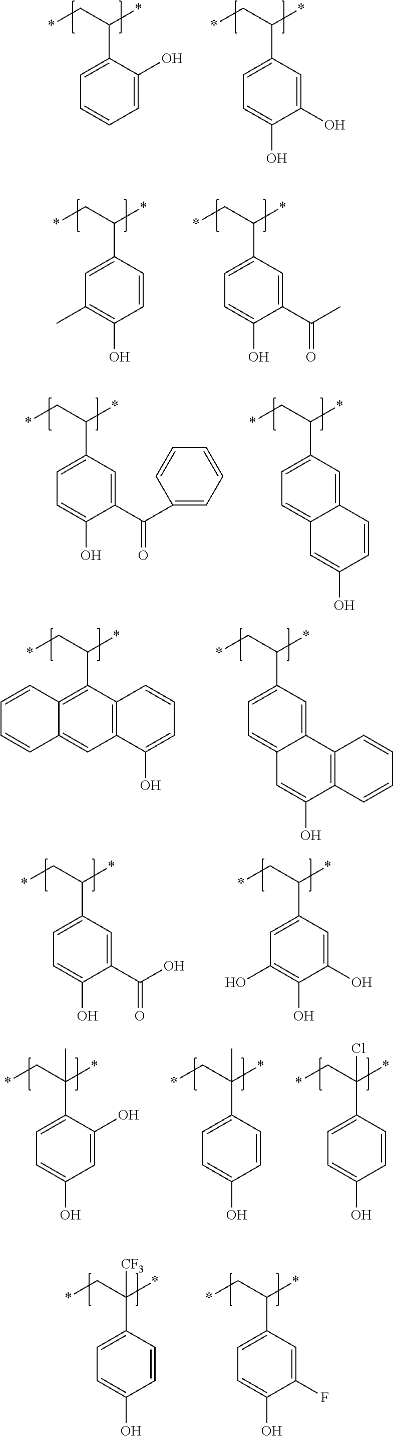

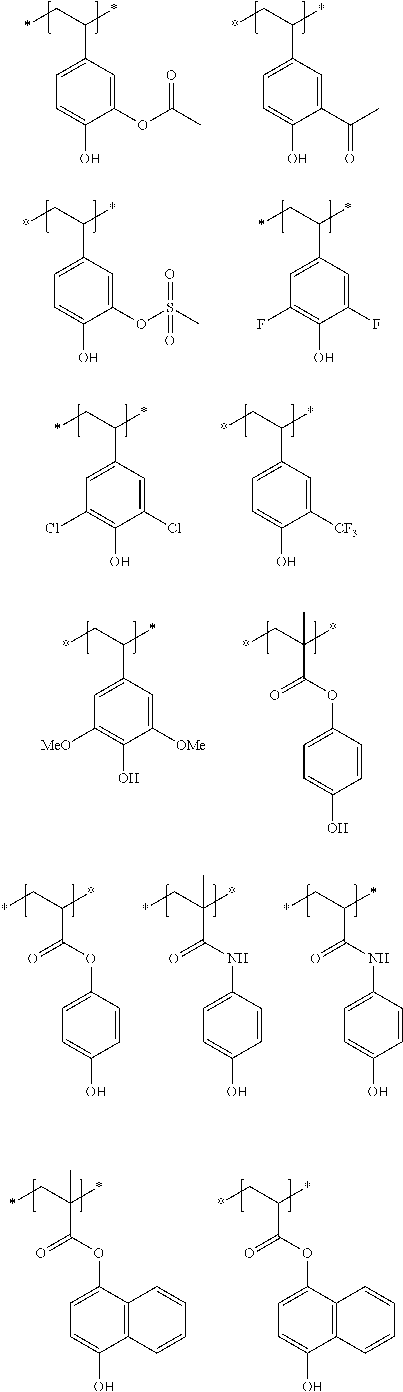

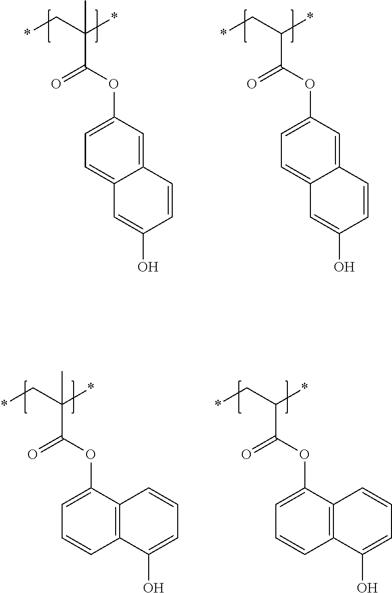

The resin (A) is a group having a non-acid decomposable polycyclic alicyclic hydrocarbon structure, and it is preferable to have a structure in which a hydrogen atom of a phenolic hydroxyl group is substituted, since a high glass transition temperature (Tg) is obtained, and dry etching resistance becomes satisfactory.

In a case where the resin (A) has the specific structure described above, the glass transition temperature (Tg) of the compound (P) becomes high, and thus an extremely strong actinic ray-sensitive or radiation-sensitive film can be formed, such that diffusion properties of an acid or dry etching resistance can be controlled. Accordingly, since diffusion properties of an acid in the exposed portion with actinic rays such as electron beams or extreme ultraviolet rays or radiation are extremely suppressed, resolving power, pattern forms, and LER in a fine pattern become further excellent. It is considered that the resin (A) having a non-acid decomposable polycyclic alicyclic hydrocarbon structure contributes further improvement of dry etching resistance.

Specifics are unclear, but it is assumed that the polycyclic alicyclic hydrocarbon structure has high donating properties of a hydrogen radical and becomes a hydrogen source at the time of decomposition of a photoacid generator, decomposition efficiency of a photoacid generator is further improved, and acid generation efficiency becomes higher. Therefore, it is considered that this contributes to more excellent sensitivity.

In the specific structure described above that may be included in the resin (A) according to the invention, an aromatic ring such as a benzene ring and a group having a non-acid decomposable polycyclic alicyclic hydrocarbon structure are linked to each other via an oxygen atom derived from the phenolic hydroxyl group. As described above, the structure contributes to high dry etching resistance and can increase the glass transition temperature (Tg) of the resin (A). Therefore, it is assumed that high resolving power is provided by these effects in combination.

According to the invention, non-acid decomposable properties mean properties of not causing decomposition reaction by an acid generated by an acid generator.

Specifically, the group having the non-acid decomposable polycyclic alicyclic hydrocarbon structure is preferably a group stable to an acid and an alkali. The group stable to an acid and an alkali means a group which does not exhibit acid decomposable properties and alkali decomposable properties. Here, the acid decomposable properties mean properties of causing decomposition reaction by an action of an acid generated by an acid generator, and an example of the group exhibiting the acid decomposable properties includes an acid decomposable group that is described in the “repeating unit having the acid decomposable group” described below.

The alkali decomposable properties mean properties of causing decomposition reaction by an action of an alkaline developer, and an example of the group exhibiting alkali decomposable properties includes a group that is included in a resin which is suitably used in the positive actinic ray-sensitive or radiation-sensitive resin composition and which is decomposed by an action of an alkali developer well-known in the related art such that a dissolution rate in an alkali developer increases (for example, a group having a lactone structure).

The group having the polycyclic alicyclic hydrocarbon structure is not particularly limited as long as the group is a univalent group having a polycyclic alicyclic hydrocarbon structure, and a total number of carbon atoms is preferably 5 to 40 and more preferably 7 to 30. The polycyclic alicyclic hydrocarbon structure may have an unsaturated bond in the ring.

The polycyclic alicyclic hydrocarbon structure in the group having the polycyclic alicyclic hydrocarbon structure means a structure of having plural monocyclic alicyclic hydrocarbon groups or a polycyclic alicyclic hydrocarbon structure, and may be a bridged type. As the monocyclic alicyclic hydrocarbon group, a cycloalkyl group having 3 to 8 carbon atoms is preferable, and examples thereof include a cyclopropyl group, a cyclopentyl group, a cyclohexyl group, a cyclobutyl group, and a cyclooctyl group, and, the structure having plural monocyclic alicyclic hydrocarbon group has plural items of these groups. The structure having plural monocyclic alicyclic hydrocarbon groups preferably has two to four monocyclic alicyclic hydrocarbon groups and particularly preferably has two monocyclic alicyclic hydrocarbon groups.

Examples of the polycyclic alicyclic hydrocarbon structure include bicyclo, tricyclo, or tetracyclo structures having having 5 or more carbon atoms, a polycyclic structure having 6 to 30 carbon atoms is preferable, and examples thereof include an adamantane structure, a decalin structure, a norbornene structure, a norbornene structure, a cedrol structure, an isobornane structure, a bornane structure, a dicyclopentane structure, an α-pinene structure, a tricyclodecane structure, a tetracyclododecane structure, or an androstane structure. In addition, a portion of carbon atoms in the monocyclic or polycyclic cycloalkyl group may be substituted with a hetero atom such as an oxygen atom.

Preferable examples of the polycyclic alicyclic hydrocarbon structure described above include an adamantane structure, a decalin structure, a norbornene structure, a norbornene structure, a cedrol structure, a structure having plural cyclohexyl groups, a structure of having plural cycloheptyl groups, a structure of having plural cyclooctyl groups, a structure of having plural cyclodecanyl groups, a structure of having plural cyclododecanyl groups, and a tricyclodecane structure. An adamantane structure is most preferable, in view of dry etching resistance (that is, a group of having the non-acid decomposable polycyclic alicyclic hydrocarbon structure is most preferably a group of having a non-acid decomposable adamantane structure).

Chemical formulae of these polycyclic alicyclic hydrocarbon structures (with respect to structures having plural monocyclic alicyclic hydrocarbon groups, monocyclic alicyclic hydrocarbon structures corresponding to the monocyclic alicyclic hydrocarbon groups (specifically, structures of Formulae (47) to (50) below)) are provided below.

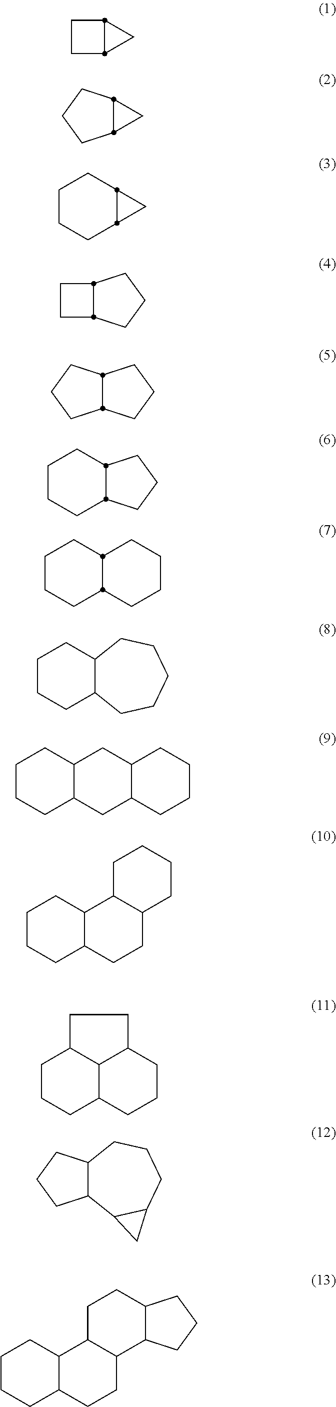

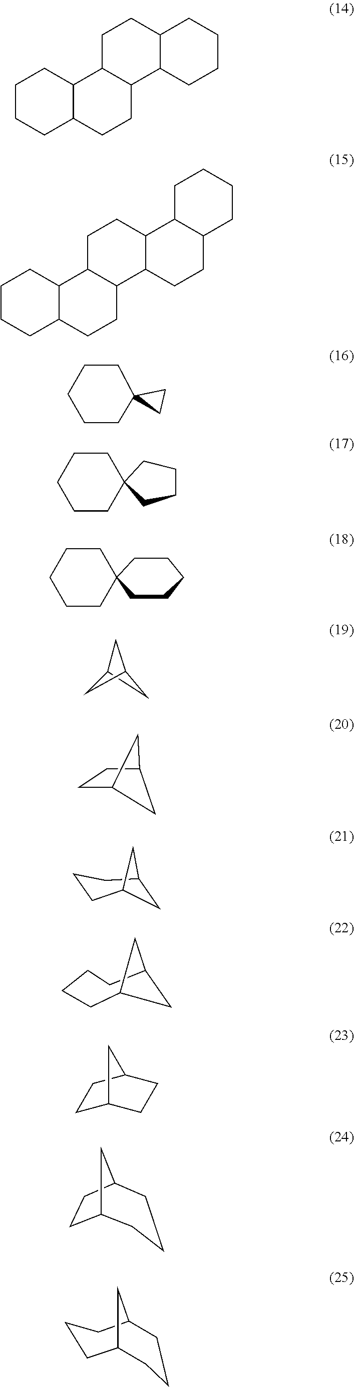

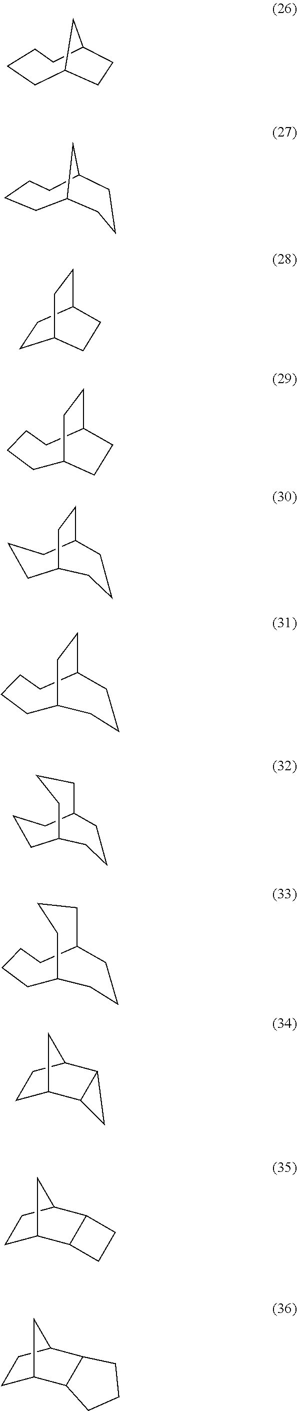

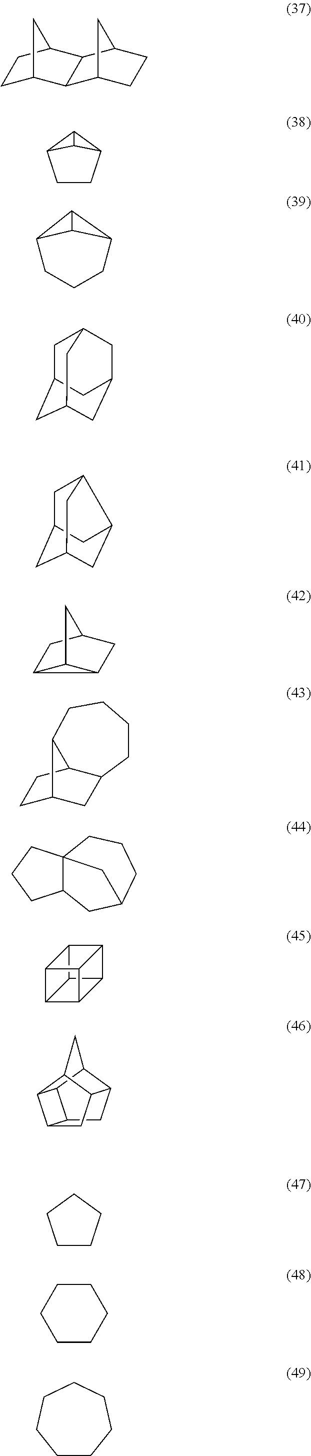

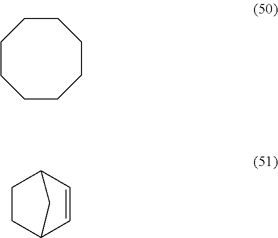 [SMILES: C1CCCCCCC1 ; C1=CC2CCC1C2]

The polycyclic alicyclic hydrocarbon structure may have a substituent, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboyxl group, a carbonyl group, a thiocarbonyl group, and an alkoxycarbonyl group (preferably having 2 to 7 carbon atoms), and groups obtained by combining these groups (a total number of carbon atoms is preferably 1 to 30, and a total number of carbon atoms is more preferably 1 to 15).

As the polycyclic alicyclic hydrocarbon structure, a structure represented by any one of Formulae (7), (23), (40), (41), and (51) above and a structure of having 2 univalent groups using any one of hydrogen atom as a direct bond in the structure of Formula (48) above are preferable, a structure represented by any one of Formulae (23), (40), and (51) and a structure of having 2 univalent groups using any one of hydrogen atom as a direct bond in the structure of Formula (48) above are more preferable, and a structure represented by Formula (40) is most preferable.

As the group having the polycyclic alicyclic hydrocarbon structure, a univalent group using any one of hydrogen atom in the polycyclic alicyclic hydrocarbon structure above as a direct bond is preferable.

A structure in which a hydrogen atom in a phenolic hydroxyl group is substituted with a group having the non-acid decomposable polycyclic alicyclic hydrocarbon structure is preferably contained in the resin (A) as a repeating unit having the structure and more preferably contained in the resin (A) as the repeating unit represented by Formula (3) below.

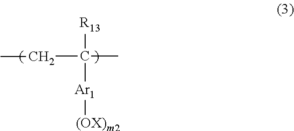

In Formula (3), R₁₃ represents a hydrogen atom or a methyl group.

X represents a group having a non-acid decomposable polycyclic alicyclic hydrocarbon structure.

Ar₁ represents an aromatic ring.

m2 represents an integer of 1 or greater.

R₁₃ in Formula (3) represents a hydrogen atom or a methyl group, and a hydrogen atom is particularly preferable.

Examples of the aromatic ring of Ar₁ of Formula (3) include an aromatic hydrocarbon ring that may have a substituent having 6 to 18 carbon atoms such as a benzene ring, a naphthalene ring, an anthracene ring, a fluorene ring, and a phenanthrene ring or examples thereof include an aromatic heterocyclic ring including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, in view of resolution, a benzene ring and a naphthalene ring are preferable and a benzene ring is most preferable.

The aromatic ring of Ar₁ may have a substituent in addition to a group represented by —OX described above, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboyxl group, and an alkoxycarbonyl group (preferably having 2 to 7 carbon atoms), and an alkyl group, an alkoxy group, and an alkoxycarbonyl group are preferable, and an alkoxy group is more preferable.

X represents a group having a non-acid decomposable polycyclic alicyclic hydrocarbon structure. Specific examples and preferable ranges of the group having the non-acid decomposable polycyclic alicyclic hydrocarbon structure represented by X are the same as those described above. X is more preferably a group represented by —Y—X₂ in Formula (4) below.

m2 is preferably an integer of 1 to 5, and most preferably 1. When m2 is 1 and Ar₁ is a benzene ring, the substitution position of —OX may be a para position, may be a meta position, or may be an ortho position with respect to the bonding position to the polymer main chain of the benzene ring, a para position or a meta position is preferable, and a para position is more preferable.

According to the invention, the repeating unit represented by Formula (3) above is preferably a repeating unit represented by Formula (4) below.

In a case where the the resin (A) having a repeating unit represented by Formula (4) is used, Tg of the resin (A) increases and forms an extremely strong actinic ray-sensitive or radiation-sensitive film. Therefore, diffusion properties of an acid and dry etching resistance can be more definitely improved.

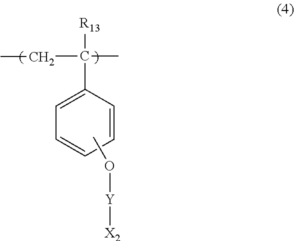

In Formula (4), R₁₃ represents a hydrogen atom or a methyl group.

Y represents a single bond or a divalent linking group.

X₂ represents a non-acid decomposable polycyclic alicyclic hydrocarbon group.

Preferable examples of the repeating unit represented by Formula (4) above are described below.

R₁₃ in Formula (4) represents a hydrogen atom or a methyl group, and a hydrogen atom is particularly preferable.

In Formula (4), Y is preferably a divalent linking group. The preferable group as a divalent linking group of Y is a carbonyl group, a thiocarbonyl group, and an alkylene group (preferably having 1 to 10 carbon atoms, more preferably having 1 to 5 carbon atoms), a sulfonyl group, —COCH₂—, or —NH—, or a divalent linking group obtained by combining these (a total number of carbon atoms is preferably 1 to 20, and a total number of carbon atoms is more preferably 1 to 10), a carbonyl group, —COCH₂—, a sulfonyl group, —CONH—, and —CSNH— are more preferable, a carbonyl group and —COCH₂— are still more preferable, and a carbonyl group is particularly preferable.

X₂ represents a polycyclic alicyclic hydrocarbon group and has non-acid decomposable properties. A total number of carbon atoms in the polycyclic alicyclic hydrocarbon group is preferably 5 to 40 and more preferably 7 to 30. The polycyclic alicyclic hydrocarbon group may have an unsaturated bond in a ring.

A polycyclic alicyclic hydrocarbon group like this is a group having plural monocyclic alicyclic hydrocarbon groups or a polycyclic alicyclic hydrocarbon group, and may be a bridged type. As the monocyclic alicyclic hydrocarbon group, a cycloalkyl group having 3 to 8 carbon atoms is preferable. Examples thereof include a cyclopropyl group, a cyclopentyl group, a cyclohexyl group, a cyclobutyl group, and a cyclooctyl group, and plural items of these groups are included. The group having plural monocyclic alicyclic hydrocarbon groups preferably includes two to four monocyclic alicyclic hydrocarbon groups, and particularly preferably includes two monocyclic alicyclic hydrocarbon groups.

An example of the polycyclic alicyclic hydrocarbon group includes a group having a bicyclo, tricyclo, or tetracyclo structure having five or more carbon atoms, and a group having a polycyclic structure having 6 to 30 carbon atoms is preferable, and examples thereof include an adamantyl group, a norbornyl group, a norbornyl group, an isobornyl group, a camphanyl group, a dicyclopentyl group, an α-pinel group, a tricyclodecanyl group, a tetracyclododecyl group, and an androstanyl group. In addition, a portion of carbon atoms in a monocyclic or polycyclic cycloalkyl group is substituted with a hetero atom such as an oxygen atom.

The polycyclic alicyclic hydrocarbon group of X₂ above is preferably an adamantyl group, a decalin group, a norbornyl group, a norbornyl group, a cedrol group, a group having plural cyclohexyl groups, a group having plural cycloheptyl groups, a group having plural cyclooctyl groups, a group having plural cyclodecanyl groups, a group having plural cyclododecanyl groups, and a tricyclodecanyl group, and an adamantyl group is most preferable, in view of dry etching resistance. Example of the chemical formula of the polycyclic alicyclic hydrocarbon structure in the polycyclic alicyclic hydrocarbon group of X₂ include the same examples of the chemical formula of the polycyclic alicyclic hydrocarbon structure in the group having the polycyclic alicyclic hydrocarbon structure described above, and preferable ranges are also the same. The polycyclic alicyclic hydrocarbon group of X₂ includes a univalent group using any one of hydrogen atoms in the polycyclic alicyclic hydrocarbon structure described above as a direct bond.

The polycyclic alicyclic hydrocarbon group may have a substituent, and examples of the substituent include the same examples described as the substituent that may be included in the polycyclic alicyclic hydrocarbon structure.

The substitution position of —O—Y—X₂ in Formula (4) may be a para position, may be a meta position, or may be a ortho position with respect to the bonding position to the polymer main chain of the benzene ring, and a para position is preferable.

According to the invention, the repeating unit represented by Formula (3) above is most preferably a repeating unit represented by Formula (4′).

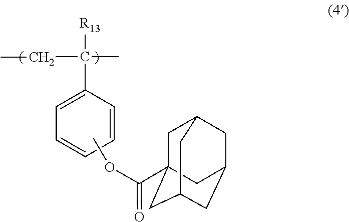

In Formula (4′), R₁₃ represents a hydrogen atom or a methyl group.

R₁₃ in Formula (4′) represents a hydrogen atom or a methyl group, and a hydrogen atom is particularly preferable.

The substitution position of the adamantylester group in Formula (4′) may be a para position, may be a meta position, or may be an ortho position with respect to the bonding position to the polymer main chain of the benzene ring, and a para position is preferable.

The specific examples of the repeating unit represented by Formula (3) are as below.

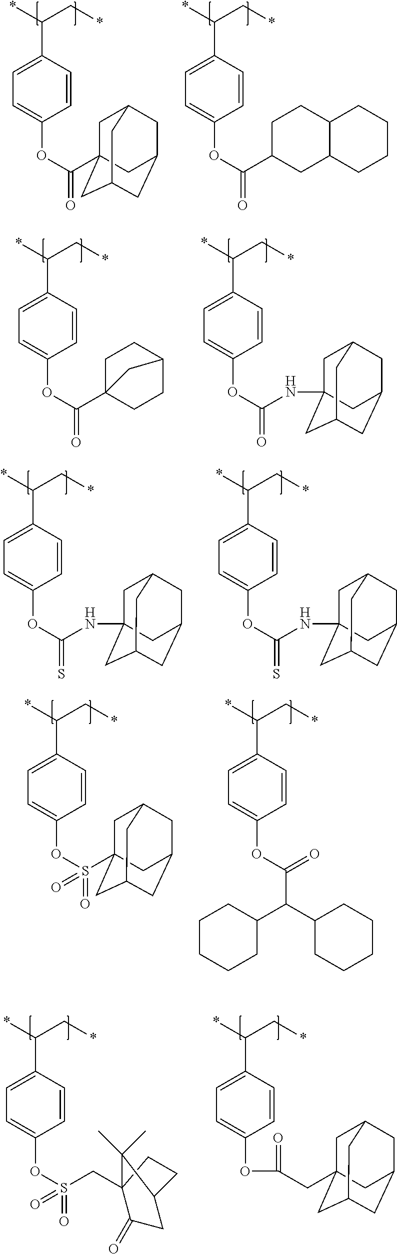

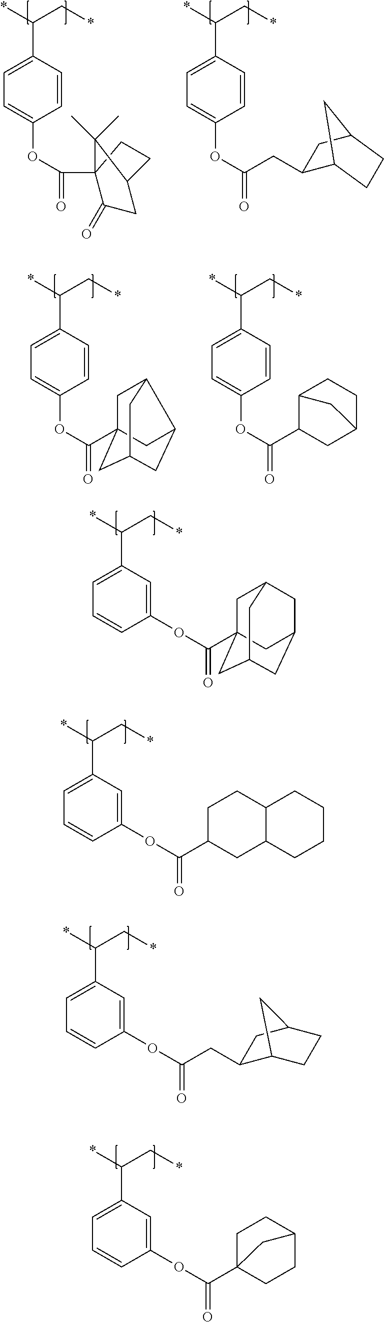

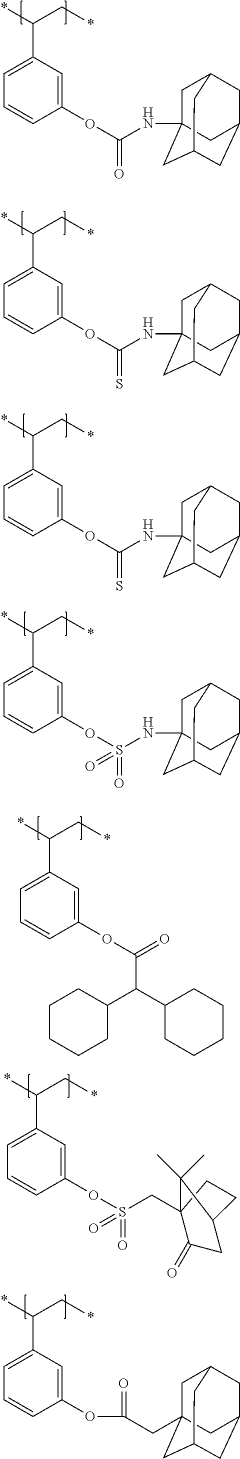

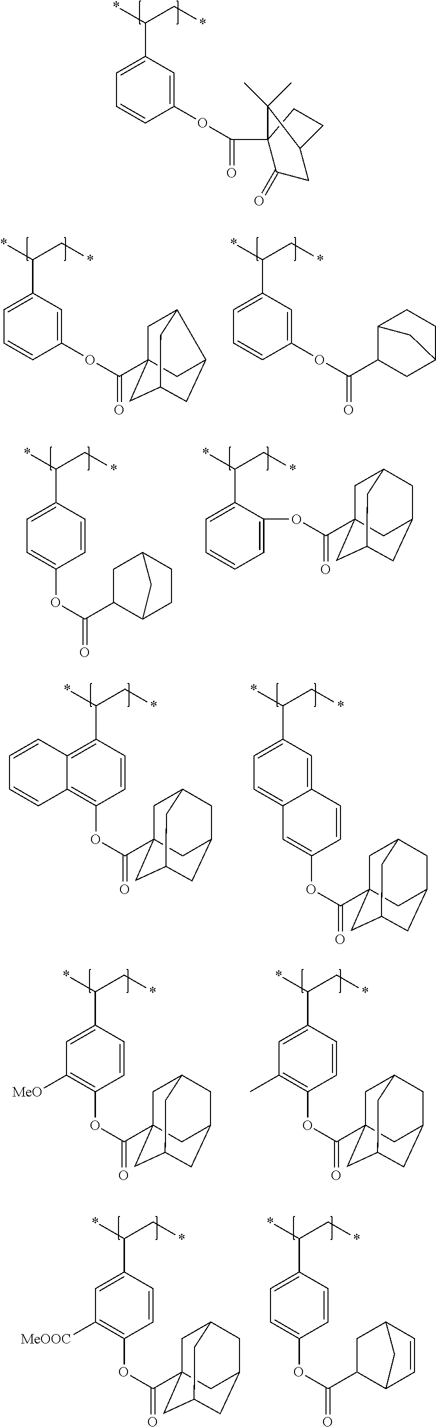

In a case where the resin (A) contains a repeating unit having a structure in which a hydrogen atom in a phenolic hydroxyl group is substituted with a group having the non-acid decomposable polycyclic alicyclic hydrocarbon structure above, the content of the repeating unit is preferably 1% to 40% by mol and more preferably 2% to 30% by mol with respect to the total repeating unit of the resin (A).

It is preferable that the resin (A) used in the invention further has a repeating unit (hereinafter, referred to as “another repeating unit”) as described below, as a repeating unit in addition to the repeating unit.

Examples of the polymerizable monomer for forming another repeating unit include styrene, alkyl-substituted styrene, alkoxy-substituted styrene, halogen-substituted styrene, O-alkylated styrene, O-acylated styrene, hydrogenated hydroxystyrene, a maleic acid anhydride, an acrylic acid derivative (acrylic acid, acrylic acid ester), a methacrylic acid derivative (a methacrylic acid, methacrylic acid ester, and the like), an N-substituted maleimide, acrylonitrile, methacrylonitrile, vinyl naphthalene, vinyl anthracene, and indene that may have a substituent.

The resin (A) may not contain another repeating unit, but in a case where another repeating unit is contained, the content of another repeating unit is generally 1% to 30% by mol, preferably 1% to 20% by mol, and more preferably 2% to 10% by mol with respect to the total repeating unit that forms the resin (A).

The resin (A) can be synthesized by a well-known radical polymerization method, a well-known anion polymerization method, or a well-known living radical polymerization method (an infester method and the like). For example, in the anion polymerization method, a polymer can be obtained by dissolving a vinyl monomer in a proper organic solvent, using a metal compound (butyl lithium and the like), and performing a reaction generally under a cooling condition.

As the resin (A), a polyphenol compound manufactured by condensation reaction of a compound containing aromatic ketone or aromatic aldehyde, and one to three phenolic hydroxyl groups (for example, JP2008-145539A), a calixarene derivative (for example, JP2004-18421A), a Noria derivative (for example, JP2009-222920A), and a polyphenol derivative (for example, JP2008-94782A) can be applied, and the resin (A) may be synthesized by performing modification with a polymer reaction.

The content (a total when plural types are included) of the repeating unit having an acid decomposable group in the acid decomposable resin is preferably in the range of 3% to 90% by mol, more preferably in the range of 5% to 80% by mol, and particularly preferably in the range of 7% to 70% by mol with respect to a total repeating unit of the acid decomposable resin.

As the group having the non-acid decomposable polycyclic alicyclic hydrocarbon structure described above, specific examples of the resin (A) having the structure in which the hydrogen atom of the phenolic hydroxyl group is substituted are provided below, but the invention is not limited thereto.

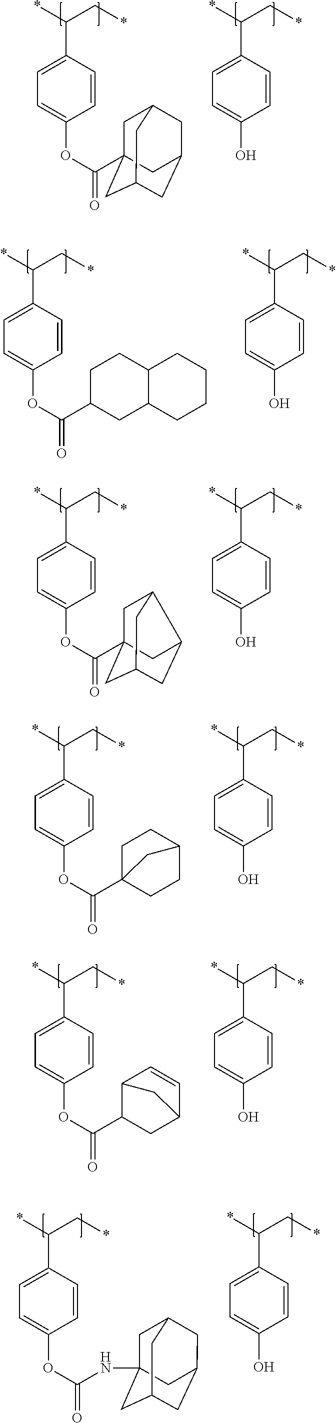

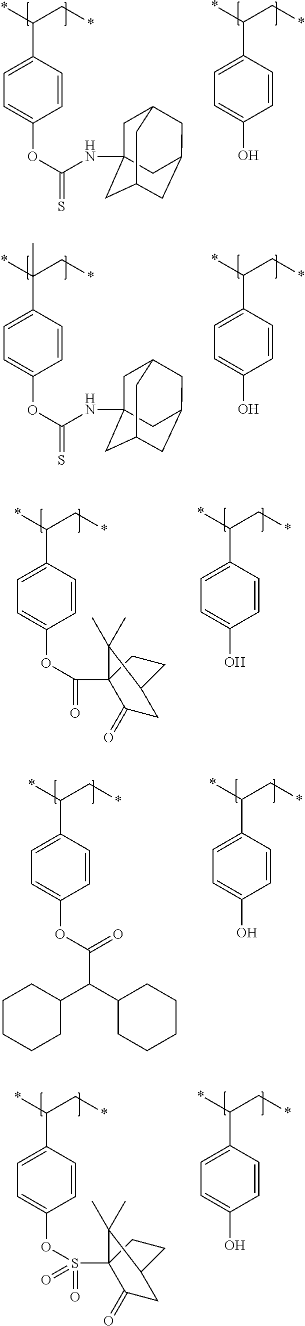

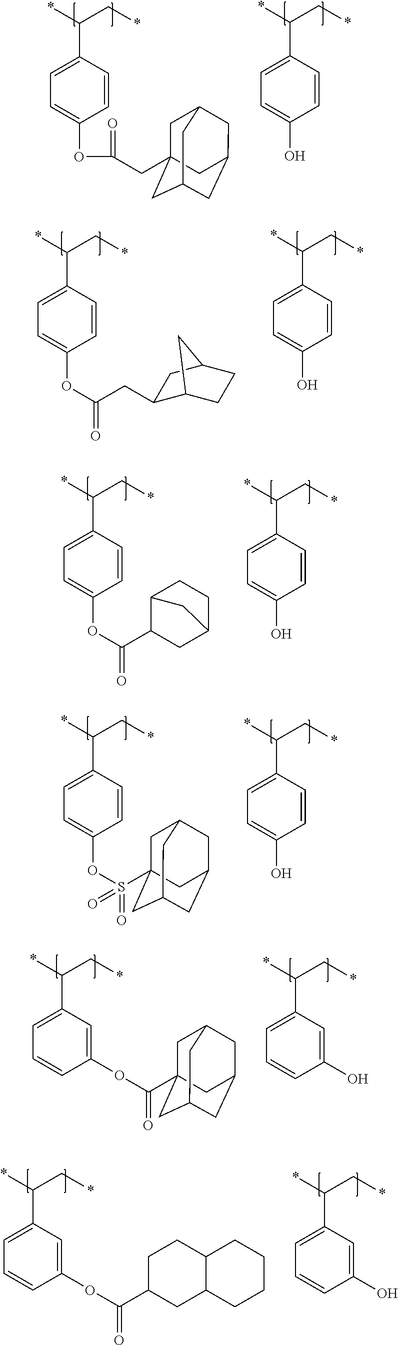

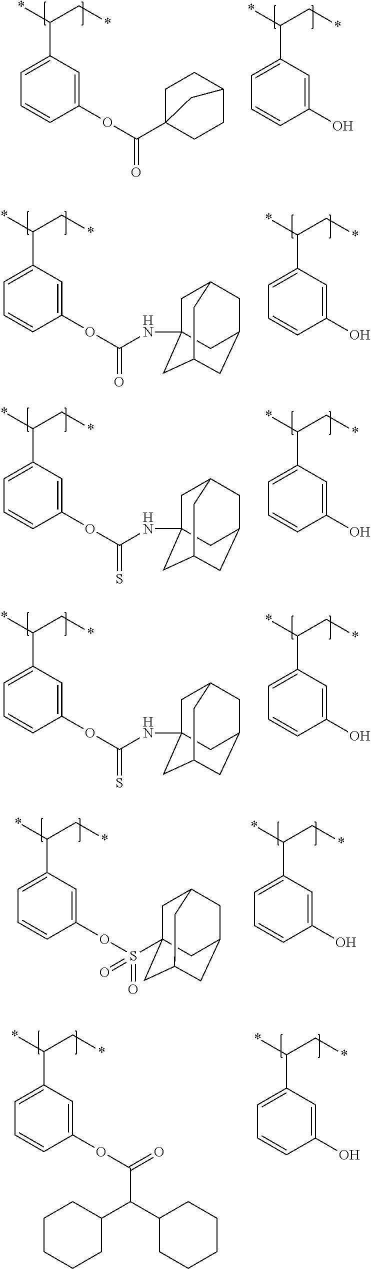

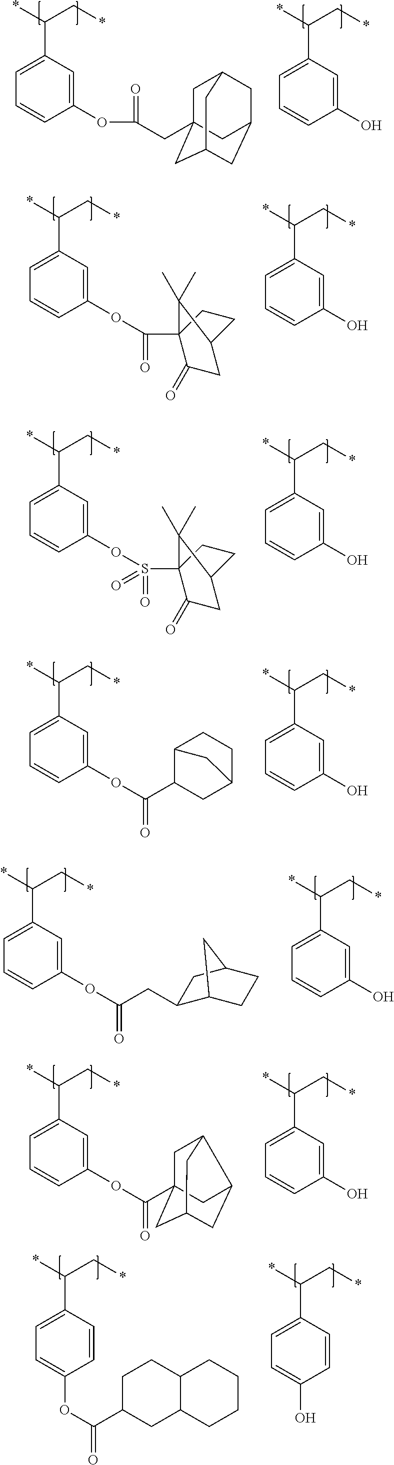

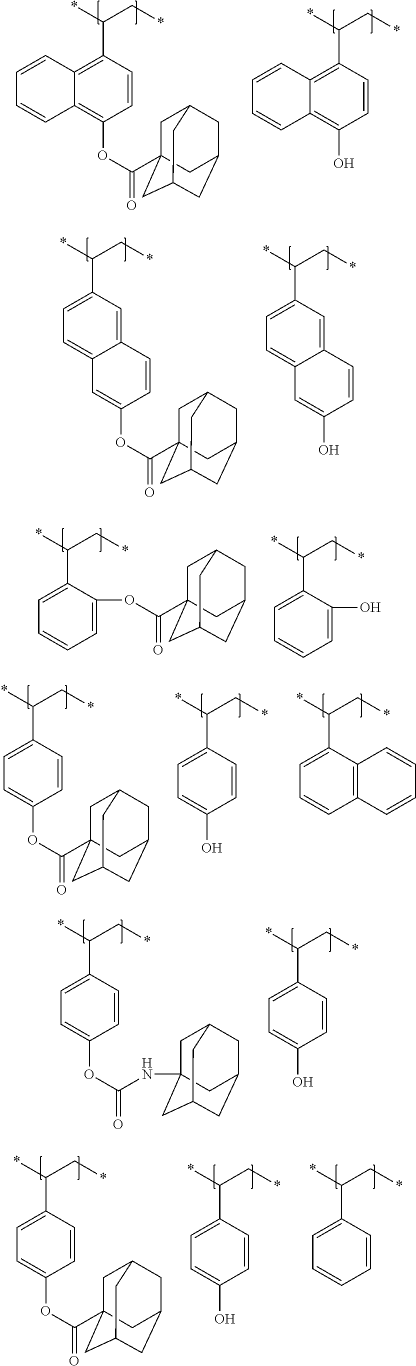

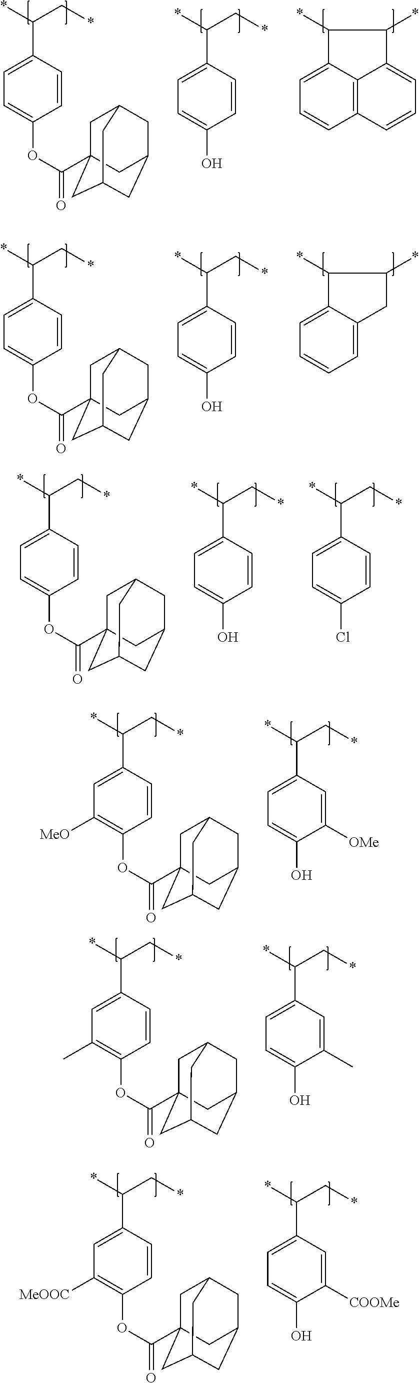

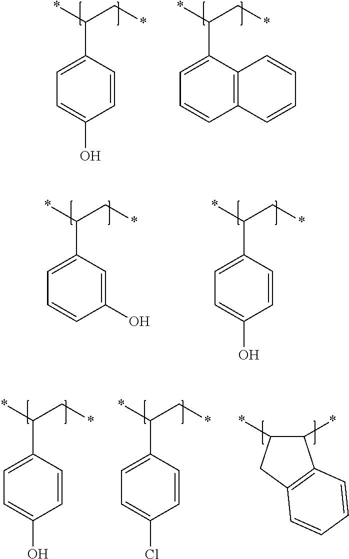

The resin (A) may have a repeating unit having an ionic structure portion that is decomposed due to irradiation of actinic rays or radiation and generates an acid at a side chain of a resin. Examples of the repeating unit include a repeating unit represented by Formula (4) below.

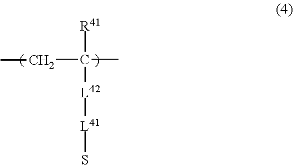

R⁴¹ represents a hydrogen atom or a methyl group. L⁴¹ represents a single bond or a divalent linking group. L⁴² represents a divalent linking group. S represents structure portion that is decomposed due to the irradiation of actinic rays or radiation and generates an acid at a side chain.

Specific examples of the resin (A) as the acid decomposable resin described above are provided below, but the invention is not limited thereto.

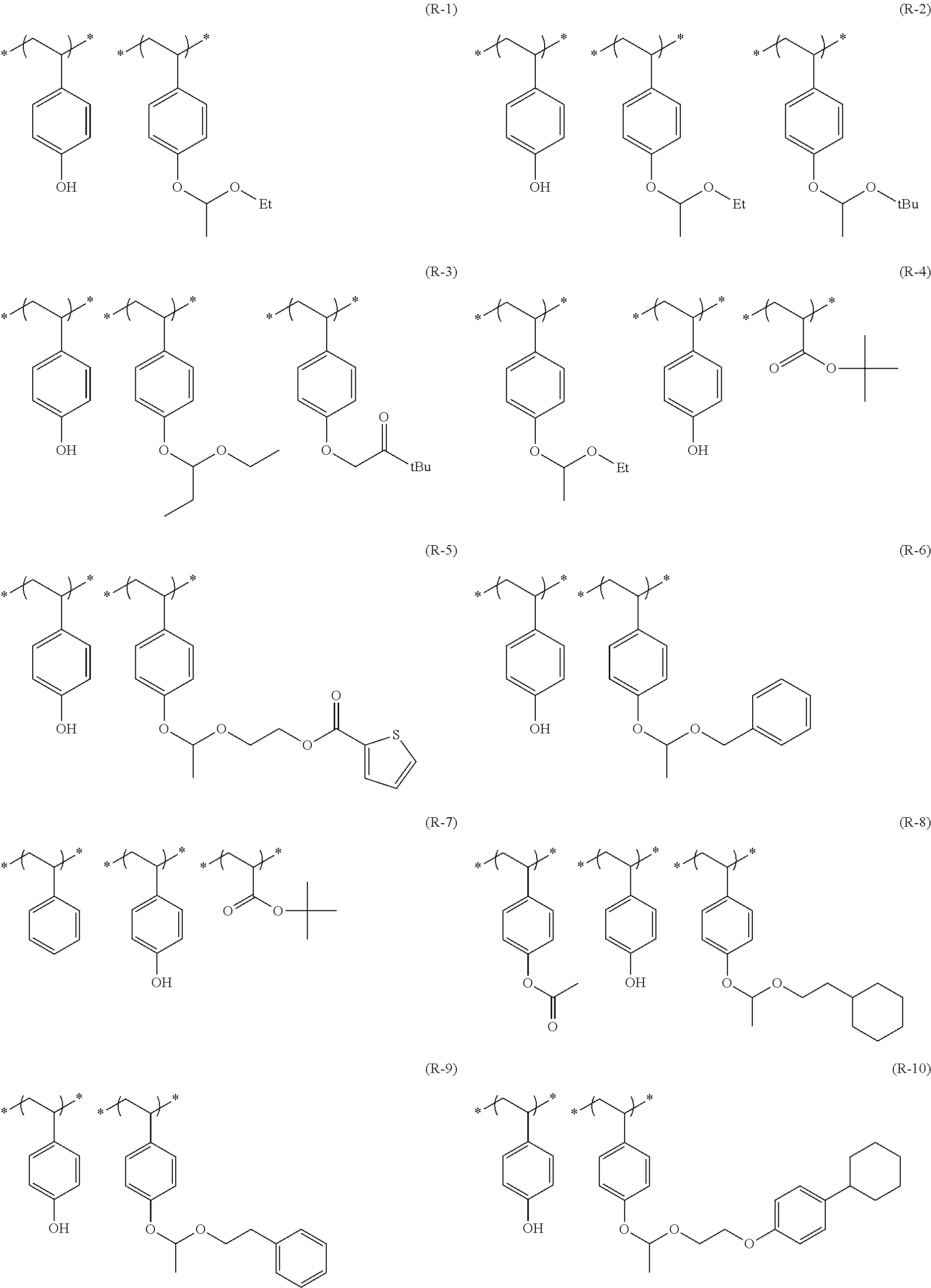

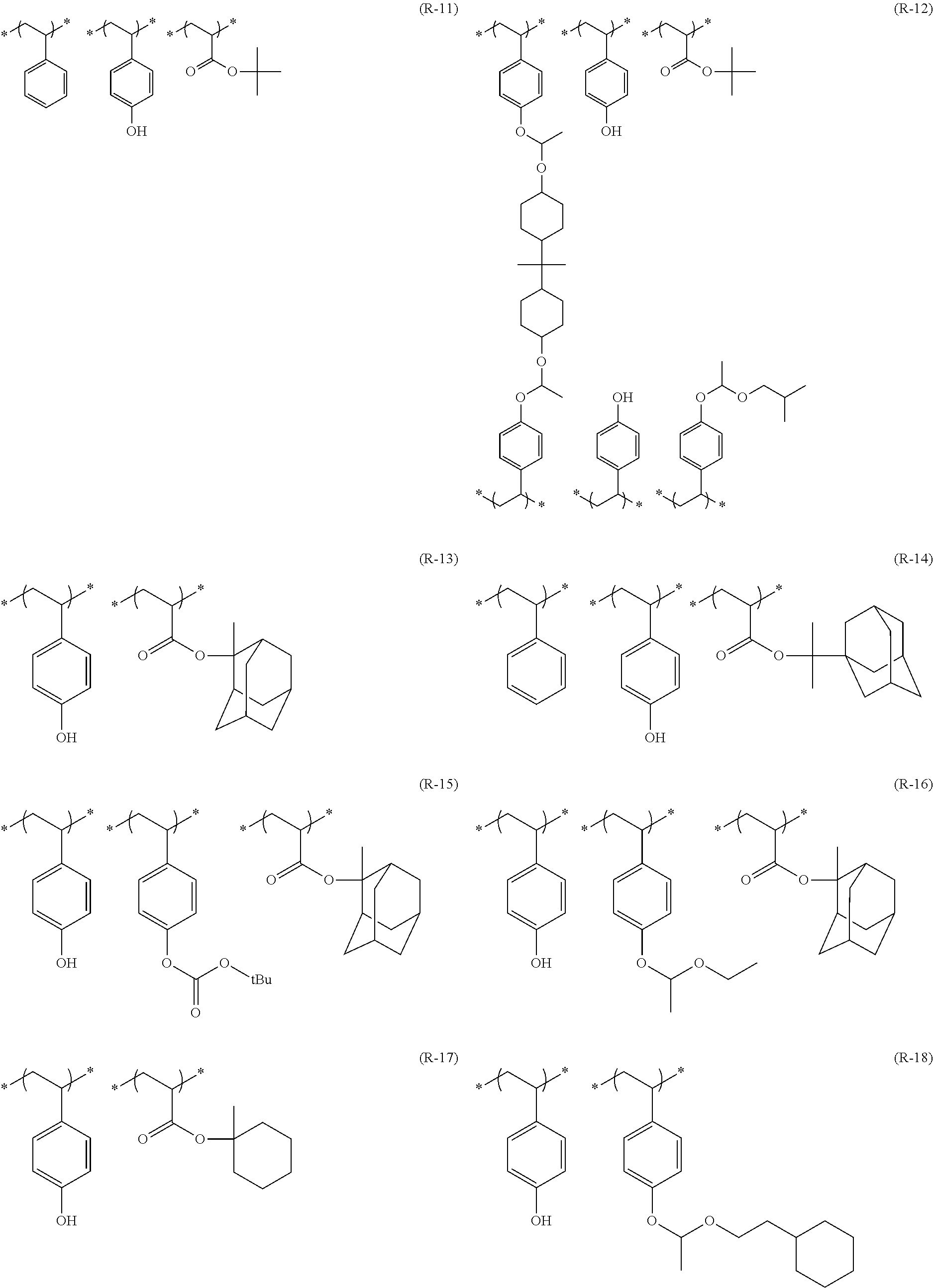

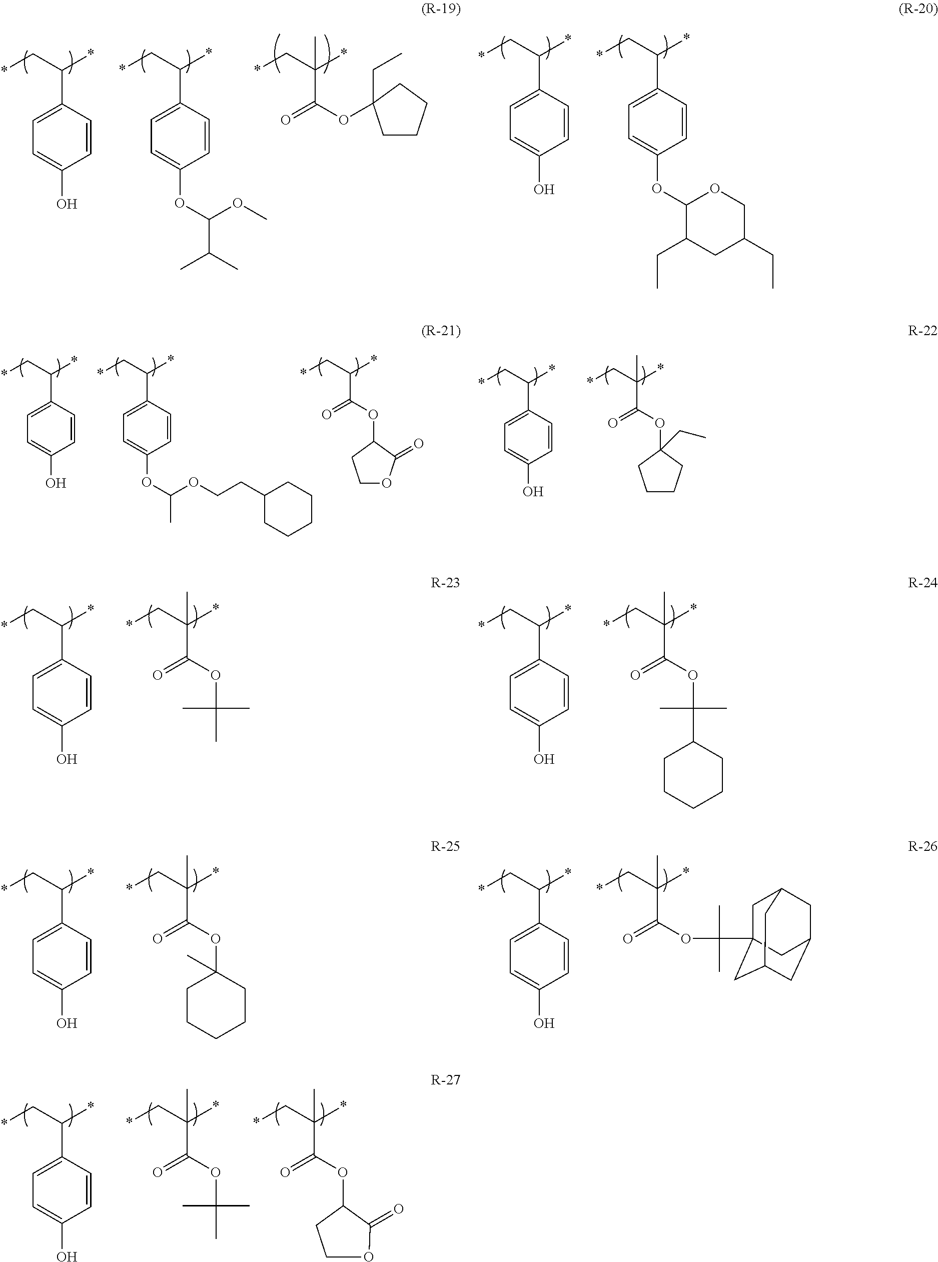

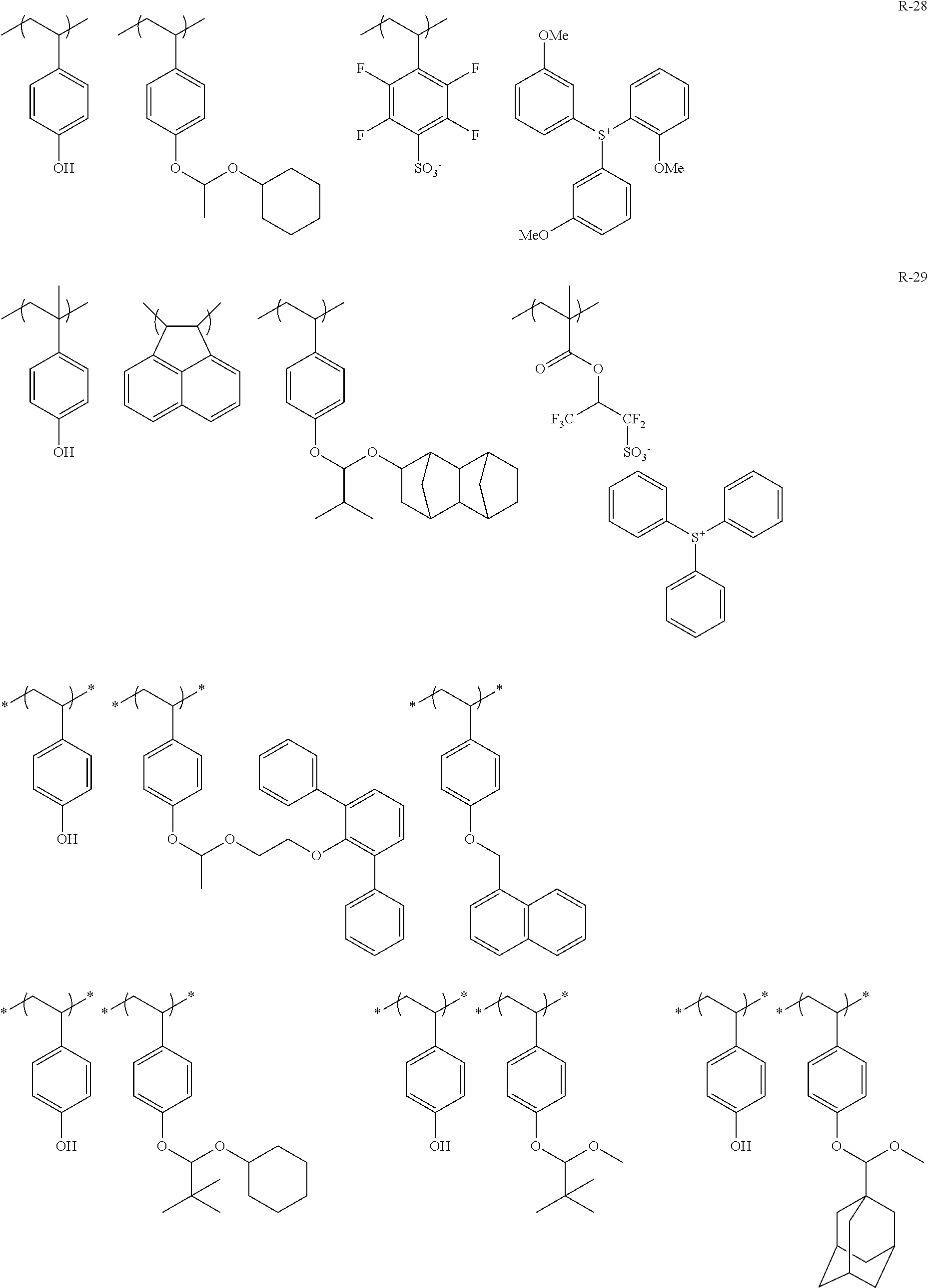

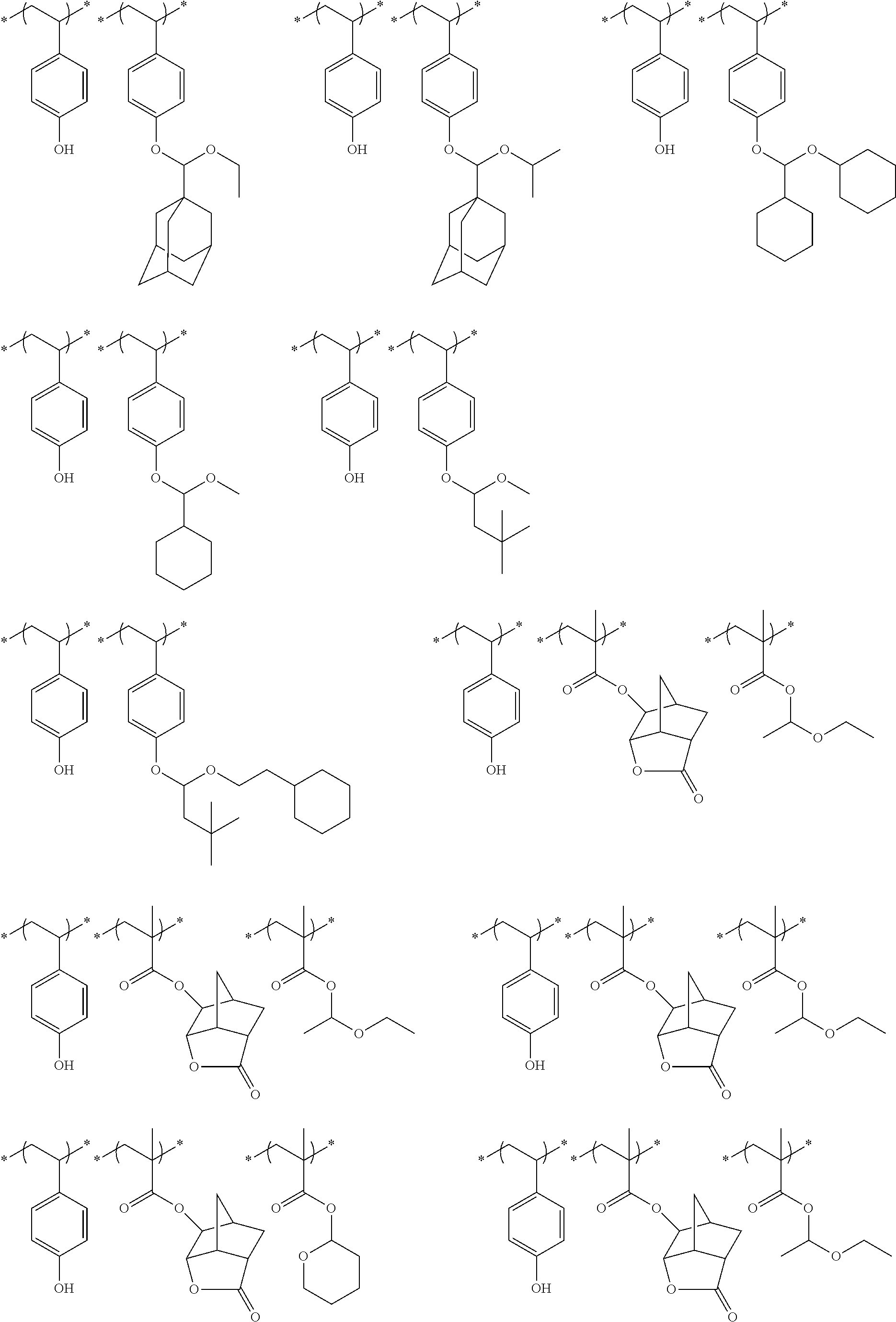

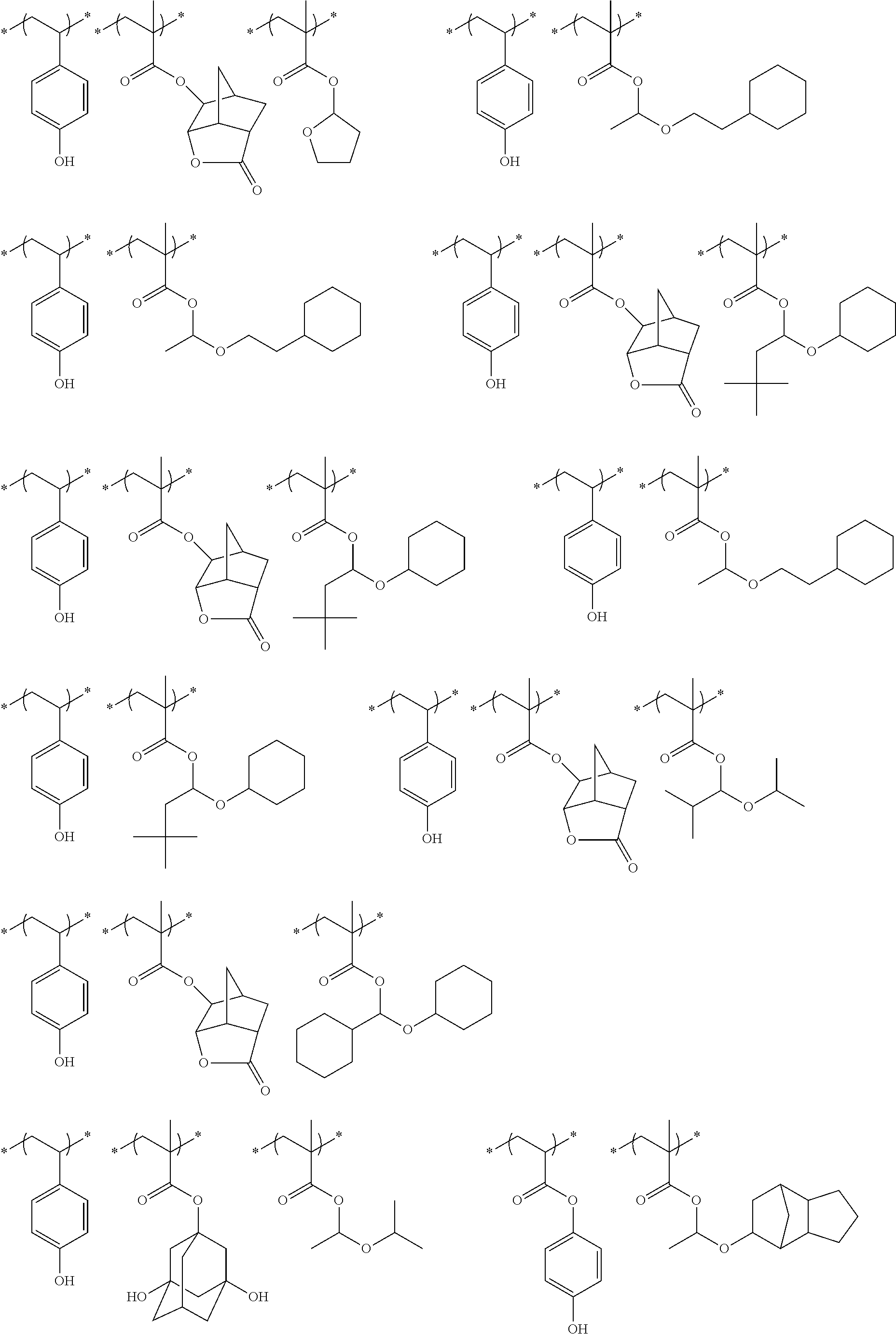

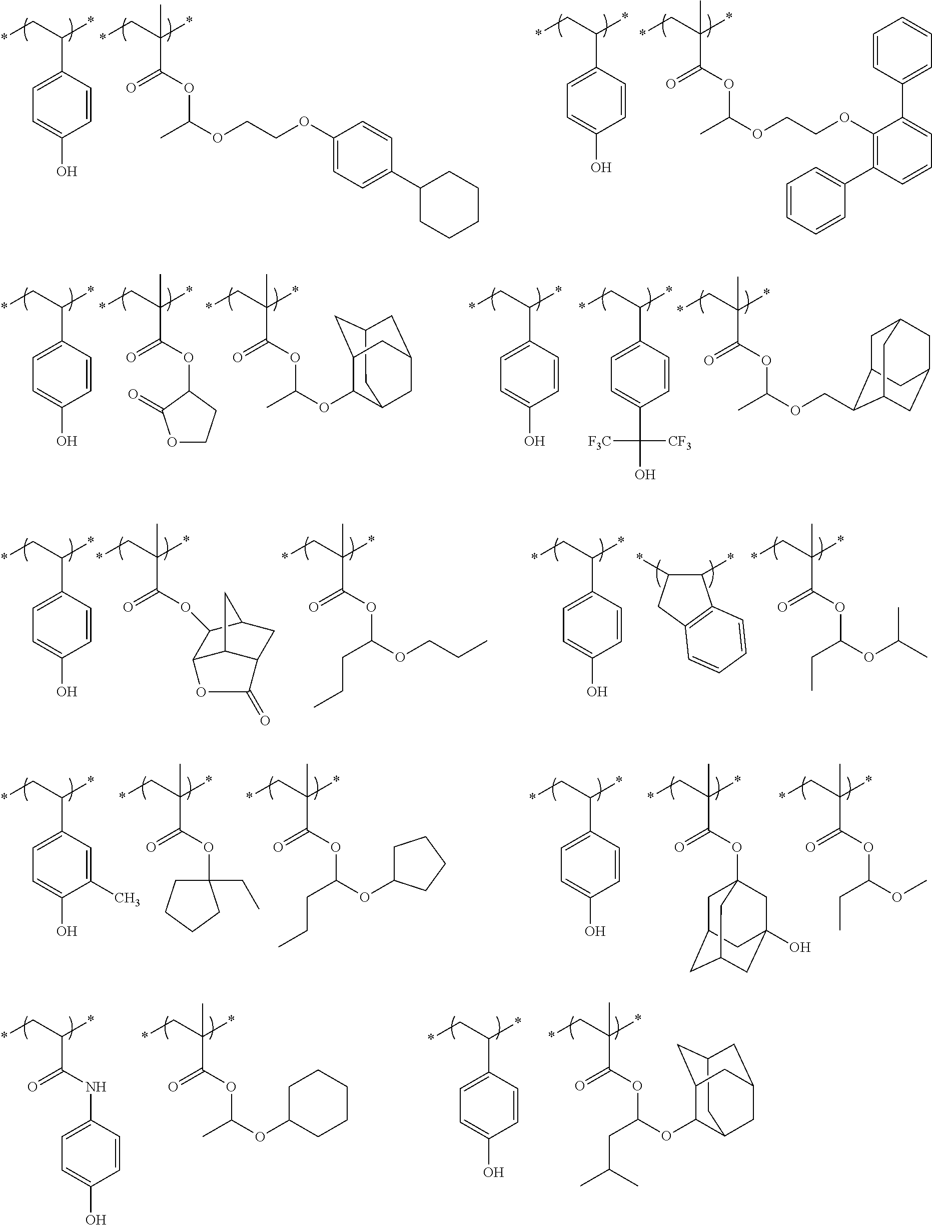

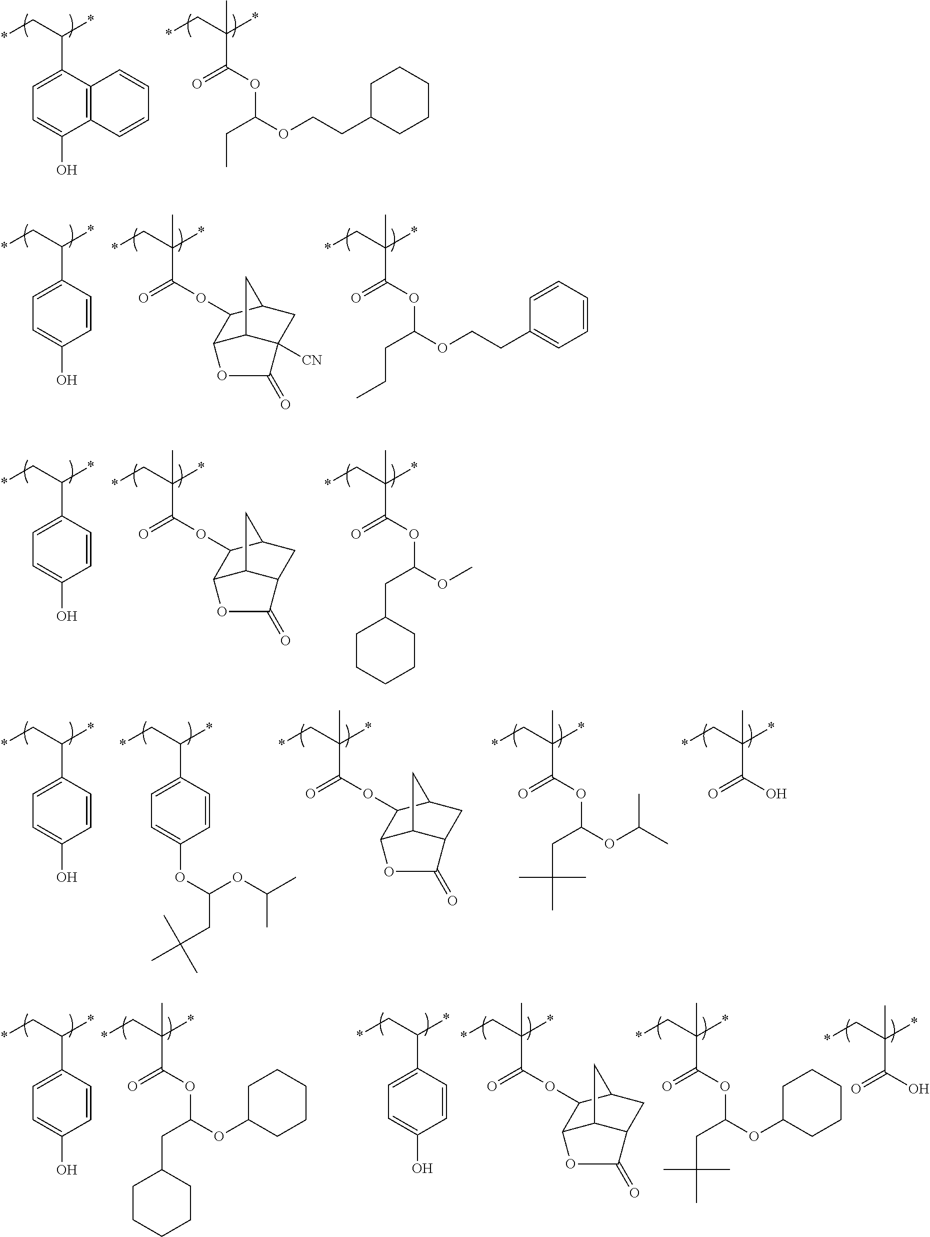

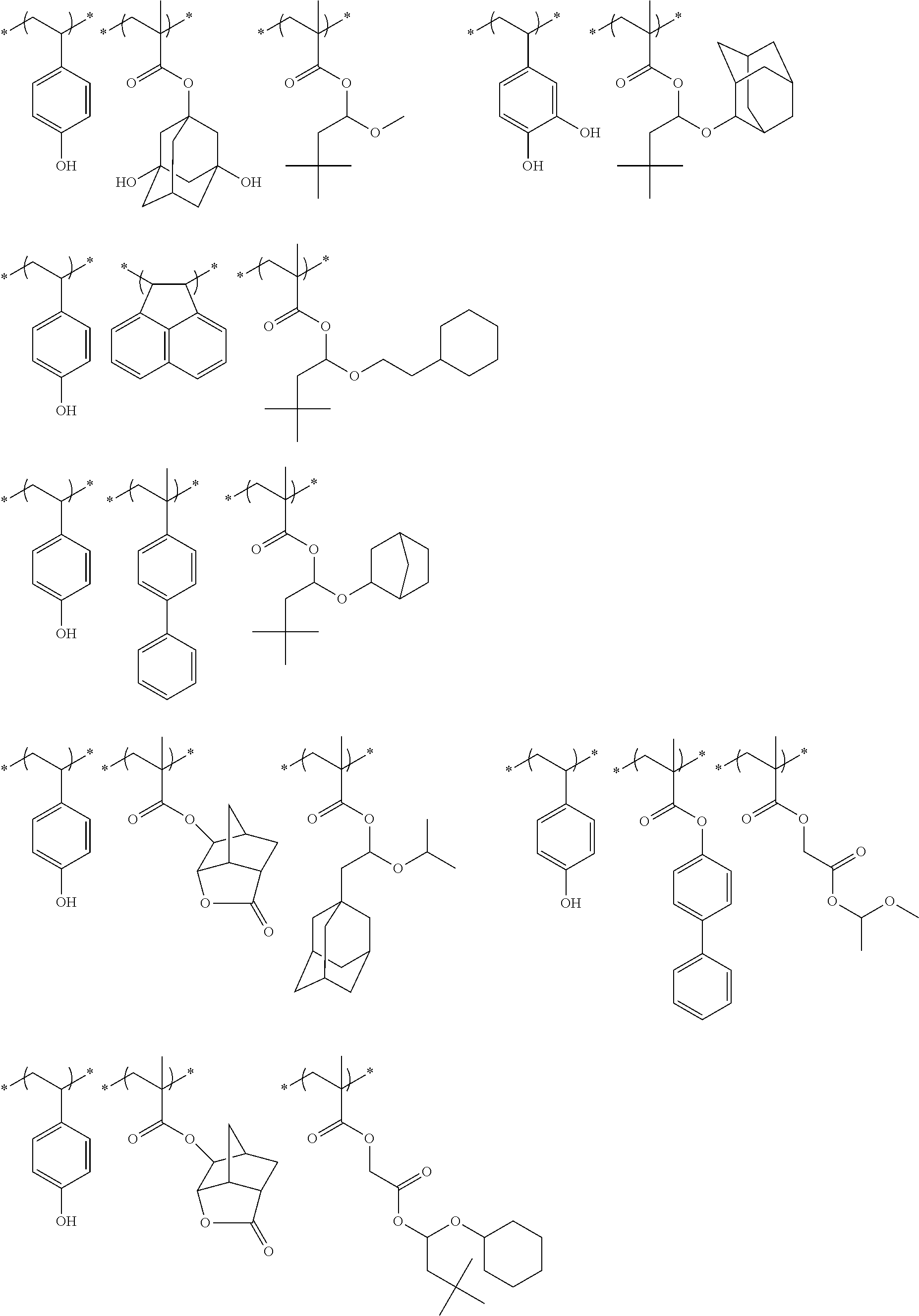

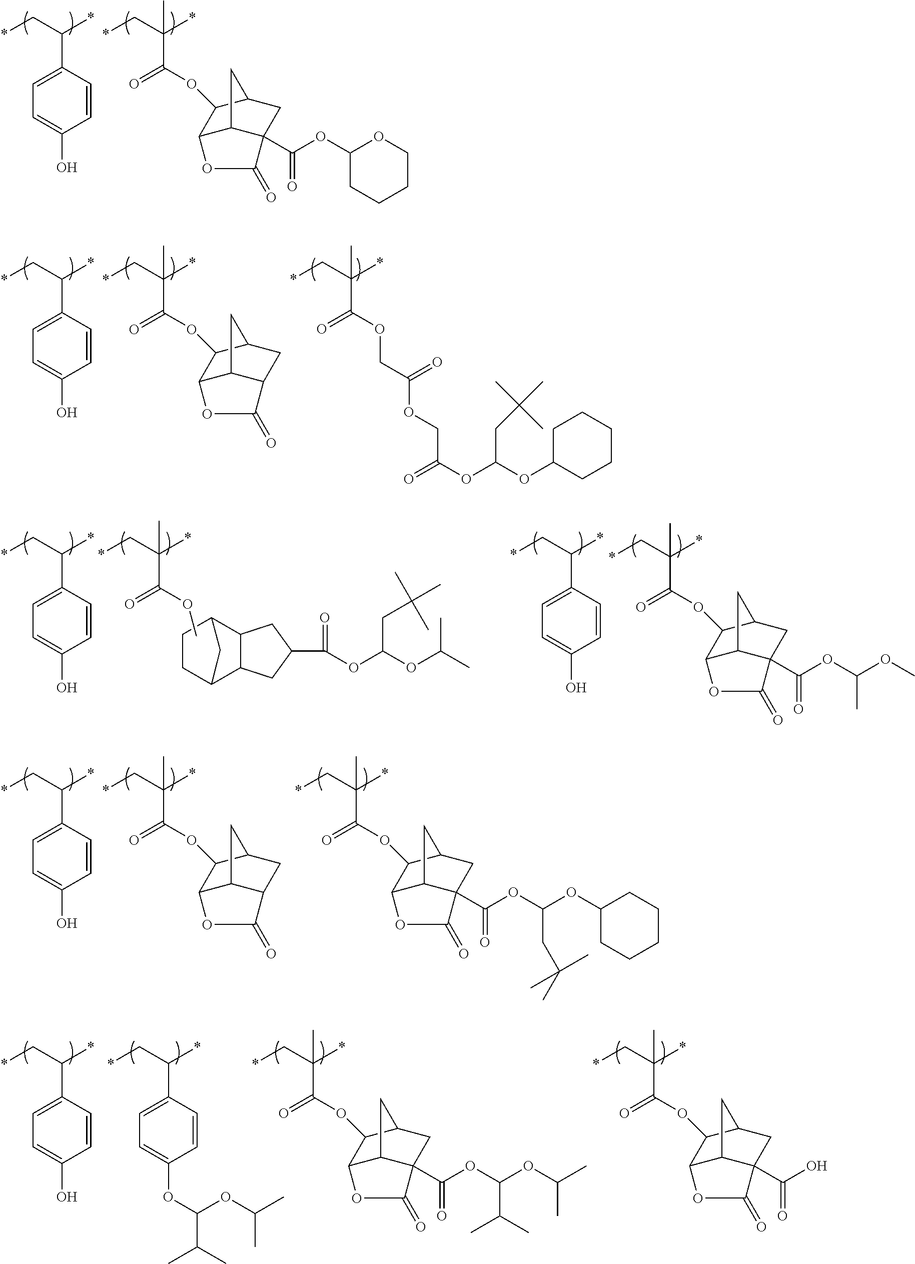

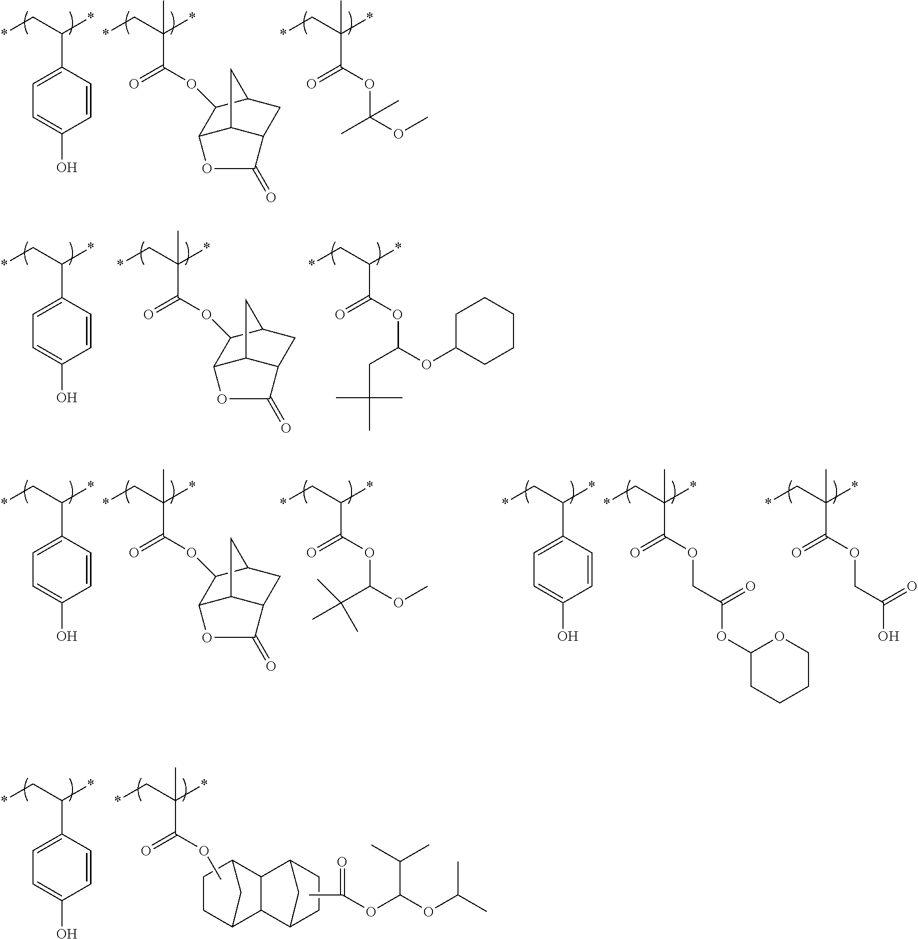

In the specific examples above, tBu represents a t-butyl group. The content ratio of the group that can be decomposed by an acid is calculated by a formula B/(B+S) with the number (B) of groups that can be decomposed by acid in a resin and the number (S) of alkaline soluble groups that are not protected with groups that are left by an acid. The content ratio thereof is preferably 0.01 to 0.7, more preferably 0.05 to 0.50, and still more preferably 0.05 to 0.40.

The resin according to the invention may have a monocyclic or polycyclic alicyclic hydrocarbon structure. Particularly, in a case where the composition according to the invention is irradiated with ArF excimer laser light, the composition preferably has an alicyclic hydrocarbon structure.

This resin may have a repeating unit including at least one type selected from a lactone group or a sultone group. Particularly, in a case where the composition according to the invention is irradiated with ArF excimer laser light, it is preferable to have a repeating unit having at least one type selected from a lactone group or a sultone group. The lactone group is preferably a group having a 5-membered to 7-membered ring lactone structure, and particularly, it is preferable that a group in which another ring structure is condensed in a form of forming a bicyclo structure or a spiro structure in a 5-membered to 7-membered ring lactone structure.

An optical isomer generally exists in a repeating unit having a lactone structure, and any optical isomer may be used. One type of optical isomer may be used singly, or plural optical isomers may be used in mixture. In a case where one type of optical isomer is mainly used, an optical isomer having optical purity of 90% ee or greater is preferable, and an optical isomer having optical purity of 95% ee or greater is more preferable.

Examples of the particularly preferable repeating unit having the lactone group include repeating units described below. In a case where an optimum lactone group is selected, a pattern profile and density dependency become satisfactory. In the formula, Rx and R represent H, CH₃, CH₂OH, or CF₃.

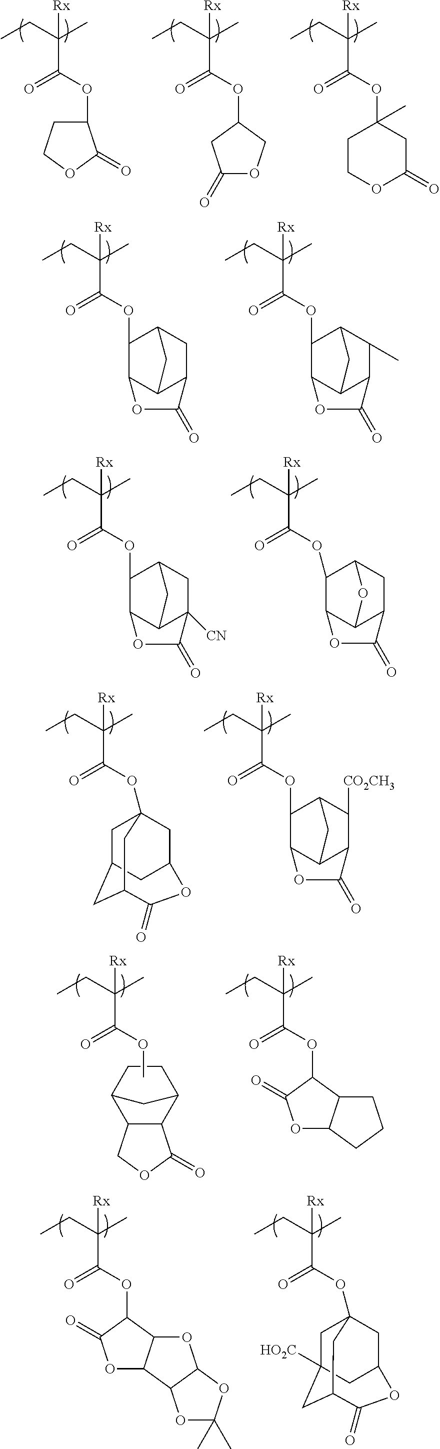

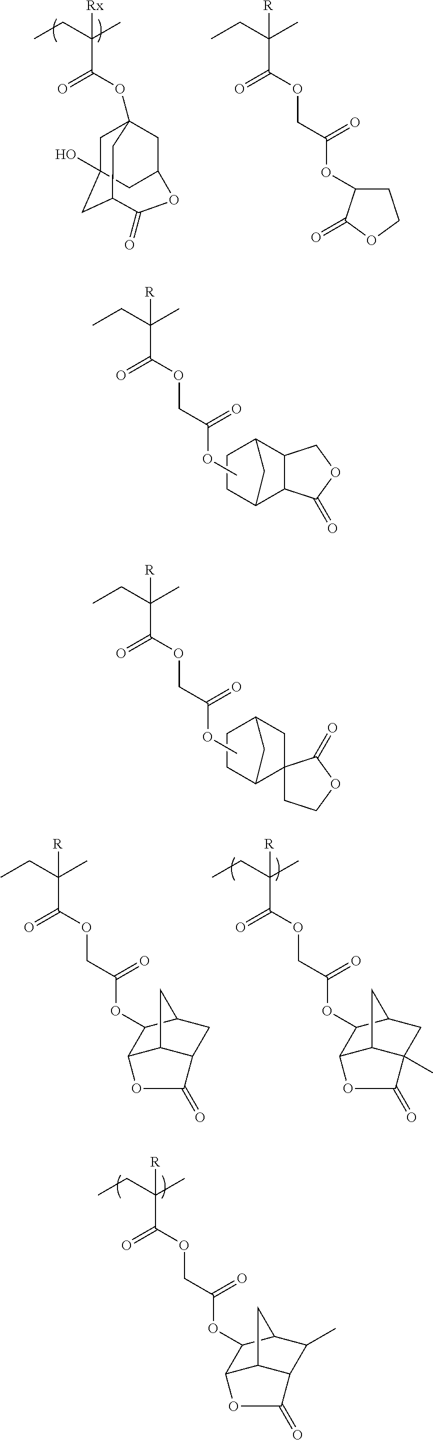

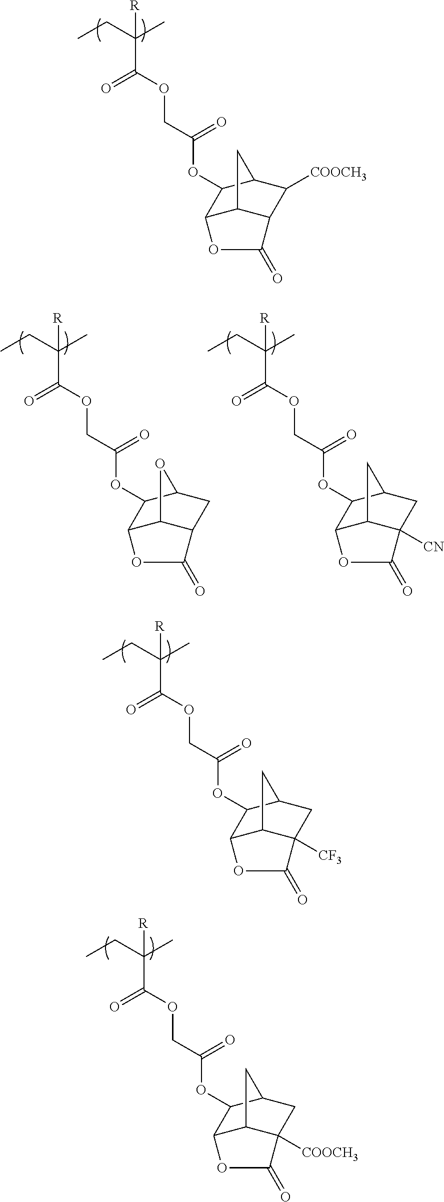

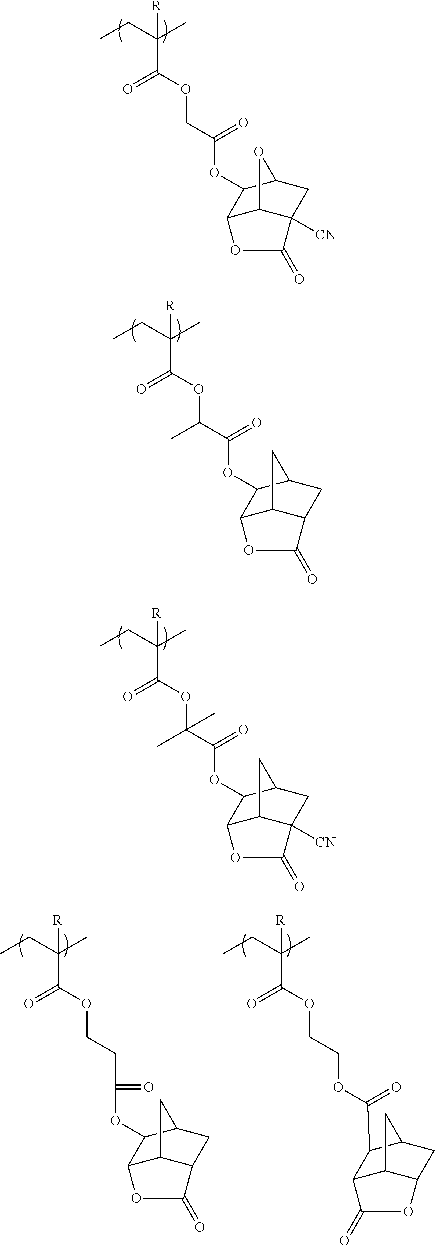

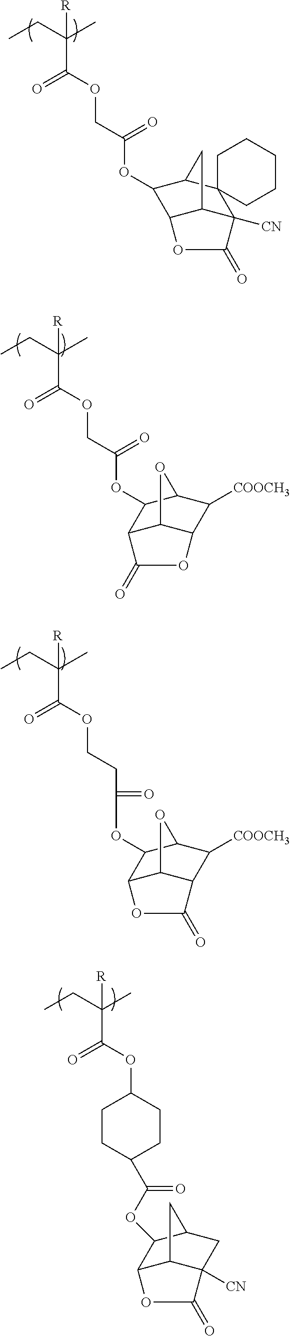

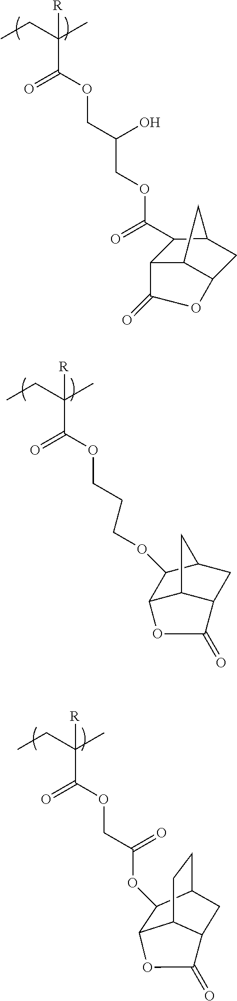

As the repeating unit that this resin includes, a repeating unit in which a sultone group is substituted with a lactone group in the repeating unit having the lactone group described above is is also preferable.

A weight average molecular weight of the resin that is decomposed due to an action of acid and of which solubility in an alkali developer increases is preferably in the range of 2,000 to 200,000, in terms of polystyrene obtained according to a GPC method. In a case where the weight average molecular weight is caused to be 2,000 or greater, heat resistance and dry etching resistance can be particularly improved. In a case where the weight average molecular weight is caused to be 200,000 or less, developing properties are particularly improved, and also film forming properties can be improved, due to decrease of viscosity of the composition.

The weight average molecular weight is more preferably in the range of 1,000 to 200,000, even more preferably in the range of 2,000 to 50,000, and particularly preferably in the range of 2,000 to 10,000. In the forming of fine patterns using electron beams, X rays, high energy rays having a wavelength of 50 nm or less (for example, EUV), the weight average molecular weight is most preferably in the range of 3,000 to 6,000. It is possible to achieve the improvement of the heat resistance and the decrease of the resolving power of the composition at the same time, by adjusting the molecular weight.

The dispersion degree (Mw/Mn) of the resin that is decomposed due to an action of acid and of which solubility in an alkali developer increases is preferably 1.0 to 3.0, more preferably 1.0 to 2.5, and still more preferably 1.0 to 1.6. In a case where the dispersion degree is adjusted, it is possible to improve, for example, line edge roughness performances. According to the invention, the weight average molecular weight (Mw) and the number average molecular weight (Mn) of the resin that is decomposed due to an action of acid and of which the solubility in the alkali developer increases can be calculated, for example, by using HLC-8120 (manufactured by Tosoh Corporation), using TSK gel Multipore HXL-M (manufactured by Tosoh Corporation, 7.8 mm ID×30.0 cm) as a column, and using tetrahydrofuran (THF) as an eluant.

In the composition according to the invention, two or more types of resins (A) may be used in combination.

A formulation ratio of the resin (A) occupying the composition according to the invention is preferably 30% to 99.9% by mass, more preferably 50% to 99% by mass, and even more preferably 60% to 99% by mass based on the total solid content.

<(B) Acid Generator>

The composition according to the invention contains a compound (hereinafter, simply referred to as an “acid generator” or a “compound (B)”) that generates acid due to irradiation of actinic rays or radiation.

A preferable embodiment of the acid generator include an onium compound. Examples of this onium compound include sulfonium salt, iodonium salt, and phosphonium salt.

As another preferable embodiment of the acid generator include a compound that generates sulfonic acid, imide acid, or methide acid due to the irradiation of actinic rays or radiation. Examples of the acid generator according to this embodiment include sulfonium salt, iodonium salt, phosphonium salt, oxime sulfonate, and imide sulfonate.

The acid generator is preferably a compound that generates acid due to irradiation of electron beams or extreme ultraviolet rays.

Examples of the preferable onium compound according to the invention include a sulfonium compound represented by Formula (7) below or an iodonium compound represented by Formula (8). These compounds preferably have at least one electron-withdrawing group in this cation portion, in view of sensitivity, resolution, a pattern shape, and LER improvement in a micro pattern. The reason is not completely clear, but the followings are considered. (i) An interaction between a compound not having an electron-withdrawing group in a cation and a photosensitive component is smaller than interaction between a compound having an electron-withdrawing group in a cation and a photosensitive component, and solubility of the resist film to the developer tends to be enhanced. Accordingly, in the comparison with a bottom of the resist film, even in a central portion or a surface layer portion of a resist film having a low reaction rate of chemical amplification reaction, a dissolving speed with respect to the developer increases, dissolving speed difference with respect to the developer in the film thickness direction of the resist film decreases, and a sectional shape of the pattern becomes better. As described above, since the sectional shape of the pattern becomes better, the sectional shape contributes to enhancement of resolution and decrease of LER. (ii) In the acid generator according to the invention, a cation has a functional group having high electron-withdrawing properties, electronic mobility in an acid generator molecule easily proceeds in the exposure by particularly using electron beams or extreme ultraviolet rays, and as a result, it is considered that an effect of sensitivity enhancement is provided.

Examples of the electron-withdrawing group include a fluorine atom, a halogen atom, a fluoroalkyl group, a cyano group, a hydroxyl group, and a nitro group. Among these, a fluorine atom is preferable.

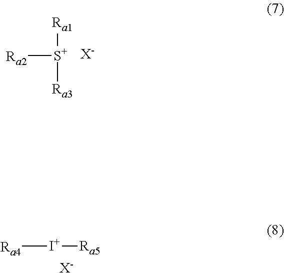

In Formulae (7) and (8),

Rₐ₁, Rₐ₂, Rₐ₃, Rₐ₄, and Rₐ₅ each independently represent an organic group.

X⁻ represents an organic anion.

Rₐ₁ to Rₐ₃ of Formula (7) above and Rₐ₄ and Rₐ₅ of Formula (8) above each independently represent an organic group, and it is preferable that at least one of Rₐ₁ to Rₐ₃, and at least one of Rₐ₄ or Rₐₛ are respectively aryl groups. The aryl group is preferably a phenyl group and a naphthyl group and even more preferably a phenyl group.

As described above, at least any one of Rₐ₁ to Rₐ₃ of Formula (7) and at least one of Rₐ₄ or Rₐ₅ of Formula (8) preferably have at least one electron-withdrawing group.

X⁻ has the same meaning as the organic anion expressed by X⁻ in Formula (I) described below.

According to one embodiment of the invention, the acid generator preferably has a triarylsulfonium cation having one or more electron-withdrawing groups and a compound that generates acid having a volume of 240 Å³ or greater due to the irradiation of actinic rays or radiation. Specific examples of the electron-withdrawing group are as described above, and a fluorine atom is particularly preferable.

This acid generator is more preferably a compound having a triarylsulfonium cation having three or more electron-withdrawing groups, it is even more preferable that respective three aryl groups in the triarylsulfonium cation have one or more electron-withdrawing groups.

It is preferable that a benzene ring that forms at least one aryl group in an aryl group in a triarylsulfonium cation of the acid generator is directly bonded to at least one electron-withdrawing group, and it is more preferable that benzene rings that form at least one aryl group of the triarylsulfonium cations in the acid generators are directly bonded to all the acid generators.

It is particularly preferable that each of the benzene rings that form aryl groups of the triarylsulfonium cations in the acid generators is directly bonded to one or more electron-withdrawing groups.

The acid generator according to the invention is preferably a compound represented by Formula (I) below.

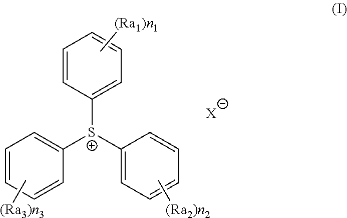

In Formula (I),

Ra₁ and Ra₂ each independently represent a substituent.

n₁ and n₂ each independently represent an integer of 0 to 5.

n₃ represents an integer of 1 to 5.

Ra₃ represents a fluorine atom or a group having one or more fluorine atoms.

Ra₁ and Ra₂ may be linked to each other to form a ring.

X⁻ represents an organic anion.

The sulfonium compound represented by Formula (I) is further described below.

As the substituents of Ra₁ and Ra₂, an alkyl group, a cycloalkyl group, an alkoxy group, a cycloalkyloxy group, an alkoxycarbonyl group, an alkylsulfonyl group, a hydroxyl group, and a halogen atom (preferably, a fluorine atom) are preferable.

The alkyl groups of Ra₁ and Ra₂ may be linear alkyl groups or branched alkyl groups. As this alkyl group, an alkyl group having 1 to 10 carbon atoms is preferable, and examples thereof include a methyl group, an ethyl group, a n-propyl group, an i-propyl group, a n-butyl group, a 2-methylpropyl group, a 1-methylpropyl group, a t-butyl group, a n-pentyl group, a neopentyl group, a n-hexyl group, a n-heptyl group, a n-octyl group, a 2-ethylhexyl group, a n-nonyl group, and a n-decyl group. Among these, a methyl group, an ethyl group, a n-butyl group, and a t-butyl group are particularly preferable.

Examples of the cycloalkyl groups of Ra₁ and Ra₂ include monocyclic or polycyclic cycloalkyl groups (preferably a cycloalkyl group having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among these, a cyclopropyl group, a cyclopentyl group, a cyclohexyl group, a cycloheptyl group, and a cyclooctyl group are particularly preferable.

Examples of the alkyl group portion of the alkoxy group of Ra₁ and Ra₂ include those exemplified as the alkyl groups of Ra₁ and Ra₂ above. As this alkoxy group, a methoxy group, an ethoxy group, a n-propoxy group, and a n-butoxy group are particularly preferable.

Examples of the cycloalkyl group portion of the cycloalkyloxy group of Ra₁ and Ra₂ include those exemplified as the cycloalkyl groups of Ra₁ and Ra₂ above. As this cycloalkyloxy group, a cyclopentyloxy group and a cyclohexyloxy group are particularly preferable.

Examples of the alkoxy group portions of the alkoxycarbonyl groups of Ra₁ and Ra₂ include those exemplified as the alkoxy groups of Ra₁ and Ra₂. As this alkoxycarbonyl group, a methoxycarbonyl group, an ethoxycarbonyl group, and a n-butoxycarbonyl group are particularly preferable.

Examples of the alkyl group portions of the alkylsulfonyl groups of Ra₁ and Ra₂ include those exemplified as the alkyl groups of Ra₁ and Ra₂ above. Examples of the cycloalkyl group portions of the cycloalkylsulfonyl groups of Ra₁ and Ra₂ include those exemplified as the cycloalkyl groups of Ra₁ and Ra₂ above. As this alkylsulfonyl group or cycloalkylsulfonyl group, a methanesulfonyl group, an ethanesulfonyl group, a n-propanesulfonyl group, a n-butanesulfonyl group, a cyclopentanesulfonyl group, and a cyclohexanesulfonyl group are particularly preferable.

Respective groups of Ra₁ and Ra₂ may further have substituents. Examples of this substituent include a halogen atom such as a fluorine atom (preferably a fluorine atom), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

The alkoxy group may be a linear shape and may be a branched shape. Examples of this alkoxy group include alkoxy groups having 1 to 20 carbon atoms such as a methoxy group, an ethoxy group, a n-propoxy group, an i-propoxy group, a n-butoxy group, a 2-methylpropoxy group, a 1-methylpropoxy group, and a t-butoxy group.

Examples of the cycloalkyloxy group include cycloalkyloxy groups having 3 to 20 carbon atoms such as a cyclopentyloxy group and a cyclohexyloxy group.

The alkoxyalkyl group may be a linear shape or a branched shape. Examples of this alkoxyalkyl group include alkoxyalkyl groups having 2 to 21 carbon atoms such as a methoxymethyl group, an ethoxymethyl group, a 1-methoxyethyl group, a 2-methoxyethyl group, a 1-ethoxyethyl group, and a 2-ethoxyethyl group.

Examples of the cycloalkyloxyalkyl group include cycloalkyloxyalkyl groups having 4 to 21 carbon atoms such as a cyclopentyloxyethyl group, a cyclopentyloxypentyl group, a cyclohexyloxyethyl group, and a cyclohexyloxypentyl group.

The alkoxycarbonyl group may be a linear shape or a branched shape. Examples of this alkoxycarbonyl group include alkoxycarbonyl groups having 2 to 21 carbon atoms such as a methoxycarbonyl group, an ethoxycarbonyl group, a n-propoxycarbonyl group, an i-propoxycarbonyl group, a n-butoxycarbonyl group, a 2-methylpropoxycarbonyl group, a 1-methylpropoxycarbonyl group, and a t-butoxycarbonyl group.

Examples of the cycloalkyloxycarbonyl group include cycloalkyloxycarbonyl groups having 4 to 21 carbon atoms such as a cyclopentyloxycarbonyl group and a cyclohexyloxycarbonyl group.

The alkoxycarbonyloxy group may be a linear shape or a branched shape. Examples of this alkoxycarbonyloxy group include alkoxycarbonyloxy groups having 2 to 21 carbon atoms such as a methoxycarbonyloxy group, an ethoxycarbonyloxy group, a n-propoxycarbonyloxy group, an i-propoxycarbonyloxy group, a n-butoxycarbonyloxy group, and a t-butoxycarbonyloxy group.

Examples of the cycloalkyloxycarbonyloxy group include cycloalkyloxycarbonyloxy groups having 4 to 21 carbon atoms such as a cyclopentyloxycarbonyloxy group and a cyclohexyloxycarbonyloxy group.

As described above, Ra₁ and Ra₂ may be linked to each other to form a ring. In this case, Ra₁ and Ra₂ preferably form a single bond or a divalent linking group, and examples of the divalent linking group include —COO—, —OCO—, —CO—, —O—, —S—, —SO—, —SO₂—, an alkylene group, a cycloalkylene group, an alkenylene group, or a combination of two or more of these, and a divalent linking group having a total carbon atoms of 20 or less is preferable. In a case where Ra₁ and Ra₂ are linked to each other to form a ring, Ra₁ and Ra₂ preferably form —COO—, —OCO—, —CO—, —O—, —S—, —SO—, —SO₂—, or a single bond, more preferably form —O—, —S—, or a single bond, and particularly preferably form a single bond.

Ra₃ is a fluorine atom or a group having a fluorine atom. Examples of the group having a fluorine atom include groups in which an alkyl group, a cycloalkyl group, an alkoxy group, a cycloalkyloxy group, an alkoxycarbonyl group, and an alkylsulfonyl group as Ra₁ and Ra₂ are substituted with a fluorine atom. Preferable examples thereof include a fluorine atom, CF₃, C₂F₅, C₃F₇, C₄F₉, C₅Fᵢᵢ, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and more preferable example thereof include CF₃.

Ra₃ is preferably a fluorine atom or CF₃ and more preferably a fluorine atom.

n₁ and n₂ are respectively 1 or greater, and at the same time, Ra₁, Ra₂, and Ra₃ are each independently preferably a fluorine atom or CF₃ and more preferably a fluorine atom.

n₁ and n₂ are each independently an integer of 0 to 5, preferably an integer of 0 to 2, and more preferably 0 or 1.

n₃ is an integer of 1 to 5, preferably 1 or 2, and more preferably 1.

In this manner, specific examples of the cation in Formula (I) include the followings.

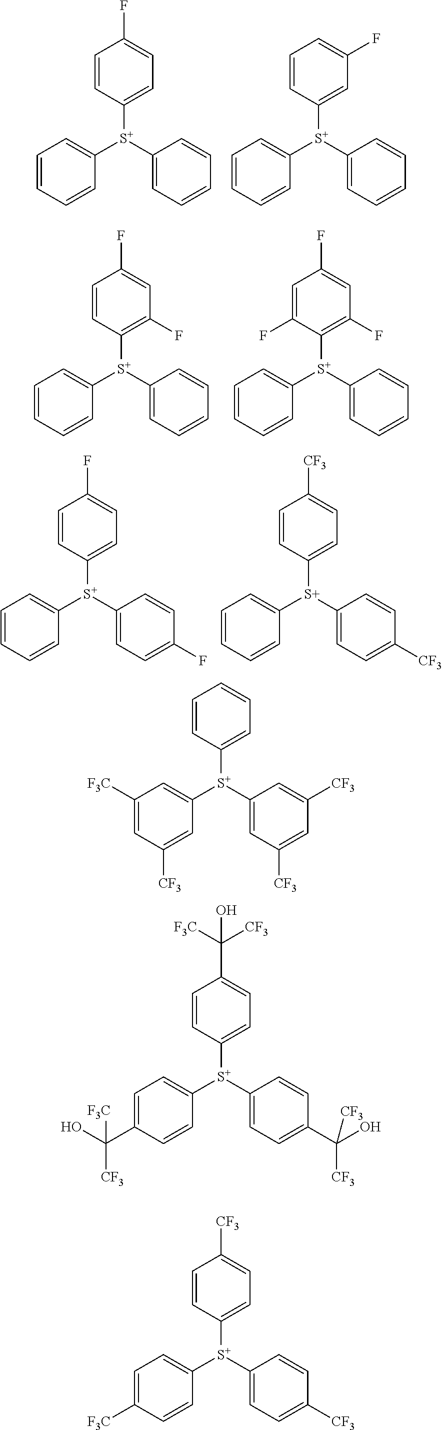

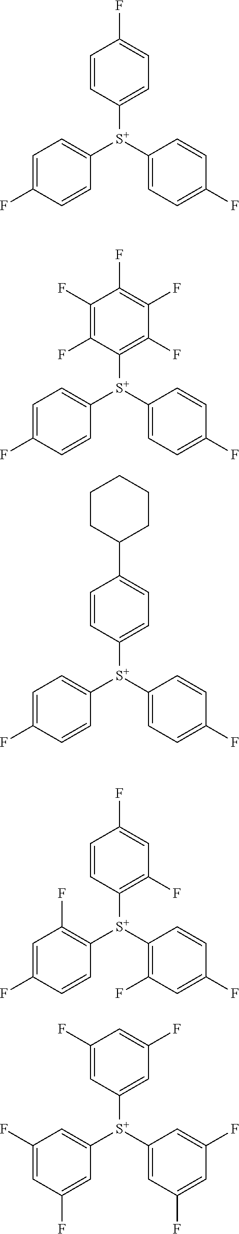 [SMILES: Fc1ccc([S+](c2ccc(F)cc2)c2ccc(F)cc2)cc1 ; Fc1ccc([S+](c2ccc(F)cc2)c2c(F)c(F)c(F)c(F)c2F)cc1 ; Fc1ccc([S+](c2ccc(F)cc2)c2ccc(C3CCCCC3)cc2)cc1 ; Fc1ccc([S+](c2ccc(F)cc2F)c2ccc(F)cc2F)c(F)c1 ; Fc1cc(F)cc([S+](c2cc(F)cc(F)c2)c2cc(F)cc(F)c2)c1]

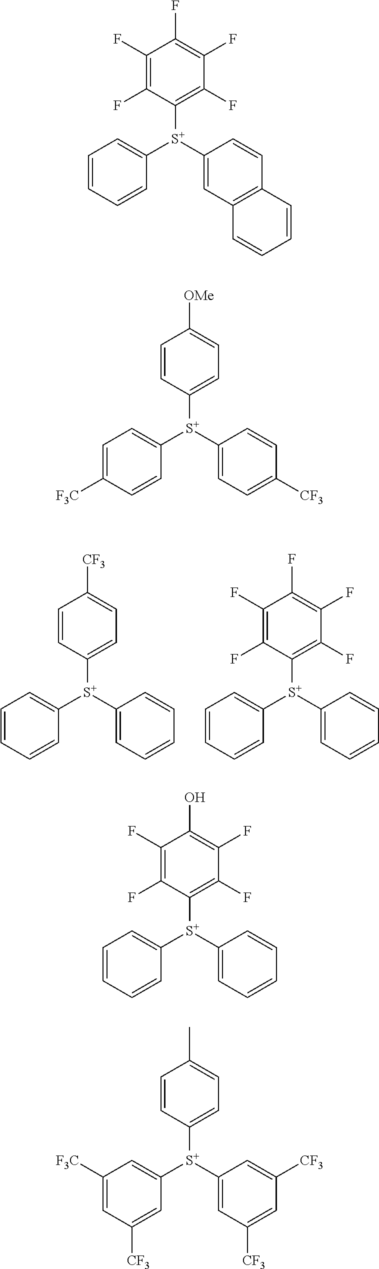 [SMILES: Fc1c(F)c(F)c([S+](c2ccccc2)c2ccc3ccccc3c2)c(F)c1F ; COc1ccc([S+](c2ccc(C(F)(F)F)cc2)c2ccc(C(F)(F)F)cc2)cc1 ; FC(F)(F)c1ccc([S+](c2ccccc2)c2ccccc2)cc1 ; Fc1c(F)c(F)c([S+](c2ccccc2)c2ccccc2)c(F)c1F ; Oc1c(F)c(F)c([S+](c2ccccc2)c2ccccc2)c(F)c1F ; Cc1ccc([S+](c2cc(C(F)(F)F)cc(C(F)(F)F)c2)c2cc(C(F)(F)F)cc(C(F)(F)F)c2)cc1]

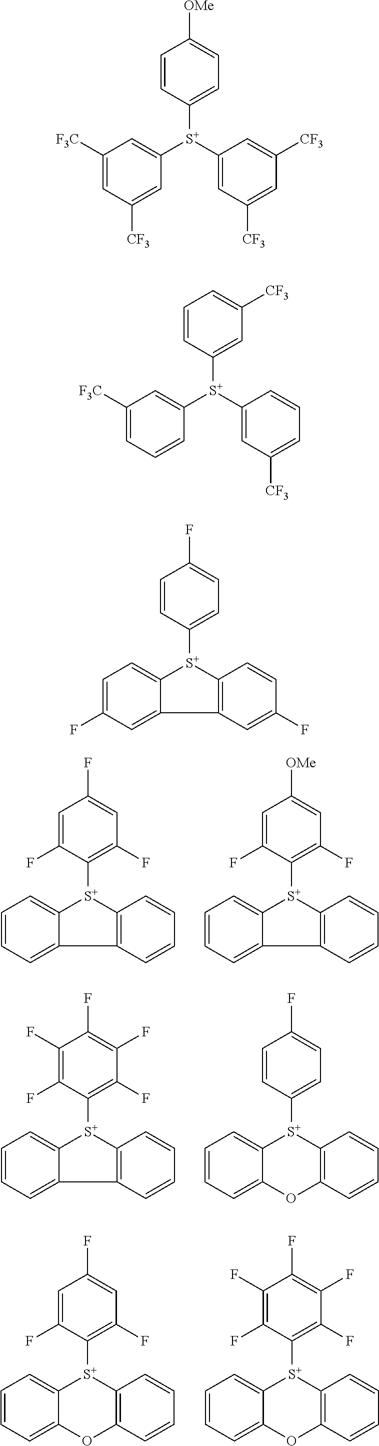

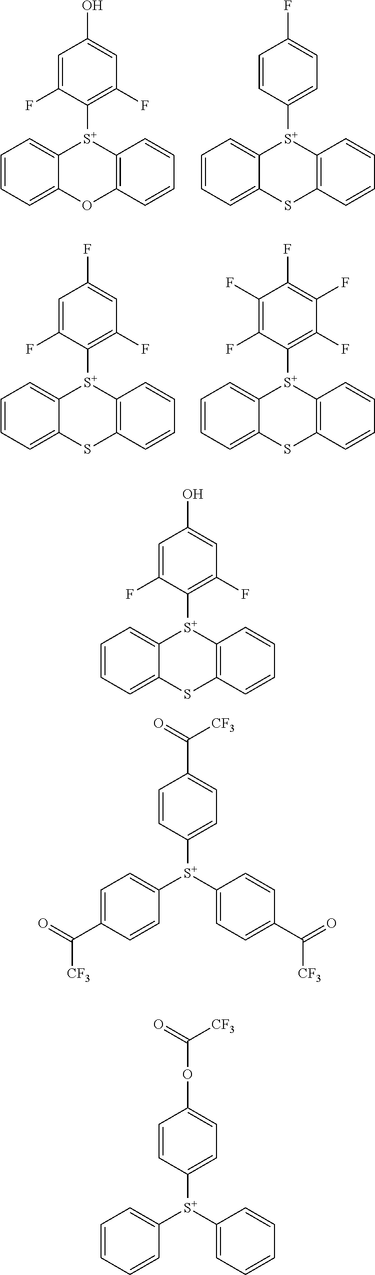

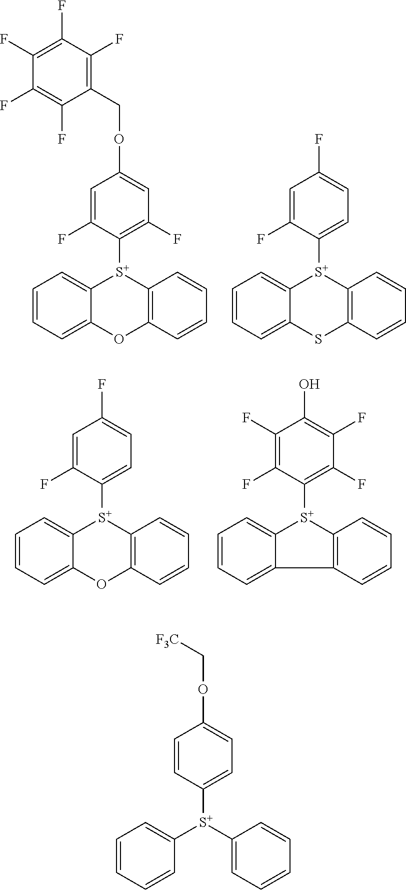 [SMILES: Fc1cc(OCc2c(F)c(F)c(F)c(F)c2F)cc(F)c1[S+]1c2ccccc2Oc2ccccc21 ; Fc1ccc([S+]2c3ccccc3Sc3ccccc32)c(F)c1 ; Fc1ccc([S+]2c3ccccc3Oc3ccccc32)c(F)c1 ; Oc1c(F)c(F)c(-[s+]2c3ccccc3c3ccccc32)c(F)c1F ; FC(F)(F)COc1ccc([S+](c2ccccc2)c2ccccc2)cc1]

According to the invention, in view of suppressing diffusion to an unexposure portion of acid generated due to exposure and making resolution satisfactory, the acid generator (B) is preferably a compound that generates an acid having a volume of 240 Å³ or greater due to irradiation of actinic rays or radiation, more preferably a compound that generates an acid having a volume of 300 Å³ or greater, even more preferably a compound that generates an acid having a volume of 350 Å³ or greater, and particularly preferably a compound that generates an acid having a volume of 400 Å³ or greater. However, in view of sensitivity or coating solvent solubility, the volume is preferably 2,000 Å³ or less and more preferably 1,500 Å³ or less. The value of the volume is calculated by using “WinMOPAC” manufactured by Fujitsu Limited. That is, first, a chemical structure of acid according to each example is input, most stable conformation of each acid by molecular field calculation by an MM3 method with this structure as an initial structure is determined, and thereafter molecular orbital calculation is performed using a PM3 method with respect to this most stable conformation, so as to calculate “accessible volume”.

Hereinafter, according to the invention, a particularly preferable acid generator is exemplified. In a portion of examples, calculation values of volumes are noted (unit: Å³). The calculation value obtained herein is a volume value of acid in which a proton is bonded to an anion portion.

Examples of the organic anion of X⁻ in Formula (I) above include a sulfonic acid anion, a carboxylic acid anion, a bis(alkylsulfonyl)amide anion, and a tris(alkylsulfonyl)methide anion. An organic anion represented by Formula (9), (10) or (11) below is preferable, and an organic anion represented by Formula (9) below is more preferable.

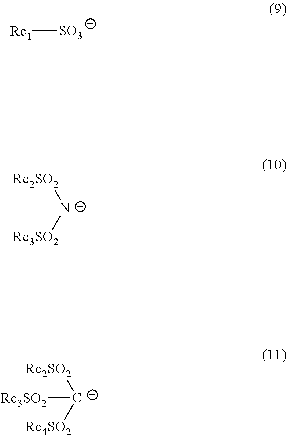

In Formulae (9), (10) and (11), Rc₁, Rc₂, Rc₃ and Rc₄ respectively represent organic groups

An organic anion of the X⁻ corresponds to sulfonic acid, imide acid, and methide acid that is acid generated due to irradiation of actinic rays such as electron beams or extreme ultraviolet rays or radiation.

Examples of the organic groups of Rc₁ to Rc₄ above include an alkyl group, a cycloalkyl group, an aryl group, or a group obtained by linking a plurality of these groups. Among these organic groups, an alkyl group in which the first position is substituted with a fluorine atom or a fluoroalkyl group, a cycloalkyl group in which the first position is substituted with a fluorine atom or a fluoroalkyl group, and a phenyl group in which the first position is substituted with a fluorine atom or a fluoroalkyl group are more preferable. A plurality of the organic groups of Rc₂ to Rc₄ may be linked to each other to form rings. As a group in which these organic groups are linked to each other, an alkylene group substituted with a fluorine atom or a fluoroalkyl group is preferable. In a case where the group has a fluorine atom or a fluoroalkyl group, acidity of acid generated by photo irradiation increases, and sensitivity is enhanced. However, it is preferable that the terminal group does not contain a fluorine atom as a substituent.

Examples of the preferably X⁻ include an aromatic sulfonic acid anion represented by Formula (SA1) below or a sulfonic acid anion represented by Formula (SA2).

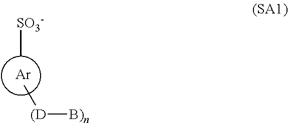

In Formula (SA1),

Ar represents an aryl group and may further have a substituent in addition to a sulfonic acid anion and a -(D-B) group.

n represents an integer of 0 or greater. n is preferably 1 to 4, more preferably 2 to 3, and most preferably 3.

D represents a single bond or a divalent linking group. Examples of this divalent linking group include an ether group, a thioether group, a carbonyl group, a sulfoxide group, a sulfone group, a sulfonic acid ester group, an ester group, and, a group consisting of a combination of two or more of these groups.

B represents a hydrocarbon group.

It is preferable that D is a single bond, and B is an aliphatic hydrocarbon structure.

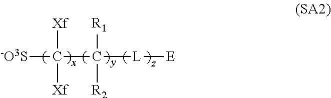

In Formula (SA2),

Xf's each independently represent a fluorine atom or an alkyl group substituted with at least one fluorine atom.

R₁ and R₂ each independently represent a hydrogen atom, a fluorine atom, or an alkyl group. In a case where there are plural R₁'s and R₂'s, respective R₁'s and R₂'s may be identical to or different from each other.

L represents a divalent linking group, and L in a case where there are plural L's may be identical to or different from each other.

E represents a cyclic organic group.

x represents an integer of 1 to 20, y represents an integer of 0 to 10, and z represents an integer of 0 to 10.

First, the sulfonic acid anion represented by Formula (SA1) are described in detail.

In Formula (SA1), Ar is preferably an aromatic ring having 6 to 30 carbon atoms. Specifically, examples of Ar include a benzene ring, a naphthalene ring, a pentalene ring, an indene ring, an azulene ring, a heptalene ring, an indacene ring, a perylene ring, a pentacene ring, an acenaphthylene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, or a phenazine ring. Among these, in view of compatibility between roughness improvement and high sensitivity, a benzene ring, a naphthalene ring, or an anthracene ring is preferable, and a benzene ring is more preferable.

In a case where Ar further has a substituent other than a sulfonic acid anion and a -(D-B) group, examples of the substituent include a halogen atom such as fluorine atom, a chlorine atom, a bromine atom, and an iodine atom; a hydroxy group; a carboxy group; and a sulfonic acid group.

In Formula (SA1), D is preferably a single bond, an ether group, or an ester group. D is more preferably a single bond.

In Formula (SA1), examples of B include an alkyl group (preferably an alkyl group having 1 to 20 carbon atoms), an alkenyl group (preferably an alkenyl group having 2 to 20 carbon atoms), an alkynyl group (preferably an alkynyl group having 2 to 20 carbon atoms), an aryl group (preferably an aryl group having 6 to 30 carbon atoms), or a cycloalkyl group (preferably a cycloalkyl group having 3 to 20 carbon atoms).

B is preferably an alkyl group or a cycloalkyl group and more preferably a cycloalkyl group. An alkyl group, an alkenyl group, an alkynyl group, an aryl group, or a cycloalkyl group as B may have a substituent.

The alkyl group as B is preferably a branched alkyl group. Examples of the branched alkyl group includes an isopropyl group, a tert-butyl group, a tert-pentyl group, a neopentyl group, a sec-butyl group, an isobutyl group, an isohexyl group, a 3,3-dimethylpentyl group, and a 2-ethylhexyl group.

Examples of the alkenyl group as B include a vinyl group, a propenyl group, and a hexenyl group.

Examples of the alkynyl group as B include a propynyl group and a hexynyl group.

Examples of the aryl group as B include a phenyl group and a p-tolyl group.

The cycloalkyl group as B may be a monocyclic cycloalkyl group or may be a polycyclic cycloalkyl group. Examples of the monocyclic cycloalkyl group include a cyclopropyl group, a cyclobutyl group, a cyclopentyl group, a cyclohexyl group, a cycloheptyl group, and a cyclooctyl group. Examples of the polycyclic cycloalkyl group include an adamantyl group, a norbornyl group, a bornyl group, a camphenyl group, a decahydronaphthyl group, a tricyclodecanyl group, a tetracyclodecanyl group, a camphoroyl group, a dicyclohexyl group, and a pinenyl group.

In a case where the alkyl group, the alkenyl group, the alkynyl group, the aryl group or the cycloalkyl group as B have substituents, examples of the substituent include the followings. That is, examples of the substituent include a halogen atom such as a fluorine atom, a chlorine atom, a bromine atom, or an iodine atom, an alkoxy group such as a methoxy group, an ethoxy group, and a tert-butoxy group; an aryloxy group such as a phenoxy group and a p-tolyloxy group; an alkylthioxy group such as a methylthioxy group, an ethylthioxy group, and a tert-butylthioxy group; an arylthioxy group such as a phenylthioxy group and a p-tolylthioxy group; an alkoxycarbonyl group such as a methoxycarbonyl group, a butoxycarbonyl group, and a phenoxycarbonyl group; an acetoxy group; a linear alkyl group such as a methyl group, an ethyl group, a propyl group, a butyl group, a heptyl group, a hexyl group, a dodecyl group, and a 2-ethylhexyl group; a branched alkyl group; a cycloalkyl group such as a cyclohexyl group; an alkenyl group such as a vinyl group, a propenyl group, and a hexenyl group; an acetylene group; an alkynyl group such as a propynyl group and a hexenyl group; an aryl group such as a phenyl group and a tolyl group; a hydroxy group; a carboxy group; a sulfonic acid group; and a carbonyl group. Among these, in view of compatibility of roughness enhancement and high-sensitivity, a linear alkyl group and a branched alkyl group are preferable.

Subsequently, a sulfonic acid represented by Formula (SA2) above is described in detail.

In Formula (SA2) above, Xf represents an fluorine atom, or an alkyl group substituted with at least one fluorine atom. As the alkyl group, an alkyl group having 1 to 10 carbon atoms is preferable, and an alkyl group having 1 to 4 carbon atoms is more preferable. In addition, an alkyl group substituted with a fluorine atom is preferably a perfluoroalkyl group.

Xf preferably represents a fluorine atom or a perfluoroalkyl group having 1 to 4 carbon atoms. Specifically, Xf preferably represents a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉. Among these, a fluorine atom or CF₃ is preferable, and a fluorine atom is most preferable.

In Formula (SA2) above, R₁ and R₂ each independently represent a hydrogen atom, a fluorine atom, or an alkyl group. The alkyl group may have a substituent (preferably, a fluorine atom) and is preferably a substituent having 1 to 4 carbon atoms. As the alkyl group having substituents of R₁ and R₂, a perfluoroalkyl group having 1 to 4 carbon atoms is particularly preferable. Specifically, examples of the alkyl group having substituents of R₁ and R₂ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, CF₃ is preferable.

In Formula (SA2), x preferably represents 1 to 8 and more preferably represents 1 to 4. y preferably represents 0 to 4 and more preferably represents 0. z preferably represents 0 to 8 and more preferably represents 0 to 4.

In Formula (SA2) above, L represents a single bond or a divalent linking group. Examples of the divalent linking group include —COO—, —OCO—, —CO—, —O—, —S—, —SO—, —SO₂—, an alkylene group, a cycloalkylene group, and an alkenylene group, or a combination of two or more types of these groups. Among these, a group of which a total number of carbon atoms is 20 or less is preferable. Among these, —COO—, —OCO—, —CO—, —O—, —S—, —SO—, or —SO₂— is preferable, and —COO—, —OCO—, or —SO₂— is more preferable.

In Formula (SA2) above, E represents a cyclic organic group. Examples of E include an cyclic aliphatic group, an aryl group, and a heterocyclic ring group.

The cyclic aliphatic group as E is preferably an cyclic aliphatic group of which a total number of carbon atoms is 20 or less, may have a monocyclic structure, and may have a polycyclic structure. As the cyclic aliphatic group having a monocyclic structure, a monocyclic cycloalkyl group such as a cyclopentyl group, a cyclohexyl group, and a cyclooctyl group is preferable. As the cyclic aliphatic group having a polycyclic structure, a polycyclic cycloalkyl group such as a norbornyl group, a tricyclodecanyl group, a tetracyclodecanyl group, a tetracyclododecanyl group, and an adamantyl group is preferable. Particularly, in a case where an cyclic aliphatic group having a bulky structure of a 6 or more-membered ring is employed as E, diffusion properties of a film in a post exposure baking (PEB) step are suppressed and thus resolving power and exposure latitude (EL) are further improved.

As the aryl group as E, an aryl group having a total number of carbon atoms of 20 or less is preferable, and examples thereof include a benzene ring, a naphthalene ring, a phenanthrene ring, or an anthracene ring.

A heterocyclic ring group as E having a total number of carbon atoms of 20 or less is preferable, and may have aromatic properties or may not have aromatic properties. As a hetero atom included in this group, a nitrogen atom or an oxygen atom is preferable. Specific examples of the heterocyclic ring structure include a furan ring, a thiophene ring, a benzofuran ring, a benzothiophene ring, a dibenzofuran ring, a dibenzothiophene ring, a pyridine ring, a piperidine ring, and a morpholine ring. Among these, a furan ring, a thiophene ring, a pyridine ring, a piperidine ring, and a morpholine ring are preferable.

E may have a substituent. Examples of the substituent include an alkyl group (may be any one of a straight chain shape, a branched shape, and a cyclic shape, and preferably has 1 to 12 carbon atoms), an aryl group (preferably has 6 to 14 carbon atoms), a hydroxy group, an alkoxy group, an ester group, an amido group, an urethane group, an ureido group, a thioether group, a sulfoneamide group, and a sulfonic acid ester group.

Hereinafter, specific examples and volume values of an acid that the acid generator (B) generates are provided, but the invention is not limited thereto.

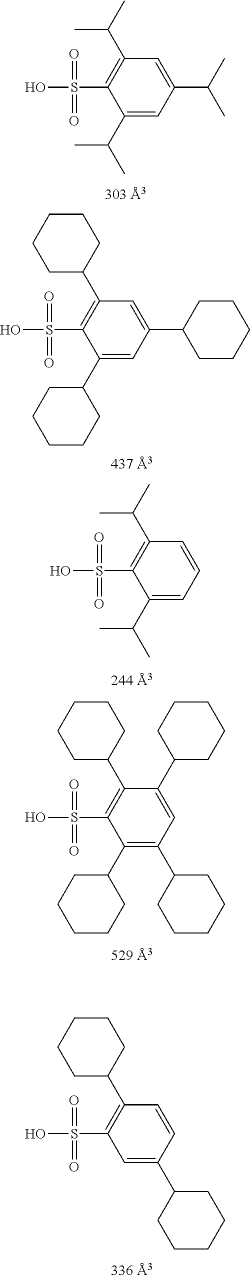 [SMILES: CC(C)c1cc(C(C)C)c(S(=O)(=O)O)c(C(C)C)c1 ; O=S(=O)(O)c1c(C2CCCCC2)cc(C2CCCCC2)cc1C1CCCCC1 ; CC(C)c1cccc(C(C)C)c1S(=O)(=O)O ; O=S(=O)(O)c1c(C2CCCCC2)c(C2CCCCC2)cc(C2CCCCC2)c1C1CCCCC1 ; O=S(=O)(O)c1cc(C2CCCCC2)ccc1C1CCCCC1]

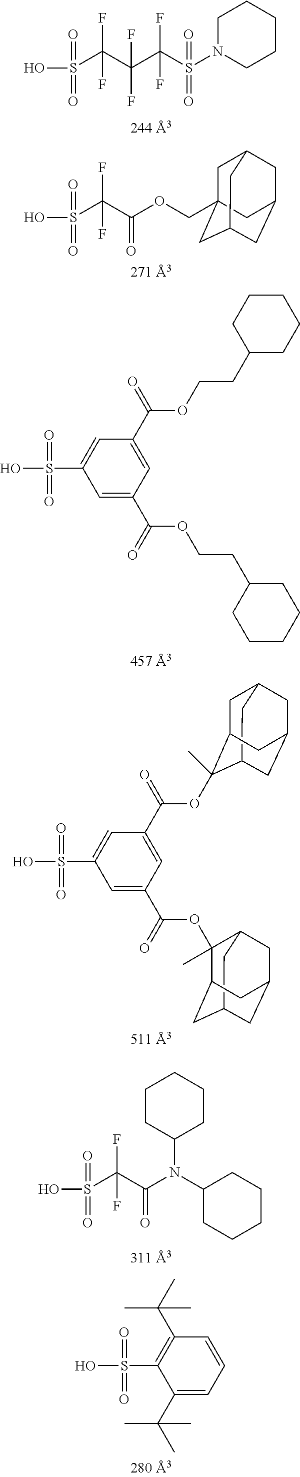

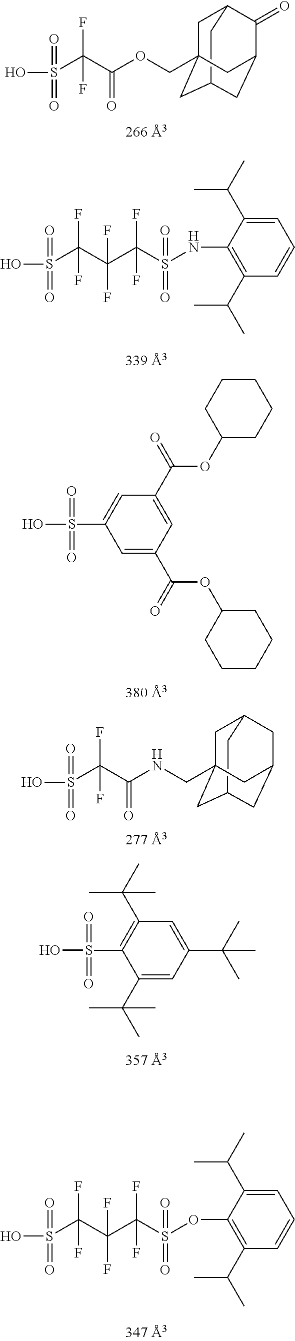 [SMILES: O=C1C2CC3CC1CC(COC(=O)C(F)(F)S(=O)(=O)O)(C3)C2 ; CC(C)c1cccc(C(C)C)c1NS(=O)(=O)C(F)(F)C(F)(F)C(F)(F)S(=O)(=O)O ; O=C(OC1CCCCC1)c1cc(C(=O)OC2CCCCC2)cc(S(=O)(=O)O)c1 ; O=C(NCC12CC3CC(CC(C3)C1)C2)C(F)(F)S(=O)(=O)O ; CC(C)(C)c1cc(C(C)(C)C)c(S(=O)(=O)O)c(C(C)(C)C)c1 ; CC(C)c1cccc(C(C)C)c1OS(=O)(=O)C(F)(F)C(F)(F)C(F)(F)S(=O)(=O)O]

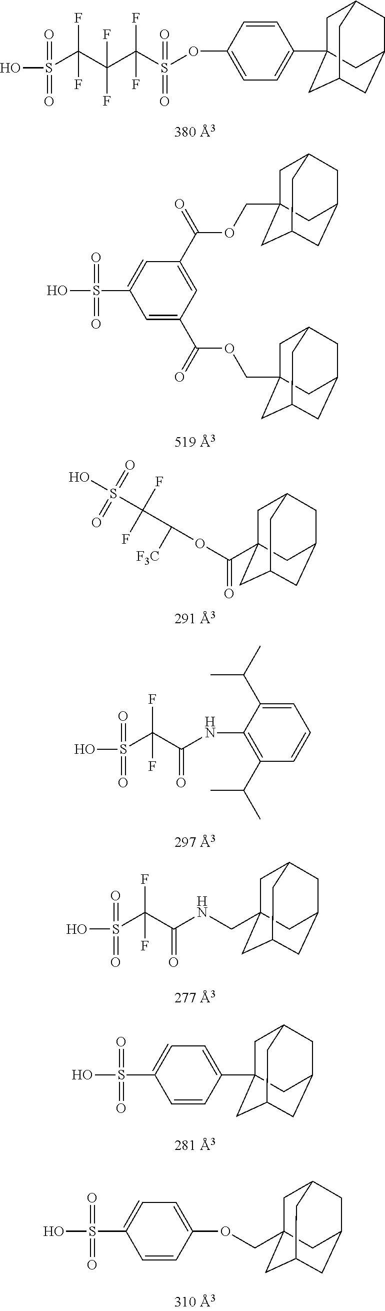

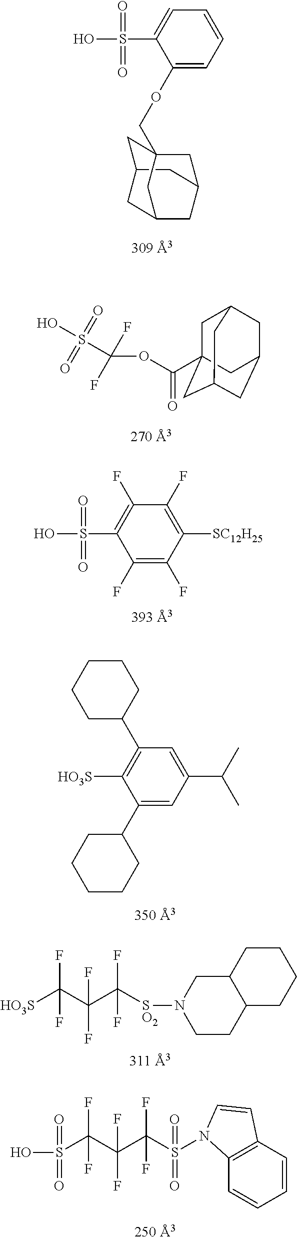

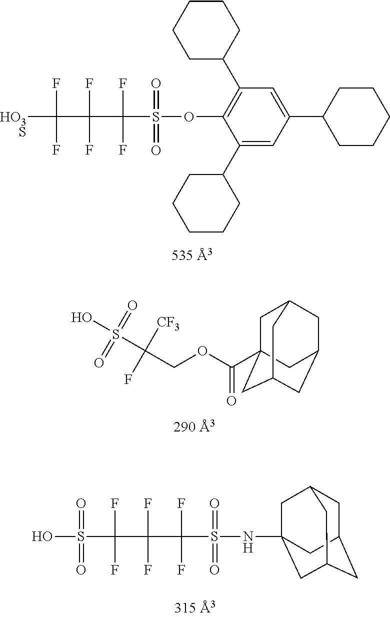 [SMILES: O=S(=O)(O)C(F)(F)C(F)(F)C(F)(F)S(=O)(=O)Oc1c(C2CCCCC2)cc(C2CCCCC2)cc1C1CCCCC1 ; O=C(OCC(F)(C(F)(F)F)S(=O)(=O)O)C12CC3CC(CC(C3)C1)C2 ; O=S(=O)(O)C(F)(F)C(F)(F)C(F)(F)S(=O)(=O)NC12CC3CC(CC(C3)C1)C2]

In the composition according to the invention, two or more types of acid generator (B) may be used in combination.

The content of the composition of the acid generator is preferably 1% to 40% by mass, more preferably 2% to 30% by mass, and still more preferably 3% to 25% by mass with respect to a total solid content of the actinic ray-sensitive or radiation-sensitive resin composition.

<(D) Solvent>

Examples of the solvent used in the composition according to the invention preferably include ethylene glycol monoethyl ether acetate, cyclohexanone, 2-heptanone, propylene glycol monomethyl ether (PGME, also referred to as 1-methoxy-2-propanol), propylene glycol monomethyl ether acetate (PGMEA, also referred to as 1-methoxy-2-acetoxypropane), propylene glycol monomethyl ether propionate, propylene glycol monoethyl ether acetate, methyl 3-methoxypropionate, ethyl 3-ethoxypropionate, methyl β-methoxyisobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methyl pyrrolidone, N,N-dimethyl formamide, γ-butyrolactone, N,N-dimethylacetamide, propylene carbonate, and ethylene carbonate. These solvents may be used singly or in combination.

The concentration of the actinic ray-sensitive or radiation-sensitive resin composition is preferably 10% by mass or less, more preferably 1% to 10% by mass, even more preferably 1% to 8% by mass, and particularly preferably 1% to 6% by mass with respect to the concentration of solid contents.

The composition according to the invention may further contain components below.

<Basic Compound>

The composition preferably contains a basic compound as an acid acceptor, in addition to the components above. In a case where the basic compound is used, it is possible to reduce a change of performances over time from the exposure to the post baking. As the basic compound like this, an organic basic compound is preferable. Specifically, examples thereof include aliphatic amines, aromatic amines, heterocyclic amines, a nitrogen-containing compound having a carboyxl group, a nitrogen-containing compound having a sulfonyl group, a nitrogen-containing compound having a hydroxy group, a nitrogen-containing compound having a hydroxyphenyl group, an alcoholic nitrogen-containing compound, an amide derivative, and an imide derivative. An amine oxide compound (a compound having a methyleneoxy unit and/or an ethyleneoxy unit is preferable, and examples thereof include compounds disclosed in JP2008-102383A) and ammonium salt (preferably hydroxide or carboxylate, and, specifically, tetraalkylammonium hydroxide represented by tetrabutylammonium hydroxide is preferable in view of LER) are also appropriately used.

A compound in which basicity increases due to an action of an acid also used as one type of a basic compound.

Specific examples of the amines include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, and tris(methoxyethoxyethyl)amine, compounds disclosed in Column 3 on line 60 in U.S. Pat. No. 6,040,112A, 2-[2-{2-(2,2-dimethoxy-phenoxyethoxy)ethyl}-bis-(2-methoxyethyl)]-amine, and compounds (C1-1) to (C3-3) exemplified in Paragraph “0066” in US2007/0224539A1. Examples of the compounds having the nitrogen-containing heterocyclic ring structure include 2-phenylbenzimidazole, 2,4,5-triphenylimidazole, N-hydroxyethylpiperadine, bis(1,2,2,6,6-pentamethyl-4-piperidyl)sebacate, 4-dimethylaminopyridine, antipyrine, hydroxyantipyrine, 1,5-diazabicyclo [4.3.0]nona-5-ene, 1,8-diazabicyclo [5.4.0]-undeca-7-ene, and tetrabutylammonium hydroxide.

A photo-decomposable basic compound (a compound in which a basic nitrogen atom originally functions as a base to show basicity, but the basic nitrogen atom is decomposed by irradiation with actinic rays or radiation, amphoteric ion compounds having basic nitrogen atoms and organic acid portions are generated, these perform neutralization in a molecule, and thus basicity decreases or disappears. For example, onium salts disclosed in JP3577743B, JP2001-215689A, JP2001-166476A, and JP2008-102383A) and a photobase generating agent (for example, compounds disclosed in JP2010-243773A) are also appropriately used.

Among these basic compounds, since satisfactory LER can be obtained, ammonium salt or a photo-decomposable basic compound is preferable.

According to the invention, the basic compound may be used singly, or two or more types thereof may be used in combination.

The content of the basic compound used in the invention is preferably 0.01% to 10% by mass, more preferably 0.03% to 5% by mass, and particularly preferably 0.05% to 3% by mass with respect to the total solid content of the actinic ray-sensitive or radiation-sensitive resin composition.

<Acid Crosslinking Compound>

The composition according to the invention may contain an acid crosslinking compound (also referred to as a “crosslinking agent”). Particularly, In a case where the composition according to the invention is used as a negative actinic ray-sensitive or radiation-sensitive resin composition, it is preferable to contain a compound (hereinafter, appropriately referred to as an acid crosslinking agent or simply a crosslinking agent) having two or more hydroxymethyl groups or alkoxymethyl groups in a molecule.

Examples of a preferable crosslinking agent include a hydroxymethylated or alkoxymethylated phenol compound, an alkoxymethylated melamine-based compound, alkoxymethylglycoluril-based compounds, and an alkoxymethylated urea-based compound. Among them, a hydroxymethylated or alkoxymethylated phenol compound is more preferable, since a satisfactory pattern form can be obtained. Examples of a particularly preferable crosslinking agent include a phenol derivative having three to five benzene rings in a molecule, having two or more hydroxymethyl groups or alkoxymethyl groups in total, and having a molecular weight of 1,200 or less, and a melamine-formaldehyde derivative or an alkoxymethylglycoluril derivative having at least two free N-alkoxymethyl groups.

In view of a pattern form, the composition according to the invention more preferably contains at least two or more types of compounds having two or more alkoxymethyl groups in a molecule, as the acid crosslinking compound, still more preferably contains at least two or more types of phenol compounds having two or more alkoxymethyl groups in a molecule, and the resist composition for the semiconductor manufacturing process according to the invention is particularly preferably a phenol derivative in which at least one of the at least two types of phenol compounds includes three to five benzene rings in a molecule, includes two or more alkoxymethyl groups in total, and has a molecular weight of 1,200 or less.

As the alkoxymethyl group, a methoxymethyl group and an ethoxymethyl group are preferable.

Among the crosslinking agents, the phenol derivative having the hydroxymethyl group can be obtained by reacting a phenol compound not having a corresponding hydroxymethyl group and formaldehyde under a base catalyst. The phenol derivative having an alkoxymethyl group can be obtained by reacting a phenol derivative having a corresponding hydroxymethyl group and alcohol under an acid catalyst.

Among the phenol derivatives synthesized in this manner, a phenol derivative having an alkoxymethyl group is particularly preferable in view of the sensitivity and the preservation stability.

Examples of another preferable crosslinking agent further includes compounds having an N-hydroxymethyl group or an N-alkoxymethyl group such as an alkoxymethylated melamine-based compound, alkoxymethylglycoluril-based compounds, and an alkoxymethylated urea-based compound.

Examples of these compounds include hexamethoxymethylmelamine, hexaethoxymethylmelamine, tetramethoxymethylglycoluril, 1,3-bismethoxymethyl-4,5-bismethoxyethyleneurea, and bismethoxymethylurea, and are disclosed in EP0,133,216A, DE3,634,671B, DE3,711,264B, and EP0,212,482A.

Among these crosslinking agents, particularly preferable crosslinking agents are provided below.

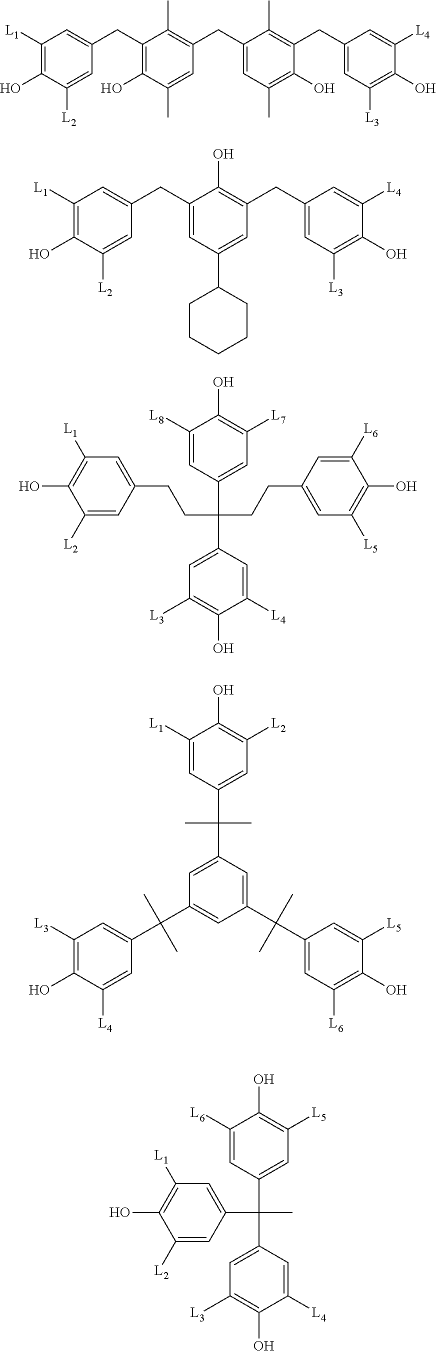

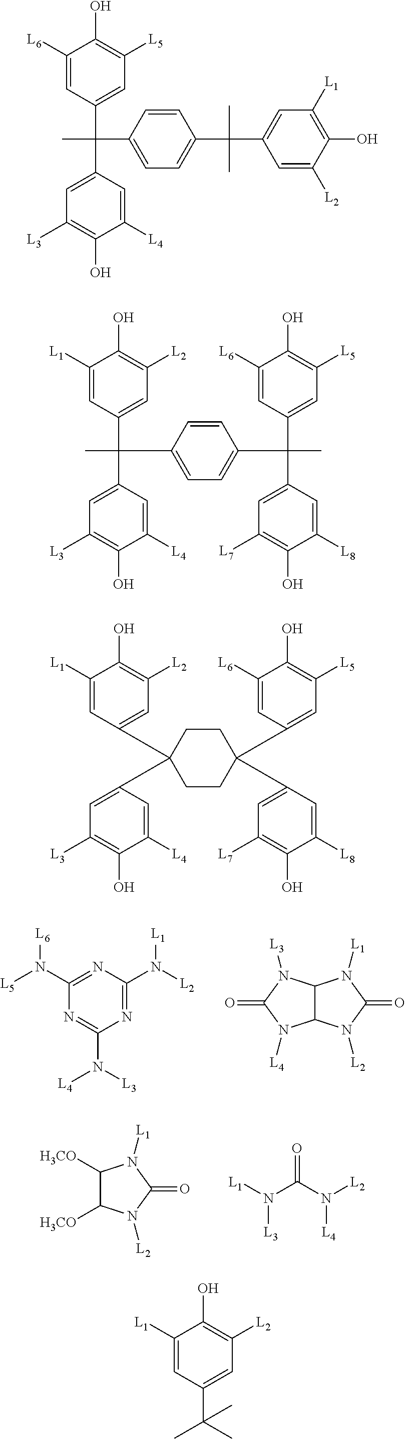

In the formula, L₁ to L₈ each independently represent a hydrogen atom, a hydroxymethyl group, a methoxymethyl group, an ethoxymethyl group, or an alkyl group having 1 to 6 carbon atoms.

An addition amount of the crosslinking agent according to the invention is preferably 3% to 65% by mass, more preferably 5% to 50% by mass with respect to the actinic ray-sensitive or radiation-sensitive resin composition. In a case where the addition amount of the crosslinking agent is caused to be 3% to 65% by mass, stability at the time of preserving a resist liquid can be satisfactorily maintained together with preventing a residual film ratio and resolving power from decreasing.

According to the invention, the crosslinking agent may be used singly or two or more types thereof may be used in combination, and it is preferable to use two or more types in view of pattern forms.

For example, in addition to the phenol derivatives, in a case where other crosslinking agents, for example, the compound having an N-alkoxymethyl group described above, is used in combination, the ratio of the phenol derivative and another crosslinking agent is 100/0 to 20/80 by a molar ratio, preferably 90/10 to 40/60, and still more preferably 80/20 to 50/50.

The acid crosslinking compound may be a resin having a repeating unit having an acid crosslinking group (hereinafter, also referred to as a resin (E)). In a case where the acid crosslinking compound is the resin (E), the repeating unit in the resin (E) has an acid crosslinking group, and thus crosslinking reactivity is high and a strong film can be formed, compared with an actinic ray-sensitive or radiation-sensitive resin composition that contains a resin not having a repeating unit having an acid crosslinking group. As a result, it is considered that dry etching resistance is improved. Diffusion of an acid in an exposed portion with actinic rays or radiation is suppressed, and as a result, it is considered that resolving power in a case where a fine pattern is formed is improved such that a pattern form becomes better and further line edge roughness (LER) decreases. As in a repeating unit represented by Formula (CL) below, in a case where a reaction point of the resin and a reaction point of a crosslinking group are close to each other, it is considered that the sensitivity of a chemical amplification resist composition is improved.

Examples of the resin (E) include a resin having a repeating unit represented by Formula (CL) below. The repeating unit represented by Formula (CL) has a structure including at least one methylol group that may have a substituent.

Here, the “methylol group” is a group represented by Formula (M) below, and is preferably a hydroxymethyl group or an alkoxymethyl group according to one embodiment of the invention.

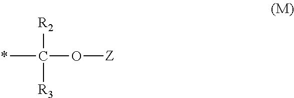

R₂ and R₃ represent hydrogen atoms, alkyl groups, or cycloalkyl groups.

Z represents a hydrogen atom or a substituent.

Hereinafter, Formula (CL) is described.

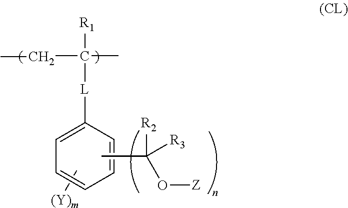

In Formula (CL),

R₂, R₃, and Z are as defined in Formula (M) above.

R₁ represents a hydrogen atom, a methyl group, or a halogen atom.

L represents a divalent linking group or a single bond.

Y represents a substituent except for a methylol group.

m represents an integer of 0 to 4.

n represents an integer of 1 to 5.

A value of m+n is 5 or less.

In a case where m is 2 or greater, plural Y's may be identical to or different from each other.

In a case where n is 2 or greater, plural R₂'s, R₃'s, and Z's may be identical to or different from each other.

Two or more of Y's, R₂'s, R₃'s, and Z's may be bonded to each other, to form a ring structure.

Each of R₁, R₂, R₃, L, and Y may have a substituent.

The content of the repeating unit having the acid crosslinking group in the resin (E) is preferably 3% to 40% by mol and more preferably 5% to 30% by mol with respect to the total repeating unit of the resin (E).

The content ratio of the resin (E) is preferably 5% to 50% by mass and more preferably 10% to 40% by mass with respect to the total solid content of the negative resist composition.

The resin (E) may have two or more types of repeating units having acid crosslinking groups or two or more types of resins (E) may be used in combination. A crosslinking agent other than the resin (E) and the resin (E) may be used in combination.

Specific examples of the repeating unit having the acid crosslinking group included in the resin (E) include structures below.

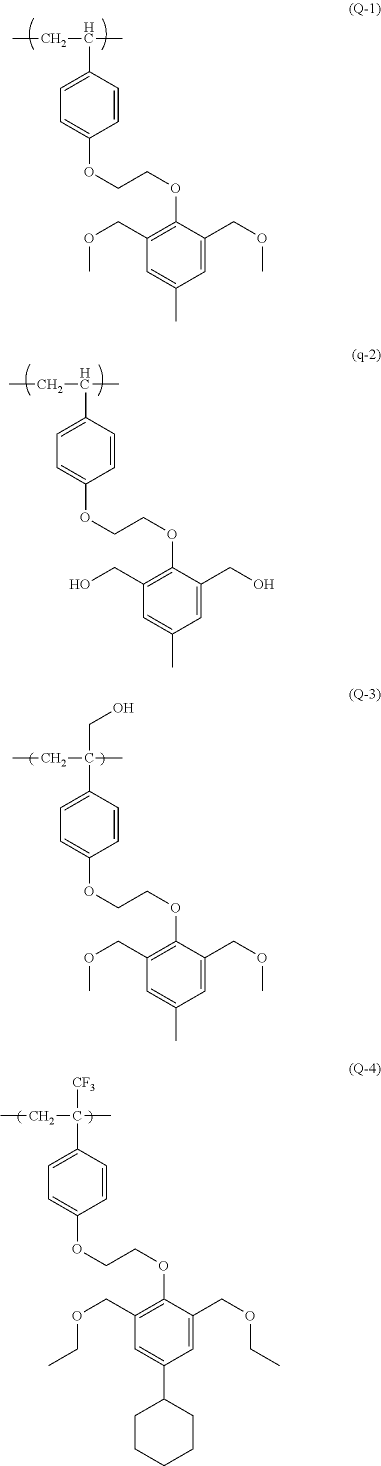

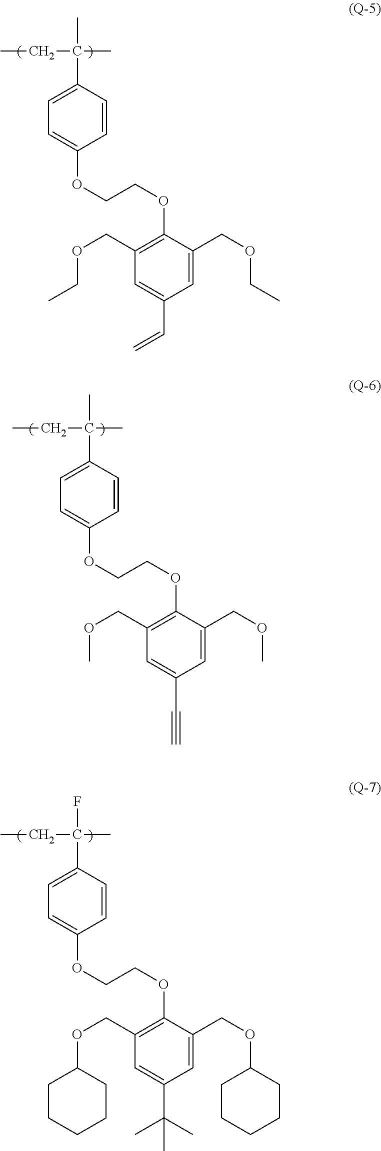

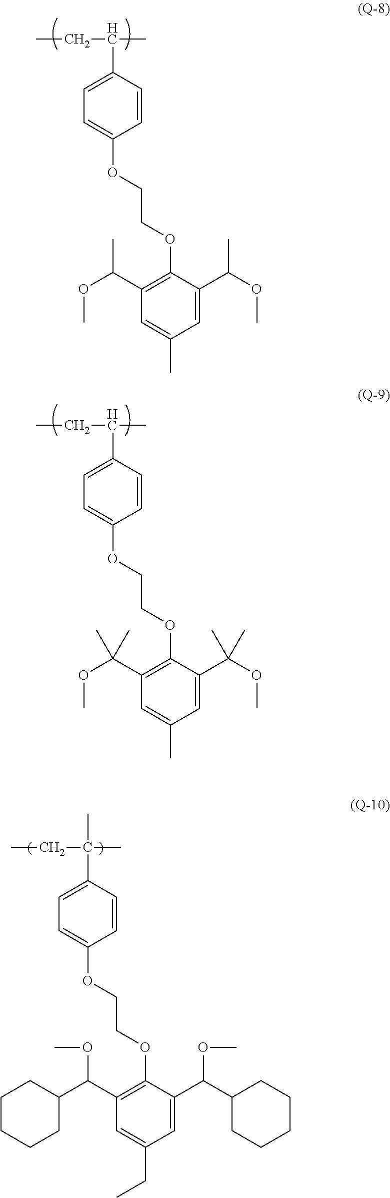

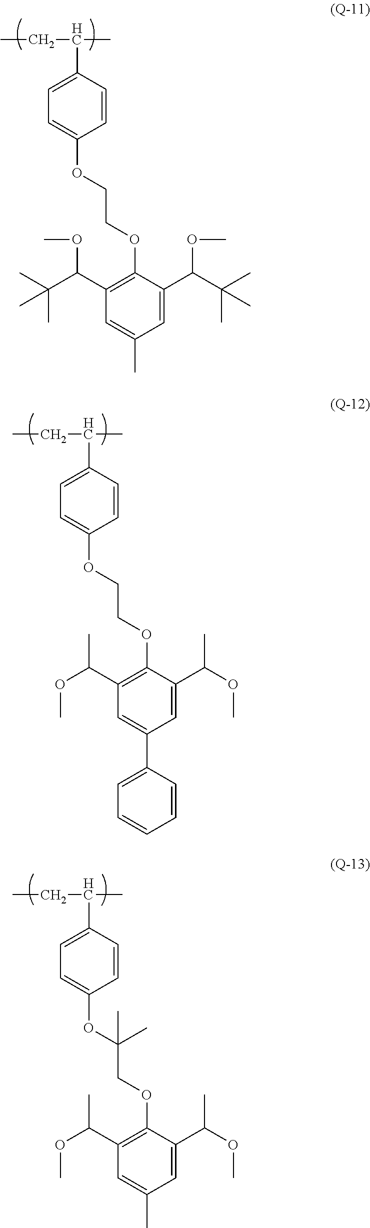

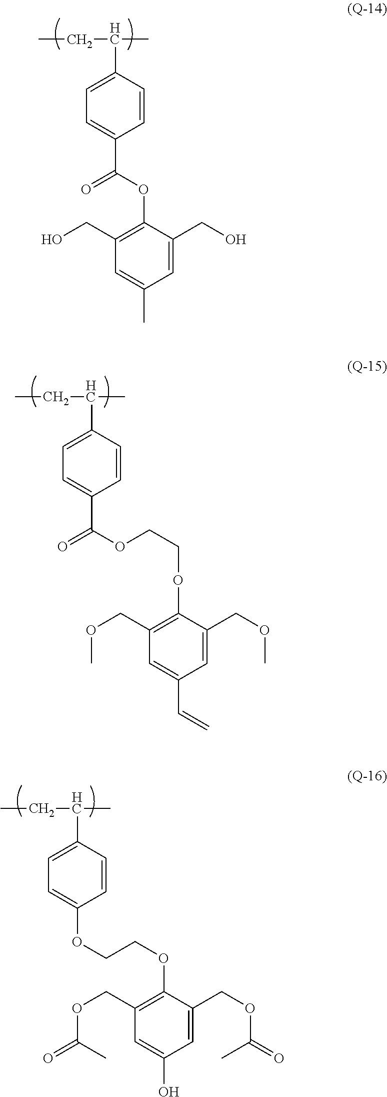

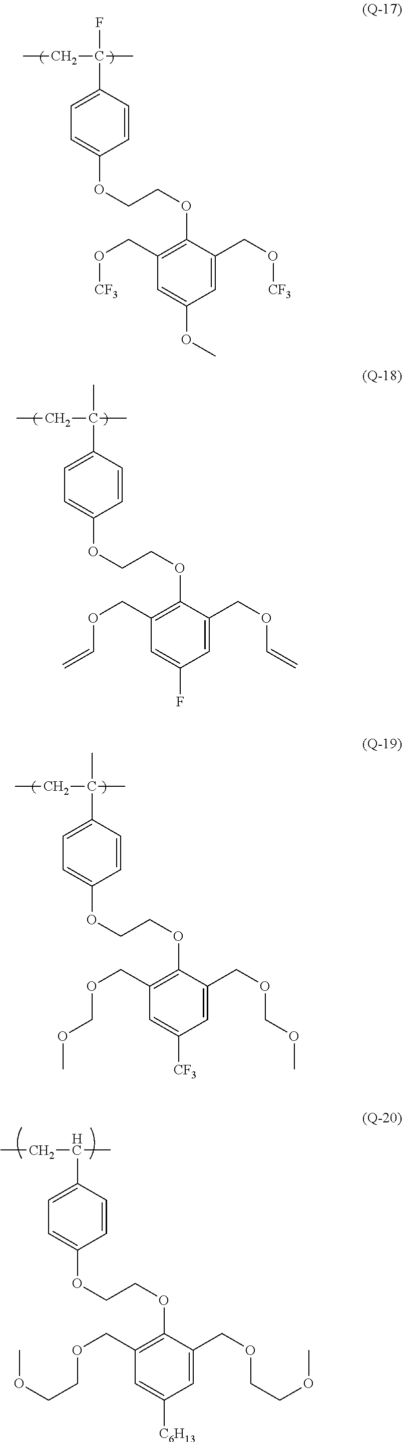

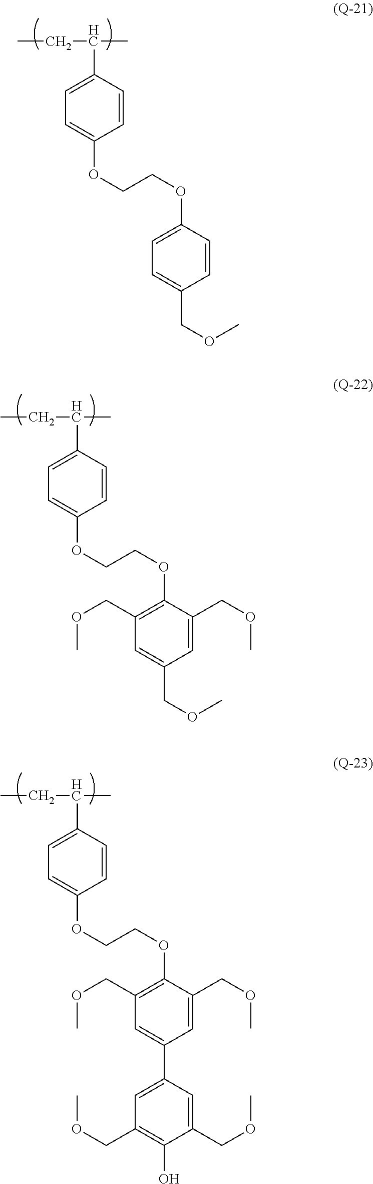

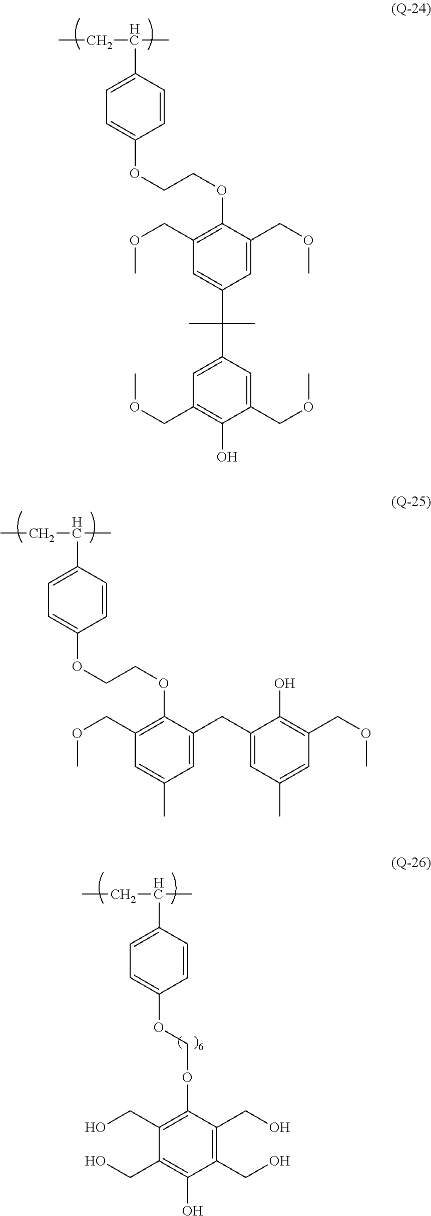

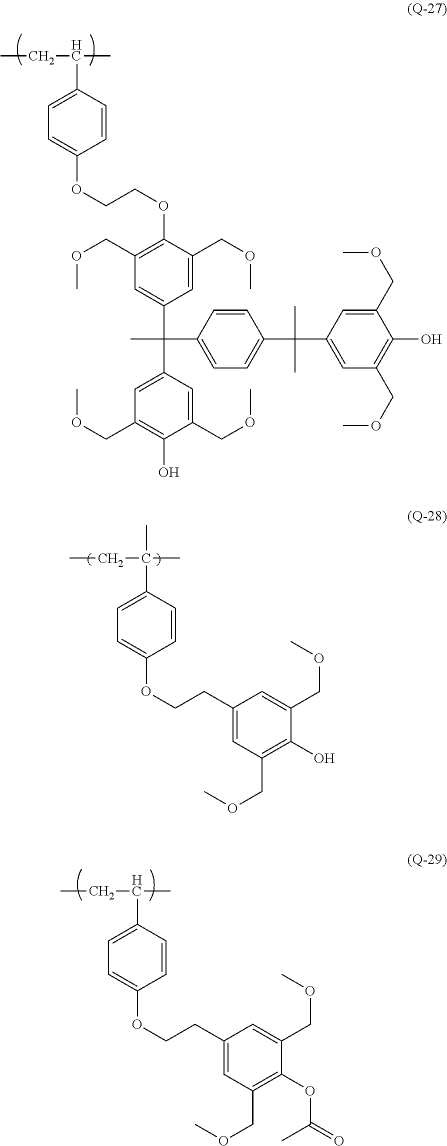

<Surfactant>

The composition according to the invention may further contain a surfactant in order to improve coating properties. Examples of the surfactant are not particularly limited, and include nonionic surfactants such as polyoxyethylene alkyl ethers, polyoxyethylene alkylallyl ethers, polyoxyethylene polyoxypropylene block copolymers, sorbitan fatty acid esters, polyoxyethylene sorbitan fatty acid esters, fluorine-based surfactants such as MEGAFACE F171 and F176 (manufactured by DIC Corporation) and FLUORAD FC430 (manufactured by Sumitomo 3M Limited) and SURFYNOL E1004 (manufactured by Asahi Glass Co., Ltd.), and PF656 and PF6320 manufactured by OMNOVA Solutions Inc., and an organosiloxane polymer such as a polysiloxane polymer KP-341 (manufactured by Shin-Etsu Chemical Co., Ltd.).

In a case where the composition according to the invention contains a surfactant, the usage amount of the surfactant is preferably 0.0001% to 2% by mass and more preferably 0.0005% to 1% by mass with respect to a total amount (except for a solvent) of the actinic ray-sensitive or radiation-sensitive resin composition.

<Carboxylic Acid Onium Salt>

The composition according to the invention may contain carboxylic acid onium salt. Examples of the carboxylic acid onium salt include carboxylic acid sulfonium salt, carboxylic acid iodonium salt, and carboxylic acid ammonium salt. Particularly, as the carboxylic acid onium salt, carboxylic acid iodonium salt and carboxylic acid sulfonium salt are preferable. According to the invention, it is preferable that a carboxylate residue of the carboxylic acid onium salt does not contain an aromatic group and a carbon-carbon double bond. As a particularly preferable anion portion, a linear, branched, monocyclic or polycyclic cyclic alkylcarboxylate anion having 1 to 30 carbon atoms is preferable. An anion of a carboxylic acid in which a portion or all of alkyl groups are substituted with fluorine is more preferable. An oxygen atom may be included in an alkyl chain. Accordingly, transparency with respect to light of 220 nm or less is secured, and thus sensitivity and resolving power are improved, such that density dependency and exposure margins are improved.

<Compound that is Decomposed Due to Action of Acid and Generates Acid>

The chemical amplification resist composition may include one or more types of compounds that is decomposed due to an action of an acid and generates an acid. The acid that is generated by the compound that is decomposed due to an action of an acid and generates an acid is preferably a sulfonic acid, a methide acid, or an imide acid.

Hereinafter, examples of the compounds that can be used in the invention are provided, but the invention is not limited thereto.

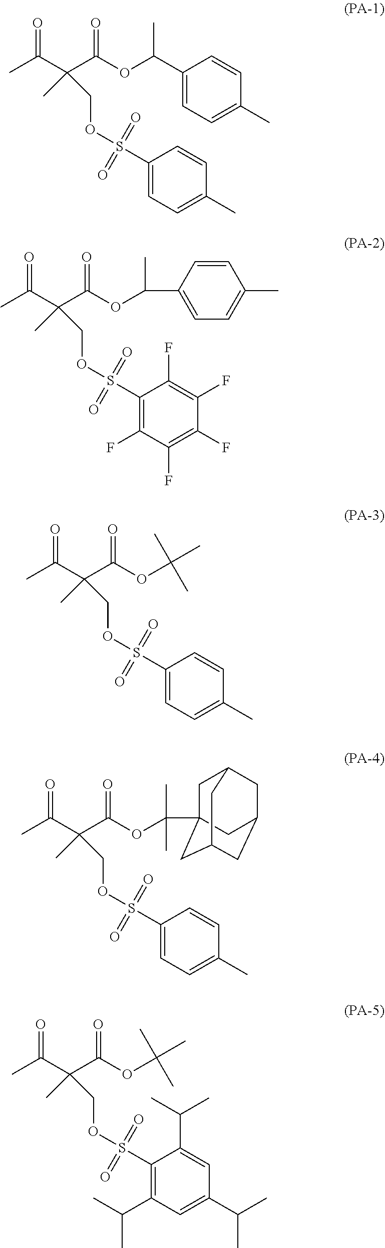

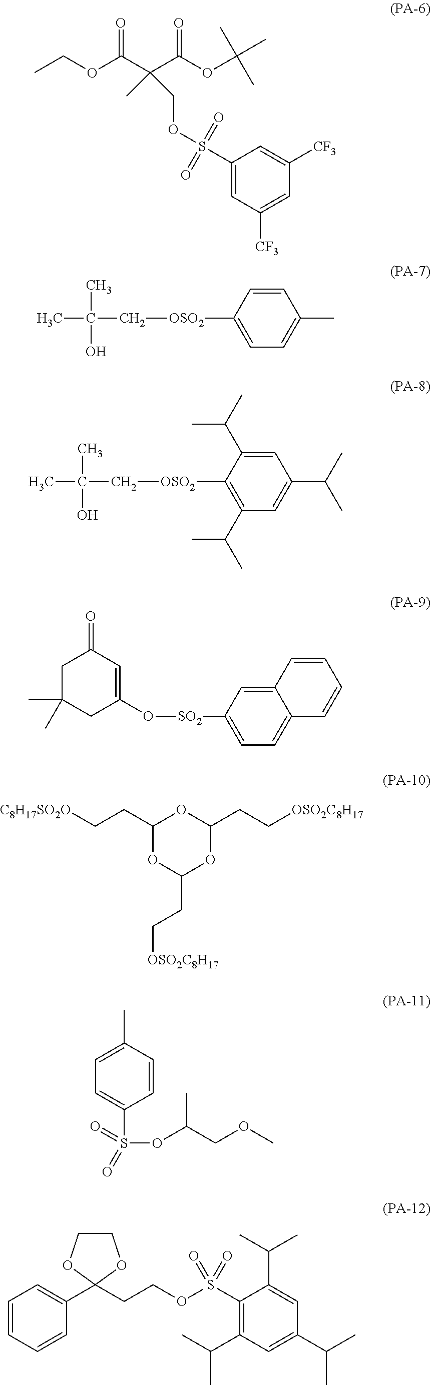

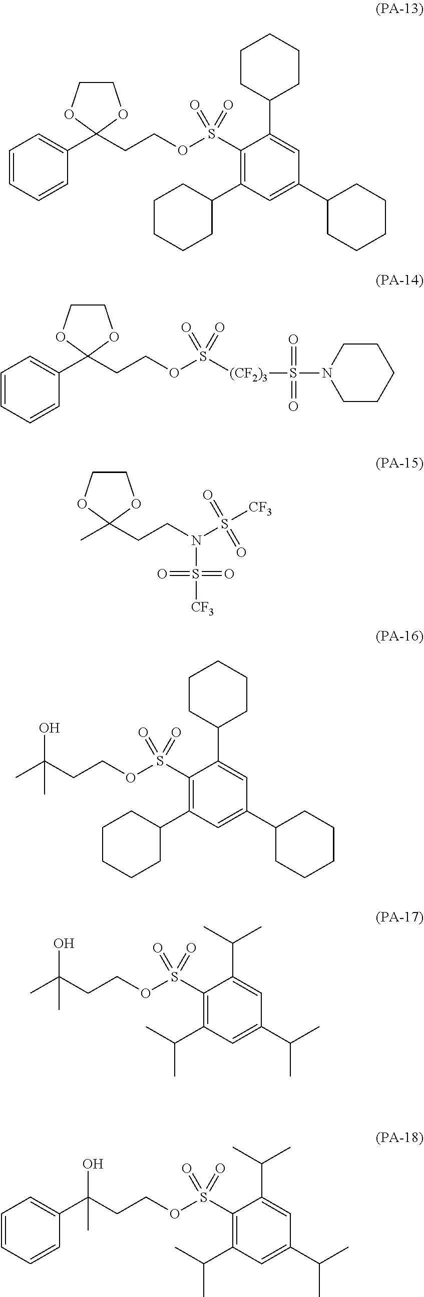

The composition according to the invention may further contain a dye, a plasticizer, and an acid proliferating agent (disclosed in WO95/29968A, WO98/24000A, JP1996-305262A (JP-H08-305262A), JP1997-34106A (JP-H09-34106A), JP1996-248561A (JP-H08-248561A), JP1996-503082A (JP-H08-503082A), U.S. Pat. No. 5,445,917A, JP1996-503081A (JP-H08-503081A), U.S. Pat. No. 5,534,393A, U.S. Pat. No. 5,395,736A, U.S. Pat. No. 5,741,630A, U.S. Pat. No. 5,334,489A, U.S. Pat. No. 5,582,956A, U.S. Pat. No. 5,578,424A, U.S. Pat. No. 5,453,345A, EP665960B, EP757628B, EP665961B, U.S. Pat. No. 5,667,943A, JP1998-1508A (JP-H10-1508A), JP1998-282642A (JP-H10-282642A), JP1997-512498A (JP-H10-282642A), JP2000-62337A, JP2005-17730A, and JP2008-209889A) other than the acid generator (B), if necessary. With respect to these compounds, respective compounds disclosed in JP2008-268935A can be included.

The invention relates to the actinic ray-sensitive or radiation-sensitive film formed with the composition according to the invention, and this actinic ray-sensitive or radiation-sensitive film is formed by coating a support such as a substrate with the actinic ray-sensitive or radiation-sensitive resin composition. The thickness of this actinic ray-sensitive or radiation-sensitive film is preferably 200 nm or less, more preferably 10 to 200 nm, and even more preferably 20 to 150 nm. As a method of coating the substrate, an appropriate coating method such as spin coating, roll coating, flow coating, dip coating, spray coating, and doctor coating is performed to coat the substrate, and spin coating is preferable. The number of revolution thereof is preferably 1,000 to 3,000 rpm. As the coating film, a thin film is formed by performing prebaking at 60° C. to 150° C. for 1 to 20 minutes, and preferably at 80° C. to 120° C. for 1 to 10 minutes.

As a materials for forming a substrate to be processed and the outermost layer thereof, for example, a silicon wafer can be used, in a case of a semiconductor wafer. Examples of a material that becomes an outermost layer include Si, SiO₂, SiN, SiON, TiN, WSi, BPSG, SOG, and an organic antireflective film.

The invention also relates to a mask blank with the actinic ray-sensitive or radiation-sensitive film obtained as described above. In order to obtain this mask blank with the actinic ray-sensitive or radiation-sensitive film, in a case where a resist pattern is formed on a photo mask blank for manufacturing a photo mask, an example of a used transparent substrate include a transparent substrate such as quarts and calcium fluoride. Generally, a necessary functional film such as a light shielding film, an antireflective film, and further a phase shift film, and additionally, an etching stopper film and an etching mask film are stacked on the substrate. As a material of the functional film, a film containing transition metal such as silicon, chromium, molybdenum, zirconium, tantalum, tungsten, titanium, and niobium is stacked. In addition, as a material used in the outermost layer, a silicon compound material having a material having silicon or a material containing oxygen and/or nitrogen in silicon, as a main constituent material or a material further containing transition metal in this material, as a main constituent material, and a transition metal compound material having a material including one or more types selected from transition metal, particularly, chromium, molybdenum, zirconium, tantalum, tungsten, titanium, and niobium, or a material having 1 or more element selected from oxygen, nitrogen, and carbon, further to this material, as a main constituent material are exemplified.

The light shielding film may be a single layer, and a multilayer structure in which plural materials are coated in an overlapped manner is more preferable. In a case of the multilayer structure, a thickness of the film per one layer is not particularly limited, and is preferably 5 nm to 100 nm and more preferably 10 nm to 80 nm. The total thickness of the light shielding film is not particularly limited, and is preferably 5 nm to 200 nm and more preferably 10 nm to 150 nm.

Among these materials, in a case where a pattern is formed by using the chemical amplification resist composition on a photo mask blank having a material containing oxygen or nitrogen generally in chromium on an outermost layer, a so-called undercut form in which a constricted shape is formed near the substrate is easily caused, but in a case where the invention is used, an undercut problem can be improved compared with a resist composition in the related art.

Subsequently, the resist film is irradiated with actinic rays or radiation (electron beams and the like), baking (generally at 80° C. to 150° C., preferably at 90° C. to 130° C., and generally for 1 to 20 minutes, preferably for 1 to 10 minutes) is preferably performed, and then development is performed. Accordingly, a satisfactory pattern can be obtained. In addition, this pattern is used as a mask, and an etching process and ion injection are appropriately performed, a semiconductor fine circuit, an imprint mold structure body, or a photo mask is created.

The pattern formed by the method can be used for forming a guide pattern (for example, see ACS Nano Vol. 4 No. 8, Pages 4815 to 4823) in directed self-assembly (DSA). The pattern formed by the method can be used as a core of a spacer process disclosed in JP1991-270227A (JP-H3-270227A) and JP2013-164509A.

Processes in a case of creating an imprint mold using the composition according to the invention are disclosed, for example, in JP4109085B, JP2008-162101A, and “Science and New Technology in Nanoimprint—Substrate technology of nanoimprint and latest technology development—edited by HIRAI, Yoshihiko (Frontier Publishing)”.

A use form of the chemical amplification resist composition according to the invention and a resist patterning method are described below.

The invention relates to a forming method for a pattern, including: exposing a mask blank comprising the actinic ray-sensitive or radiation-sensitive film or actinic ray-sensitive or radiation-sensitive film and developing a mask blank provided with the exposed actinic ray-sensitive or radiation-sensitive film or actinic ray-sensitive or radiation-sensitive film. According to the invention, the exposure is preferably performed by using ArF light, KrF light, and electron beams or extreme ultraviolet rays.

As the exposure (patterning step) of the actinic ray-sensitive or radiation-sensitive film in the manufacturing of a precisely integrated circuit element and the like, it is preferable to perform irradiation of the actinic ray-sensitive or radiation-sensitive film according to the invention with electron beams or extreme ultraviolet rays (EUV) in a pattern shape. Exposure is performed such that the exposure amount is about 0.1 to 20 μC/cm² and preferably about 3 to 15 μC/cm² in the case of the electron beams, is about 0.1 to 20 mJ/cm² and preferably about 3 to 15 mJ/cm², in the case of extreme ultraviolet rays. Subsequently, post exposure baking is performed on a hot plate, at 60° C. to 150° C. for 1 to 20 minutes and preferably at 80° C. to 120° C. for 1 to 10 minutes, and subsequently, a resist pattern is formed by performing developing, rinsing, and drying.

A developer used in the step of developing the actinic ray-sensitive or radiation-sensitive film formed by using the composition according to the invention is not particularly limited. However, for example, a developer containing an alkali developer or an organic solvent (hereinafter, also referred to as an organic developer) can be used.

As the alkali developer, for example, alkaline aqueous solutions of inorganic alkalis such as sodium hydroxide, potassium hydroxide, sodium carbonate, sodium silicate, sodium silicate, and ammonia water, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, tetraalkylammonium hydroxide such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, quaternary ammonium salt such as trimethylphenylammonium hydroxide, trimethylbenzylammonium hydroxide, and triethylbenzylammonium hydroxide, and cyclic amines such as pyrrole and piperidine can be used. An appropriate amount of alcohols or a surfactant may be added to an alkali developer, to be used. The alkaline concentration of the alkali developer is generally 0.1% to 20% by mass. pH of the alkali developer is generally 10.0 to 15.0. An alkaline concentration and pH of the alkali developer can be appropriately prepared to be used. The alkali developer may be used by adding a surfactant or an organic solvent.

The organic developer is particularly preferably used when a negative pattern is obtained by using a composition including a resin (in other words, a resin having a group of which polarity increases due to an action of an acid) in which solubility with respect to the alkali developer due to an action of an acid increases. As the organic developer, a polar solvent such as an ester-based solvent (butyl acetate and the like), a ketone-based solvent (2-heptanone, cyclohexanone, and the like), an alcohol-based solvent, an amide-based solvent, and an ether-based solvent (propylene glycol monomethyl ether, and the like), and a hydrocarbon-based solvent can be used. A moisture content with respect to the total organic developer is preferably less than 10% by mass and it is more preferable not to substantially contain moisture.

That is, the usage amount of the organic solvent with respect to the organic developer is preferably 90% by mass to 100% by mass and more preferably 95% by mass to 100% by mass with respect to the total amount of the developer.

An appropriate amount of alcohols and/or a surfactant can be added to the developer, if necessary.

The surfactant is not particularly limited, and an ionic or nonionic fluorine-based and/or silicon-based surfactant can be used. Examples of the fluorine and/or the silicon-based surfactant include surfactants disclosed in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, and a nonionic surfactant is preferable. The nonionic surfactant is not particularly limited, and a fluorine-based surfactant or a silicon-based surfactant is still more preferably used.

The usage amount of the surfactant is generally 0.001% to 5% by mass, preferably 0.005% to 2% by mass, and still more preferably 0.01% to 0.5% by mass with respect to the total amount of the developer.

The developer used in the invention may include a basic compound. Specific examples and preferable examples of the basic compound that can be included in the developer used in the invention include compounds exemplified as the basic compound that can be included in the chemical amplification resist composition.

As the developing method, a method of dipping a substrate in a tank filled with a developer for a certain period of time (dipping method), a method of performing developing by piling a developer by surface tension on a substrate surface and and stopping for a certain period of time (paddling method), a method of spraying a developer on a surface of a substrate (spraying method), and a method of scanning a developer discharging nozzle at a regular speed on a substrate that rotates at a regular speed and continuously discharging a developer (dynamic dispensing method) can be applied.

In a case where the various developing methods above include a step of discharging a developer from a developing nozzle of a developing apparatus to a resist film, the discharge pressure (flow velocity near a unit area of the discharged developer) of the discharged developer is preferably 2 mL/sec/mm² or less, more preferably 1.5 mL/sec/mm² or less, and still more preferably 1 mL/sec/mm² or less. The lower limit of the flow velocity is not particularly limited, and 0.2 mL/sec/mm² or greater is preferable, considering throughput.

In a case where the discharge pressure of the discharged developer is caused to be in the range described above, it is possible to significantly decrease the defect of the pattern derived from a resist residue after development.

Details of this mechanism are not clear, but it may be considered that, in a case where the discharge pressure is caused to be in the range described above, the pressure applied by the developer to the resist film decreases such that the resist film or the resist pattern is suppressed from being carelessly cut or destroyed.

The discharge pressure (mL/sec/mm²) of the developer is a value at a developing nozzle outlet in a developing apparatus.

Examples of the method of adjusting the discharge pressure of the developer include a method of adjusting discharge pressure with a pump or the like or a method of changing discharge pressure by adjusting the pressure by a supply from a pressure tank.

After a step of performing developing by using the developer, a step of stopping development while substituting the developer with another solvent may be performed.

As the rinse liquid in a rinse process performed after the alkali development, pure water is used, and an appropriate amount of surfactant may be added to be used.

In a case where the developer is an organic developer, as the rinse liquid, it is preferable to use a rinse liquid containing at least one of organic solvents selected from the group consisting of a ketone-based solvent, an ester-based solvent, an alcohol-based solvent, and an amide-based solvent.

In the patterning method according to the invention, a step (organic solvent development step) of performing development by using a developer including an organic solvent and a step (alkaline development step) of performing development by using an alkaline aqueous solution and forming a resist pattern can be performed in combination. Accordingly, a finer pattern can be formed.

According to the invention, a portion having weak exposure strength is removed by an organic solvent development step, and a portion having strong exposure strength is removed by further performing an alkaline development step. Since it is possible to form a pattern without dissolving only an area having intermediate exposure strength by a multiple development process in which development is performed plural times, it is possible to form a finer pattern than as usual (the same mechanism as disclosed Paragraph “0077” in JP2008-292975A).

The invention also relates to a photo mask obtained by exposing and developing a mask blank provided with the actinic ray-sensitive or radiation-sensitive film. As the exposure and the development, the steps described above are applied. The photo mask is suitably used for manufacturing a semiconductor.

The photo mask according to the invention may be a light transmission-type mask used in ArF excimer laser and the like, or may be a light reflection-type mask used in a reflection system lithography having EUV light as a light source.

The invention also relates to an electronic device manufacturing method including the patterning method according to the invention described above and an electronic device manufactured by the manufacturing method.

The electronic device according to the invention is suitably mounted on an electric and electronic apparatus (home electric appliances, OA.media related-apparatuses, optical apparatuses, communication apparatuses, and the like).

### EXAMPLES

Hereinafter, the invention is described in detail with reference to examples, but the invention is not limited thereto.

[Synthesization of (B) Acid Generator]

### Synthesization Example 1

### Synthesization of Compound (B-1)

A compound (A0) below was synthesized according to the disclosure of Synthesis, 2004, 10, 1648 to 1654.

A compound (B0) was synthesized according to the disclosure of Bulletin of the Chemical Society of Japan, Vol. 66 (1993), No. 9, pages 2590 to 2602.

10 g of the compound (A0) was dissolved in 30 ml of methanol, 7.7 g of the compound (B0) was added hereto, and stirring was performed for one hour. Thereafter, 100 ml of ethyl acetate was added to the obtained mixture solution, 100 ml of distilled water was added, and an organic layer was extracted. After the obtained organic layer was washed with 100 ml of a 0.1 N—NaOH aqueous solution, was washed with 100 ml of a 0.1 N—HCl aqueous solution, and was washed with 100 ml of distilled water three times. Subsequently, the organic solvent was distilled from the organic layer after washing, precipitated crystal was taken by filtering, and the precipitated crystal was dried with a vacuum pump, so as to obtain 12.2 g of a compound (B-1) below.

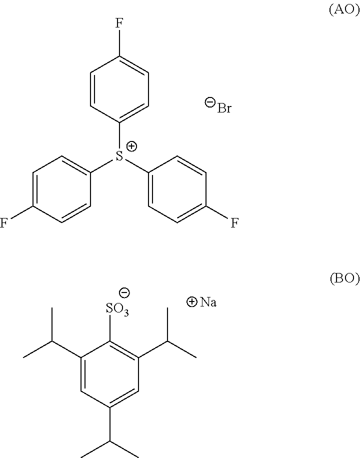

A chemical shift of ¹H-NMR of the compound (B-1) is indicated below.

¹H-NMR (d6-DMSO: ppm) δ: 1.17 to 1.77 (30H, m), 2.40-2.38 (1H, m), 4.21-4.17 (2H, m), 6.88 (2H, s), 7.69-7.63 (6H, m), and 7.96-7.91 (6H, m).

### Synthesization Example 2

### Synthesization of Compound (B-2)

Salt exchange between sulfonium bromide and sodium sulfonate was performed in the same manner as Synthesization of the compound (B-1), so as to synthesize a compound (B-2) indicated below. A chemical shift of ¹H-NMR of the compound (B-2) below is indicated below.

¹H-NMR (d6-DMSO:ppm) δ: 1.17 to 1.09 (18H, m), 2.81-2.76 (1H, m), 4.61-4.55 (2H, m), 6.94 (2H, s), 7.69-7.63 (6H, m), and 7.96-7.91 (6H, m).

A compound (B-3) was having the structure below was synthesized below.

Structures of the compound (B-1), (B-2) and (B-3), pKa values of generated acid, and volumes of sulfonic acid generated from these compounds are indicated below. Here, the pKa values are values calculated by methods above by using a software package: Advanced Chemistry Development (ACD/Labs) Software V8.14 for Solaris (1994-2007 ACD/Labs), and volumes thereof are values calculated by the method above by using “WinMOPAC” manufactured by Fujitsu Limited.

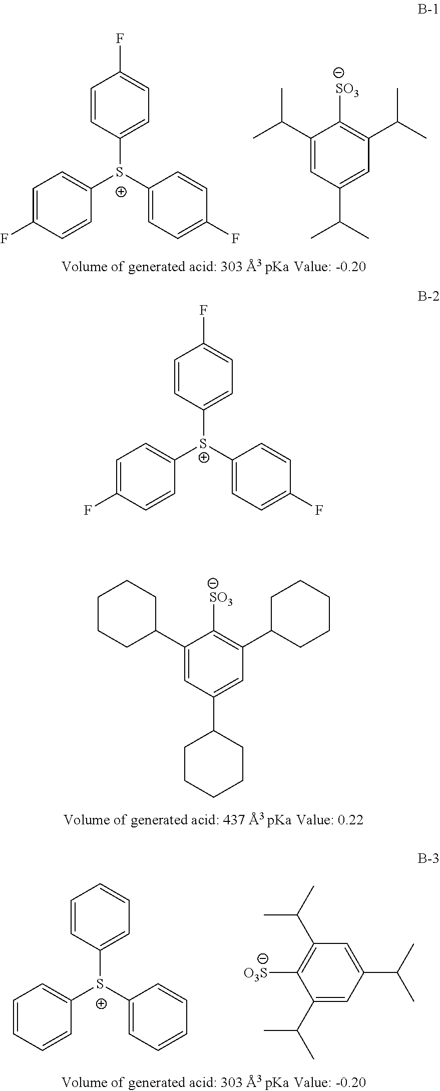

Among the components used as examples of Table 1 below, components except for the acid generator are described below.

[Resin] As the resins, resins (A-1) and (A-2) indicated below are used. A compositional ratio (molar ratio), a weight average molecular weight (Mw), a degree of dispersion (weight average molecular weight (Mw)/number average molecular weight (Mn)), and a pKa value are indicated together.

Here, a weight average molecular weight Mw (in terms of polystyrene), a number average molecular weight Mn (in terms of polystyrene), and a degree of dispersion Mw/Mn (PDI) were calculated by the GPC (solvent: THF) measurement. A compositional ratio (molar ratio) was calculated by the ¹H-NMR measurement. The pKa value is a value calculated by the method above by using a software package: Advanced Chemistry Development (ACD/Labs) Software V8.14 for Solaris (1994-2007 ACD/Labs) with respect to a monomer unit forming the resin.

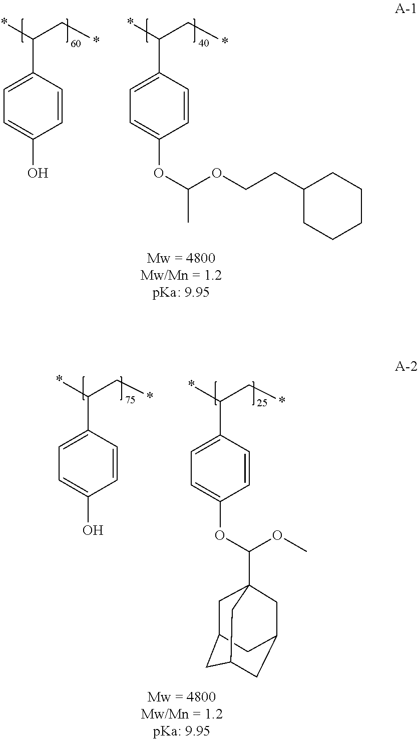

[Organic Acid]

As the organic acid, an aromatic organic carboxylic acid described below was used. Here, the pKa value is a value calculated by the method above by using a software package: Advanced Chemistry Development (ACD/Labs) Software V8.14 for Solaris (1994-2007 ACD/Labs).

C-1: 2-Hydroxy-3-naphthoic acid (pKa: 3.02)

C-2: 2-Naphthoic acid (pKa: 4.20) C-3: Benzoic acid (pKa: 4.20)

[Basic Compound]

F-1: Tetrabutylammonium hydroxide

F-2: Tri(n-octyl)amine

[Solvent]

S-1: Propylene glycol monomethyl ether acetate (1-Methoxy-2-acetoxypropane)

S-2: Propylene glycol monomethyl ether (1-Methoxy-2-propanol)

S-3: 2-Heptanone

S-4: Ethyl lactate

S-5: Cyclohexanone

S-6: γ-Butyrolactone

S-7: Propylene carbonate

(1) Preparation of Support

A six-inch wafer (subjected to a shielding film treatment which was used in a common photo mask blank) subjected to Cr oxide vapor deposition was prepared.

(2) Preparation of Resist Solution

Respective components illustrated in Table 1 below were added to the solvent in any one of sequence of addition order (a) to (e) below, a solution having a concentration of solid content of 2% by mass was prepared, and this was micro-filtrated with a polytetrafluoroethylene filter having a pore size of 0.04 μm, so as to obtain a resist solution.

(3) Preparation of Resist Film

The six-inch wafer was coated with a resist solution by using a spin coater Mark 8 manufactured by Tokyo Electron Limited, and the resist solution was dried on a hot plate at 110° C. for 90 seconds, so as to obtain a resist film having a film thickness of 50 nm. That is, a resist-coated mask blank was obtained.

(4) Manufacturing of Resist Pattern

Pattern irradiation was performed on this resist film by using an electron beam drawing apparatus (manufactured by Elionix Inc.; ELS-7500, Acceleration voltage: 50 KeV). The resist film after the irradiation was heated on a hot plate at 120° C. for 90 seconds and was immersed in 2.38% by mass of tetramethyl ammonium hydroxide (TMAH) aqueous solution for 60 seconds, was rinsed for 30 seconds, and was dried.

(5) Evaluation of Resist Pattern

The obtained pattern was evaluated in temporal stability and resolution by a method below. Evaluation results were shown in Table 1.

[LS resolution]

The sectional shape of the obtained pattern was observed by using a scanning type electron microscope (S-4300 manufactured by Hitachi, Ltd.). An exposure amount (electron beam irradiation amount) when a 1:1 line and space resist pattern having a line width of 50 nm was resolved was set to sensitivity. As this value becomes smaller, sensitivity is higher.

Limited resolution (minimum line width in which lines and spaces were separately resolved) in the exposure amount (electron beam irradiation amount) indicating the sensitivity was set to be the LS resolution.

A: Minimum line width≦40 nm

B: 40 nm<minimum line width<50 nm

C: 50 nm≦minimum line width

[Temporal Stability]

An exposure amount in which lines and spaces (1:1) having a line width of 100 nm and being formed by using a resist liquid immediately after the preparation were resolved was set to be an initial condition. After the resist liquid stored in an airtight container was stored in the 50° C. environment for 10 days, the lines and spaces were resolved in the initial condition by using this resist solution. At this point, a shift amount from the line width of 100 nm was determined according to the following criteria.

A: CD variation amount≦1 nm

B: 1 nm<CD variation amount<2 nm

C: 2 nm≦CD variation amount

TABLE 1

| | Resin | Acid generator | Organic acid | Basic compound | Solvent | Adding | Temporal | |
|---|---|---|---|---|---|---|---|---|
| | (% by mass) | (% by mass) | (% by mass) | (% by mass) | (mass ratio) | order | stability | Resolution |
| Example 1 | A-1 | B-1 | C-1 | F-1 | S-1/S-2 | (a) | B | A |
| | (78.0) | (15) | (5.5) | (1.5) | (80/20) | | | |
| Example 2 | A-1 | B-1 | C-1 | F-1 | S-1/S-5 | (a) | A | A |
| | (75.5) | (15) | (8.0) | (1.5) | (60/40) | | | |
| Example 3 | A-1 | B-1 | C-1/C-2 | F-1 | S-1/S-4 | (a) | A | A |
| | (75.5) | (15) | (4.0/4.0) | (1.5) | (60/40) | | | |
| Example 4 | A-1/A-2 | B-1 | C-3 | F-1 | S-1/S-2/S-3 | (a) | A | A |
| | (40.0/35.5) | (15) | (8.0) | (1.5) | (80/15/5) | | | |
| Example 5 | A-2 | B-1/B-2 | C-3 | F-1 | S-1/S-2/S-6 | (a) | A | A |
| | (75.5) | (5/10) | (8.0) | (1.5) | (80/15/5) | | | |
| Example 6 | A-2 | B-1/B-2 | C-3 | F-1 | S-1/S-2/S-7 | (b) | A | A |
| | (75.5) | (10/5) | (8.0) | (1.5) | (80/15/5) | | | |
| Example 7 | A-2 | B-2 | C-3 | F-1 | S-1/S-2 | (c) | A | A |
| | (75.5) | (15) | (8.0) | (1.5) | (80/20) | | | |
| Example 8 | A-2 | B-3 | C-1 | F-1 | S-1/S-2 | (a) | A | B |
| | (75.5) | (15) | (8.0) | (1.5) | (80/20) | | | |
| Comparative | A-1 | B-1 | — | F-1/F-2 | S-1/S-5 | (e) | C | A |
| Example 1 | (83.5) | (15) | | (1.0/0.5) | (60/40) | | | |
| Comparative | A-1 | B-1 | C-1 | F-1 | S-1/S-2 | (a) | C | A |
| Example 2 | (79.0) | (15) | (4.5) | (1.5) | (80/20) | | | |
| Comparative | A-2 | B-2 | C-1 | F-1 | S-1/S-2 | (d) | C | A |
| Example 3 | (75.5) | (15) | (8.0) | (1.5) | (80/20) | | | |

Adding order (a) Solvent→basic compound→organic acid→resin→acid generator (b) Solvent→basic compound→photoacid generator→organic acid→resin (c) Solvent→basic compound→resin→organic acid→photoacid generator (d) Solvent→basic compound→resin→photoacid generator→organic acid (e) Solvent→basic compound→resin→photoacid generator
The expression “% by mass” in the table means a ratio of respective components with respect to the total mass of the total solid content.

From results shown in Table 1, patterns that were able to be obtained by the manufacturing method according to the invention had excellent temporal stability and excellent resolution.

What is claimed is:

1. A manufacturing method for an actinic ray-sensitive or radiation-sensitive resin composition that contains (A) resin, (B) acid generator, (C) organic acid; and (D) solvent, comprising:
at least one of (i), (ii), or (iii) below,
wherein a content ratio of (C) organic acid in the actinic ray-sensitive or radiation-sensitive resin composition is greater than 5% by mass based on a total solid content in the composition,
(i) dissolving (C) organic acid in a solution that does not substantially contain (A) resin and (B) acid generator;
(ii) dissolving (C) organic acid in a solution that contains (B) acid generator and does not substantially contain (A) resin; and
(iii) dissolving (C) organic acid in a solution that contains (A) resin and does not substantially contain (B) acid generator.

2. The manufacturing method according to claim 1,
wherein pKa of (C) organic acid is lower than pKa of (A) resin and is greater than pKa of acid generated from (B) acid generator.

3. The manufacturing method according to claim 1,
wherein (C) organic acid is organic carboxylic acid.

4. The manufacturing method according to claim 3,
wherein (C) organic acid is aromatic organic carboxylic acid.

5. The manufacturing method according to claim 1,
wherein (A) resin includes a repeating unit having a group that is decomposed due to an action of acid and of which polarity increases.

6. The manufacturing method according to claim 1,
wherein (A) resin includes a repeating unit having a phenolic hydroxyl group.

7. The manufacturing method according to claim 1,
wherein (B) acid generator is an ionic compound consisting of an organic anion and a cation selected from a sulfonium cation and an iodonium cation, and
the cation is a cation having at least one electron-withdrawing group.

8. The manufacturing method according to claim 7,
wherein the organic anion is an aromatic sulfonic acid anion.

9. The manufacturing method according to claim 1,
wherein the actinic ray-sensitive or radiation-sensitive resin composition further contains a basic compound.

10. The manufacturing method according to claim 9,
wherein the basic compound is an ammonium salt.

11. The manufacturing method according to claim 1,
wherein a concentration of a solid content of the actinic ray-sensitive or radiation-sensitive resin composition is 10% by mass or less.

12. An actinic ray-sensitive or radiation-sensitive resin composition manufactured by the manufacturing method according to claim 1.

13. An actinic ray-sensitive or radiation-sensitive film manufactured from the actinic ray-sensitive or radiation-sensitive resin composition according to claim 12.

14. The actinic ray-sensitive or radiation-sensitive film according to claim 13,
wherein a film thickness is 200 nm or less.

15. A mask blank comprising:
the actinic ray-sensitive or radiation-sensitive film according to claim 13.

16. A photo mask manufactured by a method including a step of exposing an actinic ray-sensitive or radiation-sensitive film comprising the mask blank according to claim 15 and a step of developing the exposed actinic ray-sensitive or radiation-sensitive film.

17. A forming method for a pattern including a step of exposing the actinic ray-sensitive or radiation-sensitive film according to 13 and a step of developing the exposed film.

18. The forming method for a pattern according to claim 17,
wherein the exposure is exposure with electronic rays or EUV light.

19. An actinic ray-sensitive or radiation-sensitive resin composition, comprising:
(A) resin;
(B) acid generator; and
(C) organic acid;
wherein a content ratio of (C) organic acid is greater than 5% by mass based on a total solid content in the actinic ray-sensitive or radiation-sensitive resin composition.

20. The actinic ray-sensitive or radiation-sensitive resin composition according to claim 19,
wherein pKa of (C) organic acid is lower than pKa of (A) resin and higher than pKa of acid that is generated from (B) acid generator.

21. The actinic ray-sensitive or radiation-sensitive resin composition according to claim 19,
wherein (A) resin is a resin including a repeating unit having a phenolic hydroxyl group,
(B) acid generator is an ionic compound consisting of an organic anion and a cation selected from a sulfonium cation and an iodonium cation, and
the cation is an ionic compound having at least one electron-withdrawing group.

22. The actinic ray-sensitive or radiation-sensitive resin composition according to claim 19,
wherein (B) acid generator is a compound that generates acid having a volume of 240 Å³ or greater due to irradiation of actinic rays or radiation.

23. A manufacturing method for an electronic device, comprising:
the forming method for a pattern according to claim 17.
